(19) United States
(12) Patent Application Publication
(10) Pub. No.: US 2005/0194588 A1
(43) Pub. Date: Sep. 8, 2005

(54) Fluorine compound, liquid repellent membrane using the same and product using the same

(76) Inventors: Hiroshi Sasaki, Mito (JP); Yasushi Tomioka, Hitachinaka (JP)

Correspondence Address: MCDERMOTT WILL & EMERY LLP, 600 13TH STREET, N.W., WASHINGTON, DC, 20005-3096, US

(21) Appl. No.: 11/032,238

(22) Filed: Jan. 11, 2005

(30) Foreign Application Priority Data
Jan. 13, 2004 (JP) JP 2004-004904

(51) Int. Cl. H01L 29/08; H01L 35/24; C07F 7/10

(52) U.S. Cl. 257/40; 549/215; 556/413; 556/485

(57) ABSTRACT

The present invention provides a liquid repellent membrane whose liquid repellency can be controlled by a varying physical stimulation; a novel fluorine compound which can be formed into the liquid repellent membrane; an electrical board, display device and color filter for display devices which are formed using the liquid repellent membrane by a method involving irradiation of visible light, which may be combined with a heating step, but needing no vacuum or ultraviolet ray irradiation process; methods for producing an electrical board, display device and color filter for display devices; and a pH sensor and ion sensor working on measurement of changed liquid repellency. The fluorine compound having liquid repellency is provided with a site at which it can be bound to a functional group, e.g., compound having a pigment unit.

### FIELD OF THE INVENTION

The present invention relates to a fluorine compound, liquid repellent membrane using the same compound, and various products using the same membrane.

### BACKGROUND OF THE INVENTION

Recently, new techniques have been proposed to produce boards, wherein a membrane having liquid repellency (hereinafter referred to as “liquid repellent membrane”) formed on a board is partly treated to lose the repellency and then coated with a liquid in which fine particles are dissolved or dispersed on the treated part. These boards are expected to go into various devices, e.g., display for TV sets, electrical board for electronic devices (e.g., radios and personal computers), color filter panel for liquid crystal displays, and board for organic electroluminescent (hereinafter referred to as “organic EL”) devices for EL displays.

Some of these techniques are disclosed by, e.g., Patent Document 1.

(Patent Document 1): JP-A 2000-282240

### BRIEF SUMMARY OF THE INVENTION

A fluorine compound containing fluorine atom, e.g., that containing a fluoro alkyl chain or fluoro benzene ring, is generally used to form a surface which repels liquid or prevents deposition of a substance thereon with little selectivity. It may be useful for developing new devices, when a compound of some functions is bound thereto. For example, when a host compound folding a specific compound can be bound to a liquid repellent fluorine compound, the micro particles surface-modified with the fluorine compound can be used for an adsorbent which selectively adsorbs a specific substance.

However, these materials have not been disclosed, and a liquid repellent membrane having a function of, e.g., changing in water repellency with some ion species or pH, cannot be realized.

A technique of partly reducing repellency and depositing a liquid selectively on the portion of decreased repellency is applicable not only to electrical lines but also to display devices of thin film transistor (TFT) or organic electro luminescence (EL) element or the like, and color filter panels in which the above device is used. These techniques mainly use light, because of availability of relatively low-cost light source which allows high-precision fabrication of the order of microns. Use of electron beams will be also effective, because these beams allow fabrication of the order of nanometers. Moreover, the liquid repellent membrane is expected to have greatly expanded applicable areas, when it can work with a physical stimulation, e.g., heat, pH, pressure, electricity or electric charge. It is also possible to develop a surface which can be controlled for its wettability by two or more stimulation types, when the liquid repellent membrane once formed can be provided with an acceptor which accepts a physical stimulation.

When repellency is to be controlled with light, even the newly proposed techniques need a vacuum process as is the case with conventional techniques, because of necessity for light having a wavelength of 172 nm, which is in the vacuum ultraviolet region, for direct photolysis of a fluorine compound. Therefore, a vacuum process which involves a vacuum chamber and the like is needed, although a vacuum deposition process may be dispensed with. Consequently, there are demands for those methods which can perform patterning with light of longer wavelength, more specifically 250 nm or more, and hence need no vacuum chamber. The light sources fall into two general categories, lamp (e.g., mercury or xenon lamp) and laser. A lamp-aided apparatus needs a lens system to collect outputted light, and also a suitable mask when fine electrical lines or the like are to be formed by light. A laser-aided apparatus, on the other hand, needs no collection of light it emits, because it runs more straight, and a desired portion can be selectively irradiated with light by scanning the surface by the laser set on an xy plotter or the like. Therefore, a laser-aided apparatus is advantageous over a lamp-aided apparatus, because of simplified structure and reduced cost. However, a common semiconductor laser can only emit light in the visible region, e.g., light of 830, 780, 630 or 405 nm in wavelength. Another laser can emit light of shorter wavelength. However, such a laser needs an apparatus of more sophisticated structure, and is difficult to move for forming electrical lines. Consequently, there are demands for liquid repellent membranes whose wettability can be controlled by a semiconductor laser.

It is an object of the present invention to provide a novel fluorine compound which can be bound to a variety of functional compounds. It is another object to provide a liquid repellent membrane using the same compound. It is still another object to provide a variety of products, e.g., electrical board, display device, color filter for display devices, pH sensor and ion sensor, using the same membrane.

The inventors of the present invention have successfully synthesized, after having extensively studied to solve the above problems, a variety of species of fluorine compounds having, in their chemical structures, a site at which they can be bound to a metal or glass and another site at which they can be bound to a residue. It is found that the compound gives a membrane which exhibits water repellency with a contact angle of 100° or more, when bound to a metal or glass. It is also found that the liquid repellent membrane can be bound to some colorants, because the fluorine compound in the membrane has in itself a site at which it can be bound to another compound. The liquid repellent membrane to which a colorant is bound can have decreased liquid repellency at the portion irradiated with light of wavelength absorbable by the colorant.

The method for reducing liquid repellency of a liquid repellent membrane by the aid of light depends on a principle that a colorant bound to the membrane is irradiated with light to convert the light energy to heat, by which the member constituting the membrane is thermally decomposed to decrease the liquid repellency.

It is observed that a membrane incorporated with a crown ether or the like in place of colorant has a decreased contact angle, when immersed in an aqueous solution of a metal which can be held in the membrane. It is also observed that a membrane having amino group serving as the binding site has a decreased contact angle, when immersed in an aqueous acidic solution, e.g., hydrochloric acid, conceivably because amino group is transformed into an ammonium salt structure to be more hydrophilic to generally decrease liquid repellency of the liquid repellent membrane. As discussed above, the inventors of the present invention have found that liquid repellent membrane can have selectively controlled liquid repellency depending on a substance with which it is treated, achieving the present invention. The present invention includes the following aspects.

The first aspect of the present invention is a fluorine compound represented by one of the following structures to achieve the above objects: 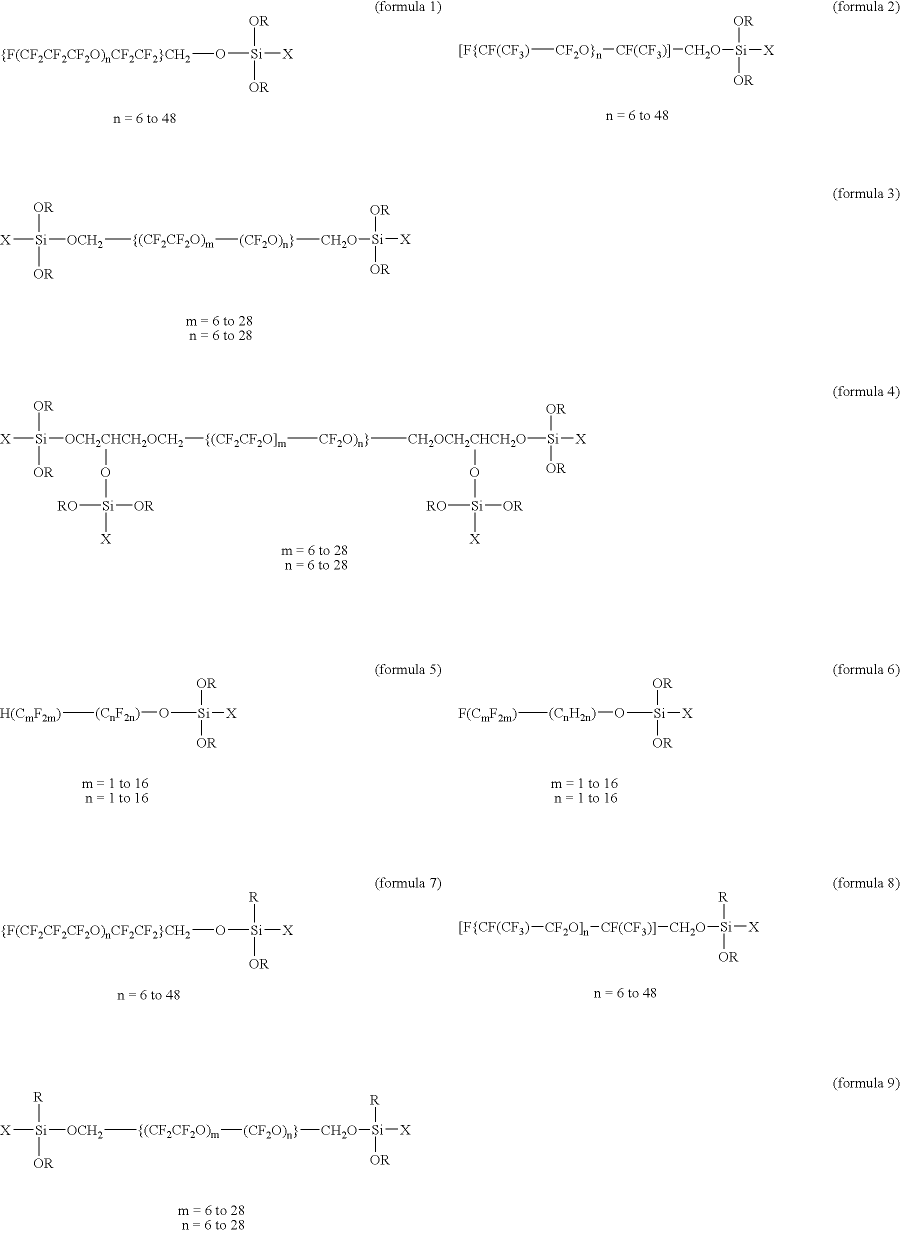 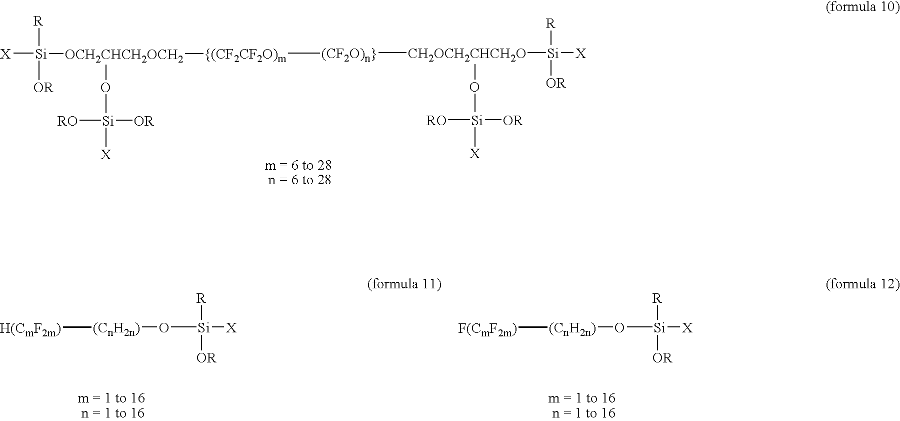
wherein, X is a structure represented by one of the following formulae, and R is an alkyl group of 1 to 4 carbon atoms:

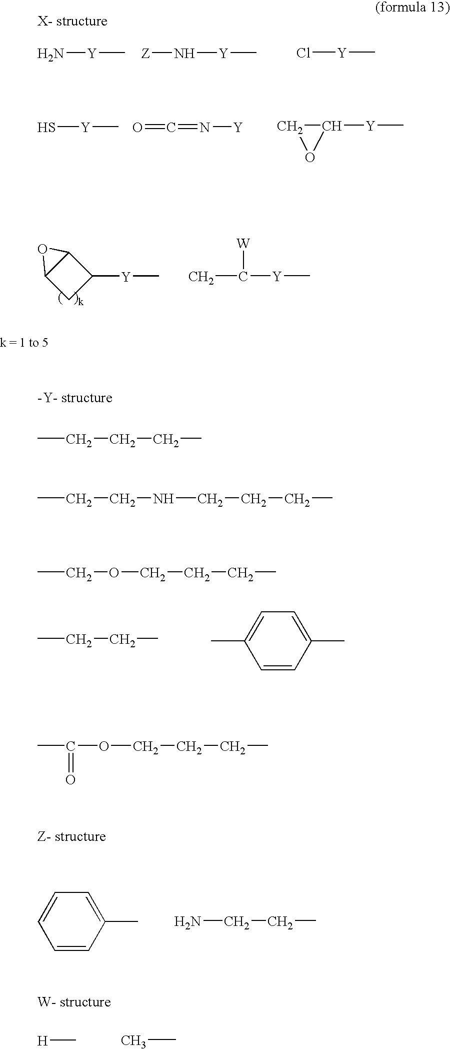

The second aspect is a fluorine compound represented by one of the following structures: 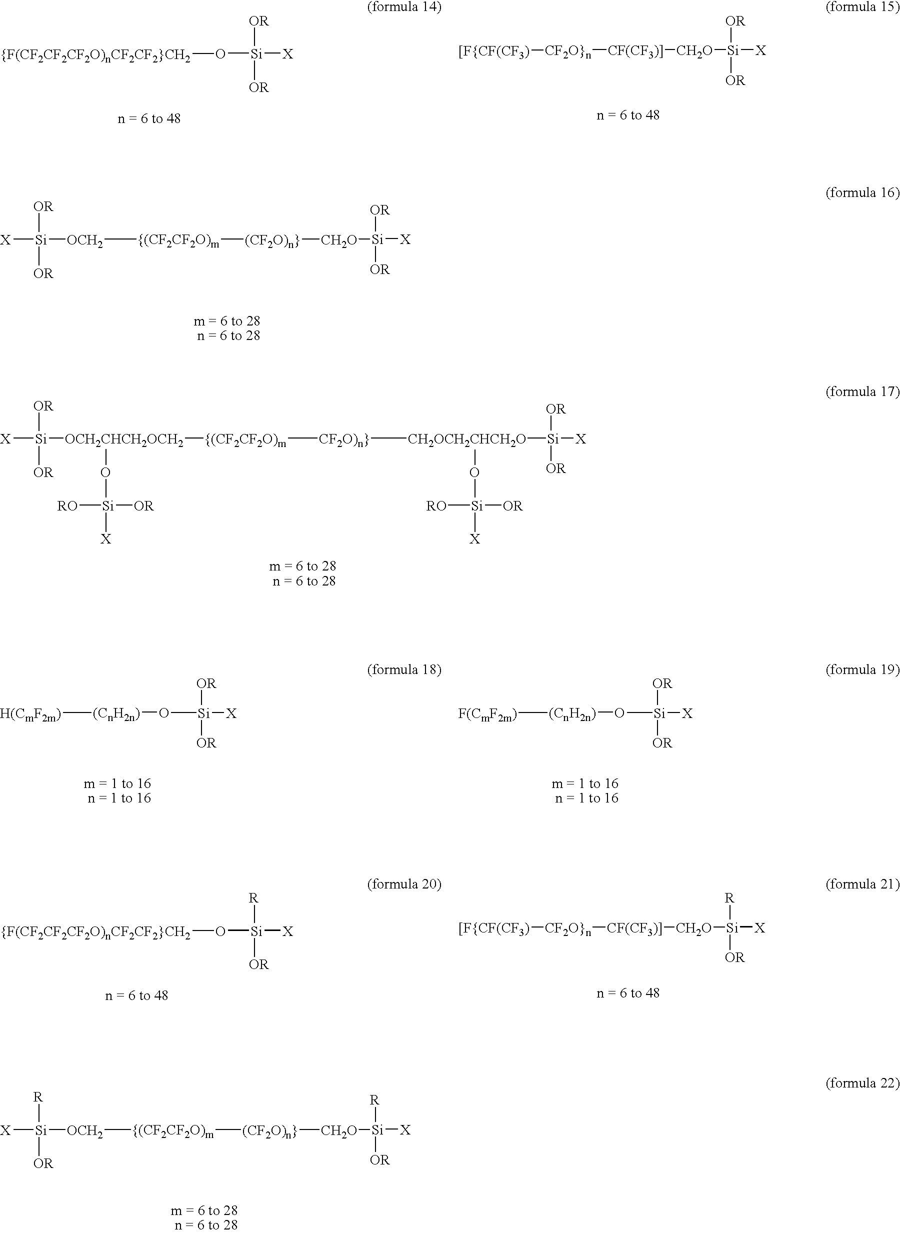 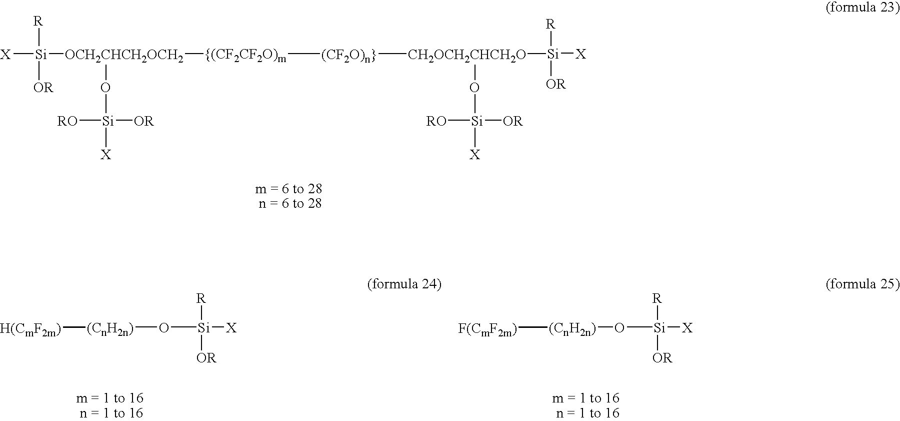
wherein, X is a structure represented by one of the following formulae, and R is an alkyl group of 1 to 4 carbon atoms:

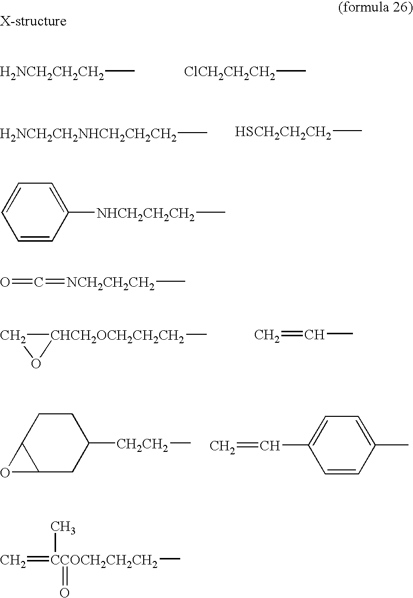

The third aspect is a liquid repellent membrane containing a fluorine compound represented by one of the following structures: 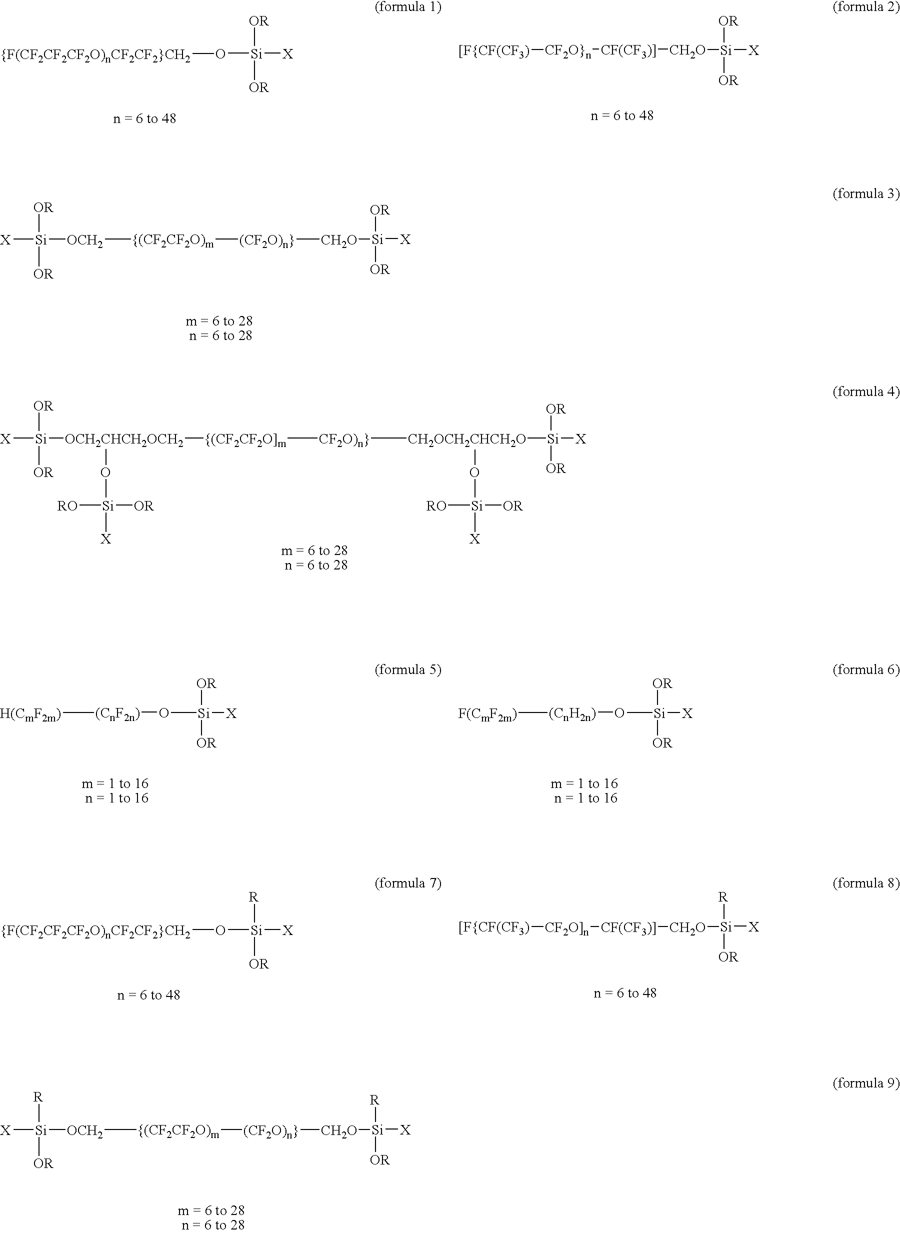 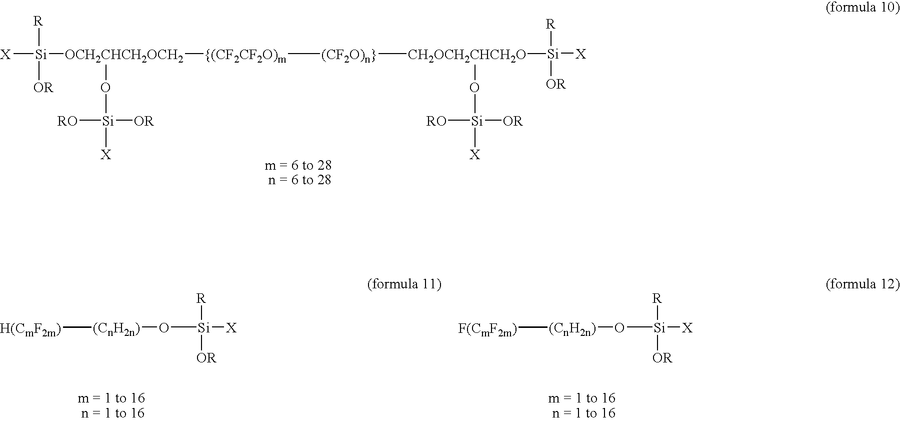
wherein, X is a structure represented by one of the following formulae, and R is an alkyl group of 1 to 4 carbon atoms:

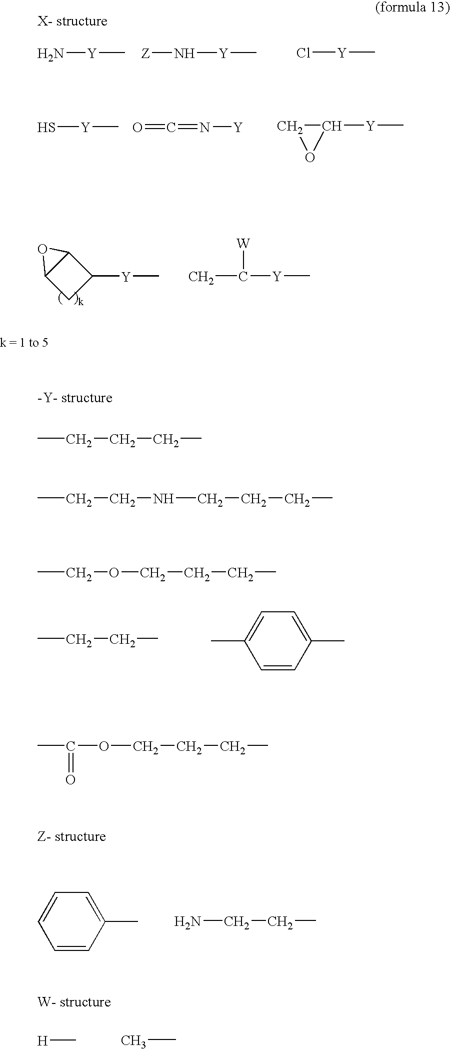

The fourth aspect is a liquid repellent membrane containing a fluorine compound represented by one of the following structures: 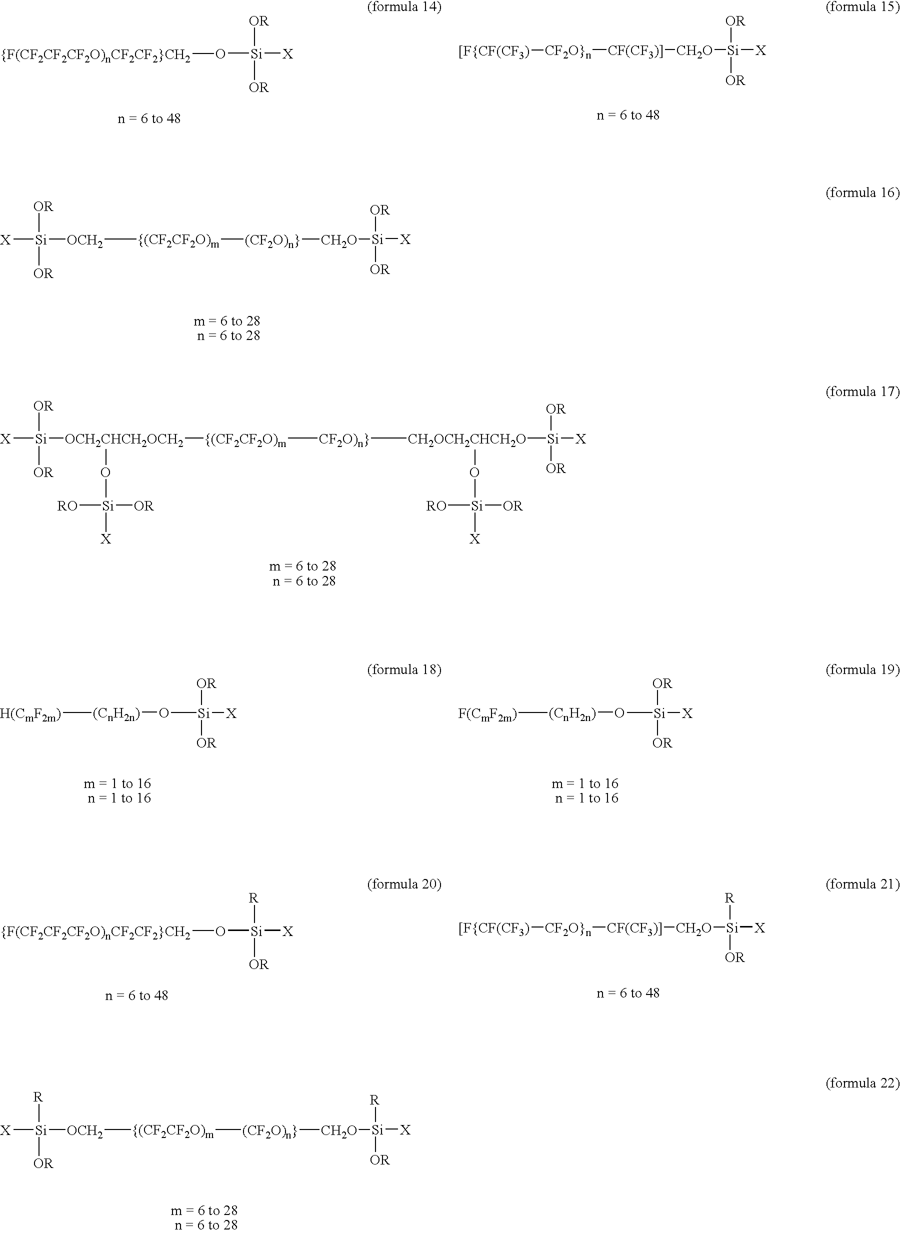 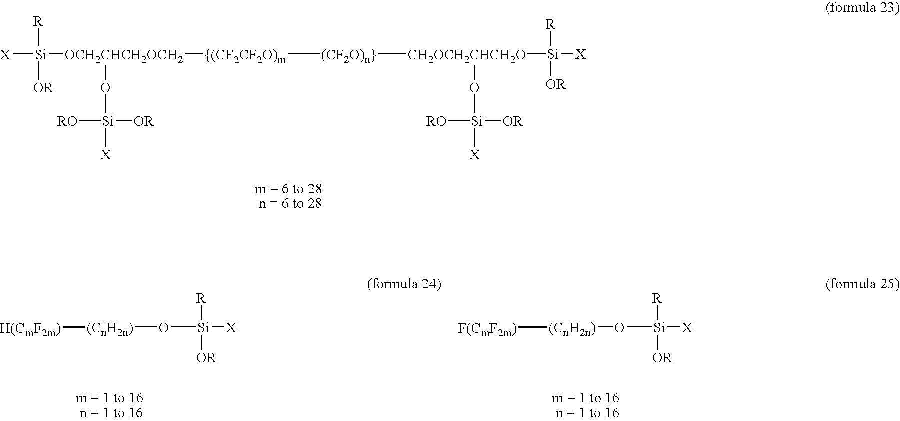
wherein, X is a structure represented by one of the following formulae, and R is an alkyl group of 1 to 4 carbon atoms:

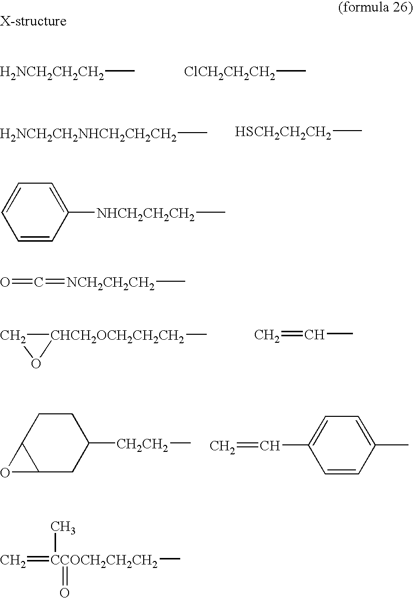

The fifth aspect is a liquid repellent membrane in which a fluorine compound represented by one of the following structures is bound to a functional compound having a coloring structure (pigment unit): 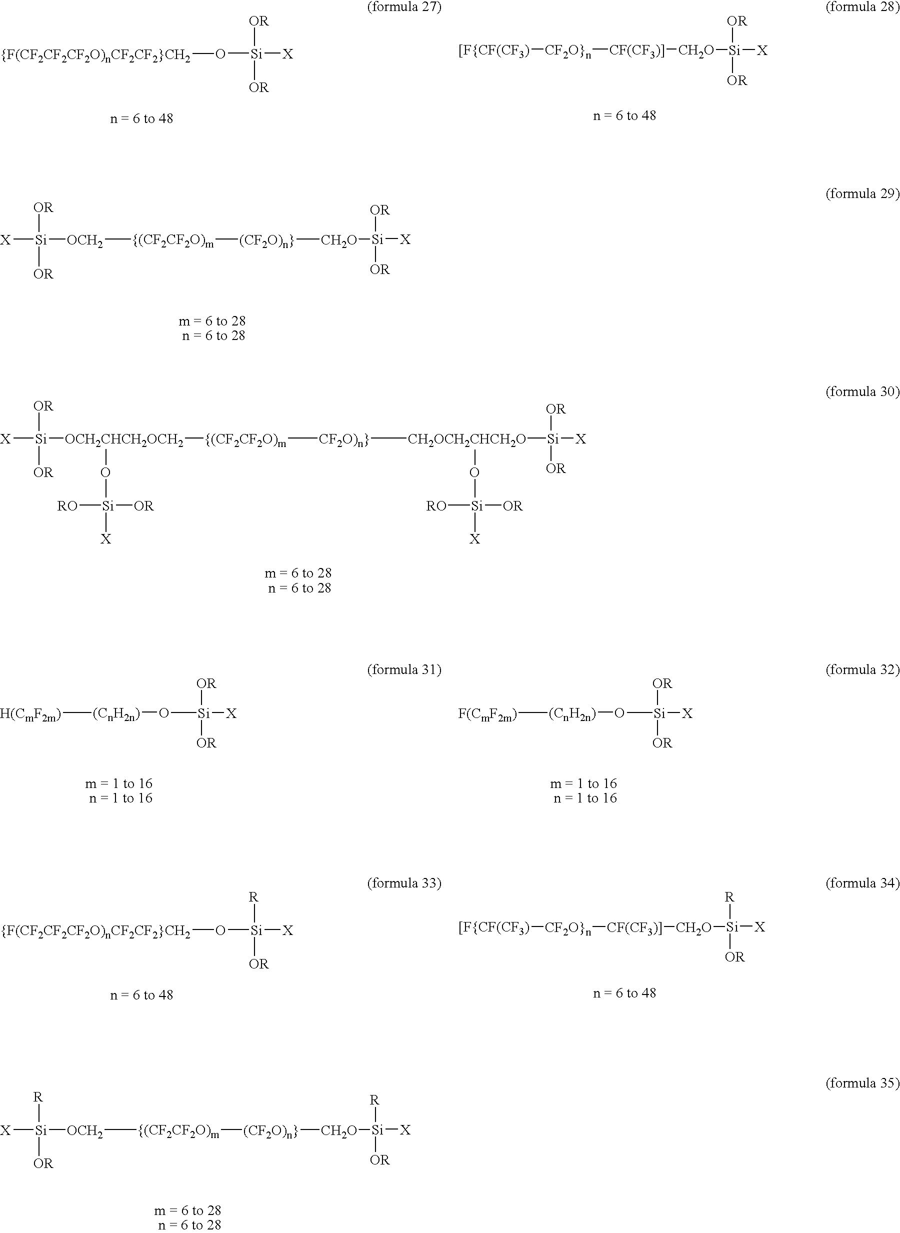 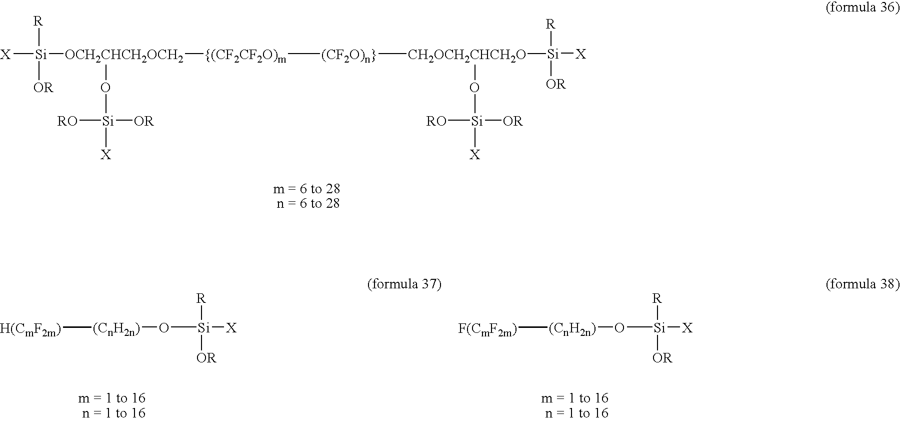
wherein, X is a structure represented by one of the following formulae, and R is an alkyl group of 1 to 4 carbon atoms:

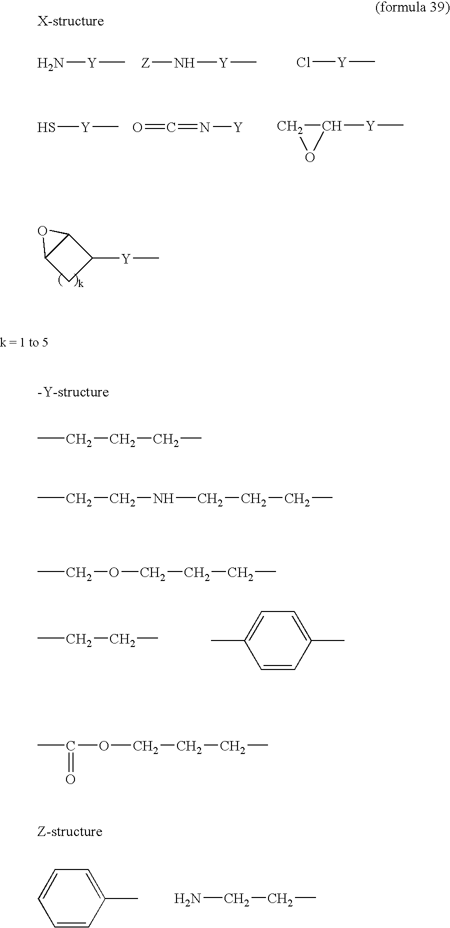

The functional compound having a coloring structure (pigment unit) is the one having a colorant commonly used as a pigment or dye serving as the skeleton. The pigment units include phthalocyanine, naphthalocyanine, anthraquinone, quinacridone, azo, indigo, thioindigo, dioxazine, acrydine, triphenyl methane, triallyl methane, fluorine, xanthene and cyanine structures.

The sixth aspect is a liquid repellent membrane in which a fluorine compound represented by one of the following structures is bound to a functional compound having a pigment unit: 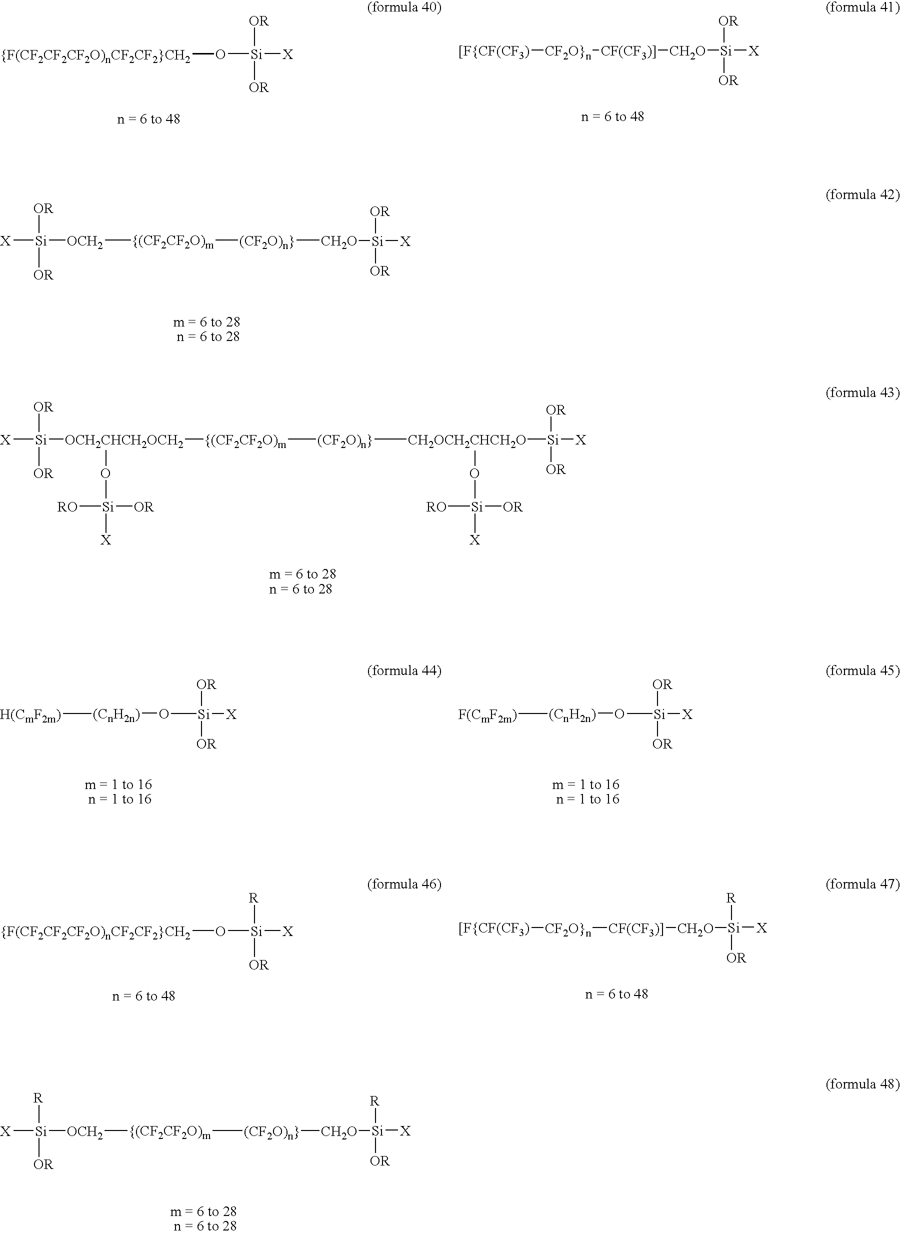 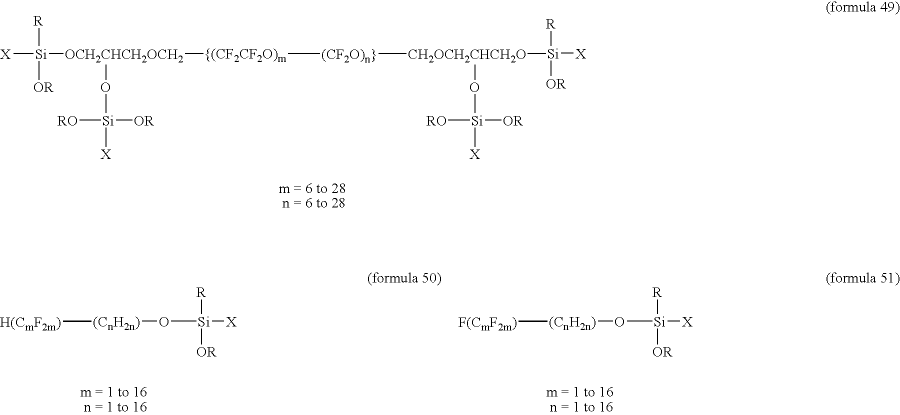
wherein, X is a structure represented by one of the following formulae, and R is an alkyl group of 1 to 4 carbon atoms:

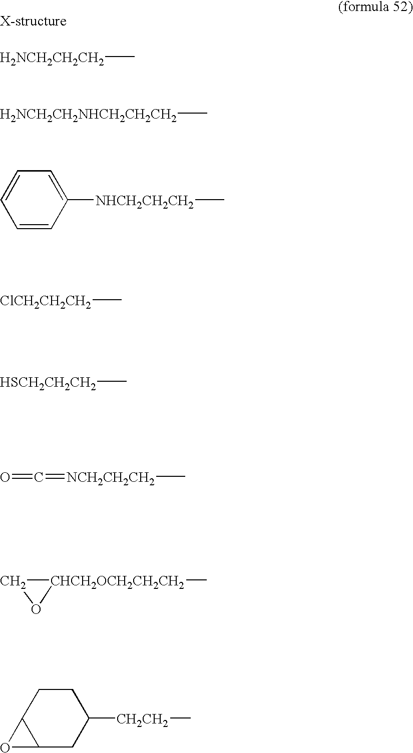

The seventh aspect is an electrical board comprising a board which supports a water repellent membrane and electrical lines in this order, wherein the water repellent membrane is the liquid repellent membrane according to the fifth or sixth aspect.

The eighth aspect is the electrical board according to the seventh aspect, wherein the water repellent membrane is formed on a board portion carrying no electrical line.

The ninth aspect is a semiconductor device comprising a board which supports layers of a gate electrode, gate insulation layer, source electrode, drain electrode, organic semiconductor layer and protective layer, wherein the liquid repellent membrane according to the fifth or sixth aspect is placed between any two adjacent layers on the board.

The tenth aspect is the semiconductor device according to the ninth aspect, wherein at least one of the source and drain electrodes is transparent.

The 11^{th} aspect is an organic electroluminescent device comprising a board which supports layers of a transparent electrode, hole-transport layer, emission layer and metallic electrode in this order, wherein the liquid repellent membrane according to the fifth or sixth aspect is placed between any two adjacent layers on the board.

The 12^{th} aspect is a color filter board comprising a board which supports a color filter layer and protective layer for protecting the color filter layer, wherein the liquid repellent membrane according to the fifth or sixth aspect is placed between the protective layer and board.

The 13^{th} aspect is a pH sensor comprising a board which supports a responsive unit, wherein the responsive unit has the liquid repellent membrane according to the fifth or sixth aspect.

The 14^{th} aspect is a pH sensor comprising a board which supports a responsive unit, wherein the responsive unit determines pH level of a sample brought into contact with the responsive unit by measuring a contact angle at the contact point.

The 15^{th} aspect is an ion sensor comprising a board which supports a responsive unit, wherein the responsive unit determines pH level of a sample brought into contact with the responsive unit by measuring a contact angle at the contact point.

The 16^{th} aspect is a method for producing an electrical board by forming a liquid repellent membrane on a board, irradiating part of the liquid repellent membrane with light to decrease liquid repellency of that part, and spreading a solution in which an electrical line material is dissolved or dispersed on the part of decreased repellency and drying the solution, wherein a fluorine compound represented by one of the following structures is used for the liquid repellent membrane: 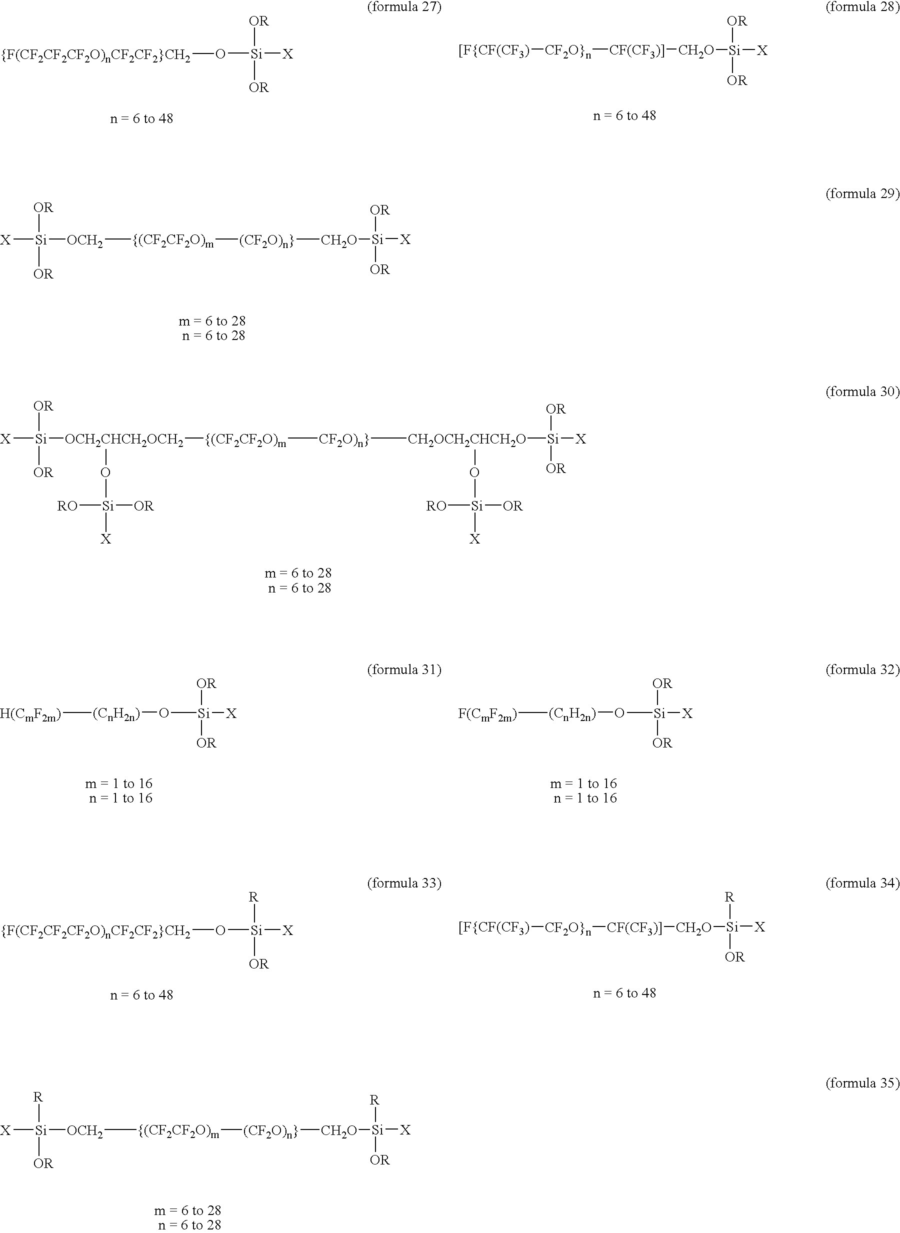 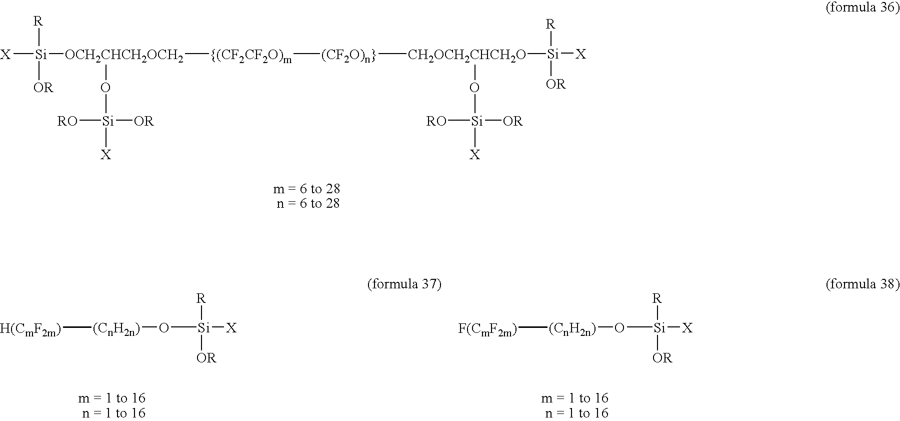
wherein, X is a structure represented by one of the following formulae, and R is an alkyl group of 1 to 4 carbon atoms:

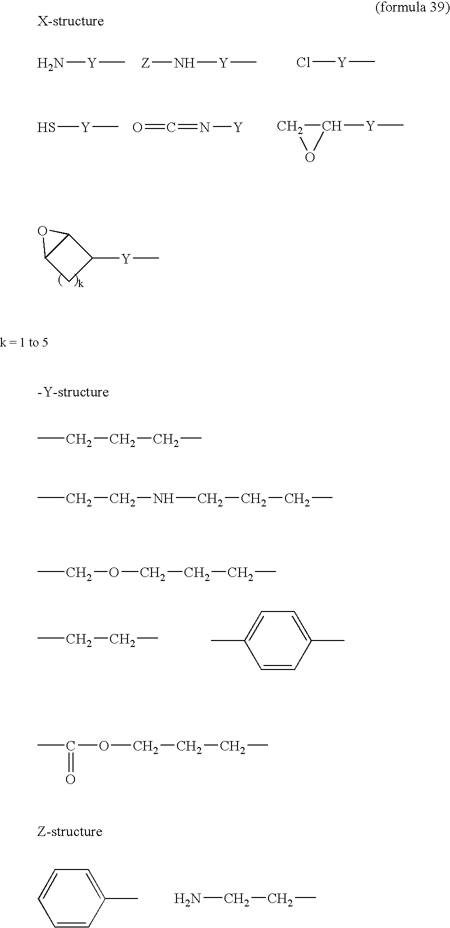

The 17^{th} aspect is a method for producing an electrical board by forming a liquid repellent membrane on a board, irradiating part of the liquid repellent membrane with light to decrease liquid repellency of that part, and spreading a solution in which an electrical line material is dissolved or dispersed on the part of decreased repellency and drying the solution, wherein a fluorine compound represented by one of the following structures is used for the liquid repellent membrane: 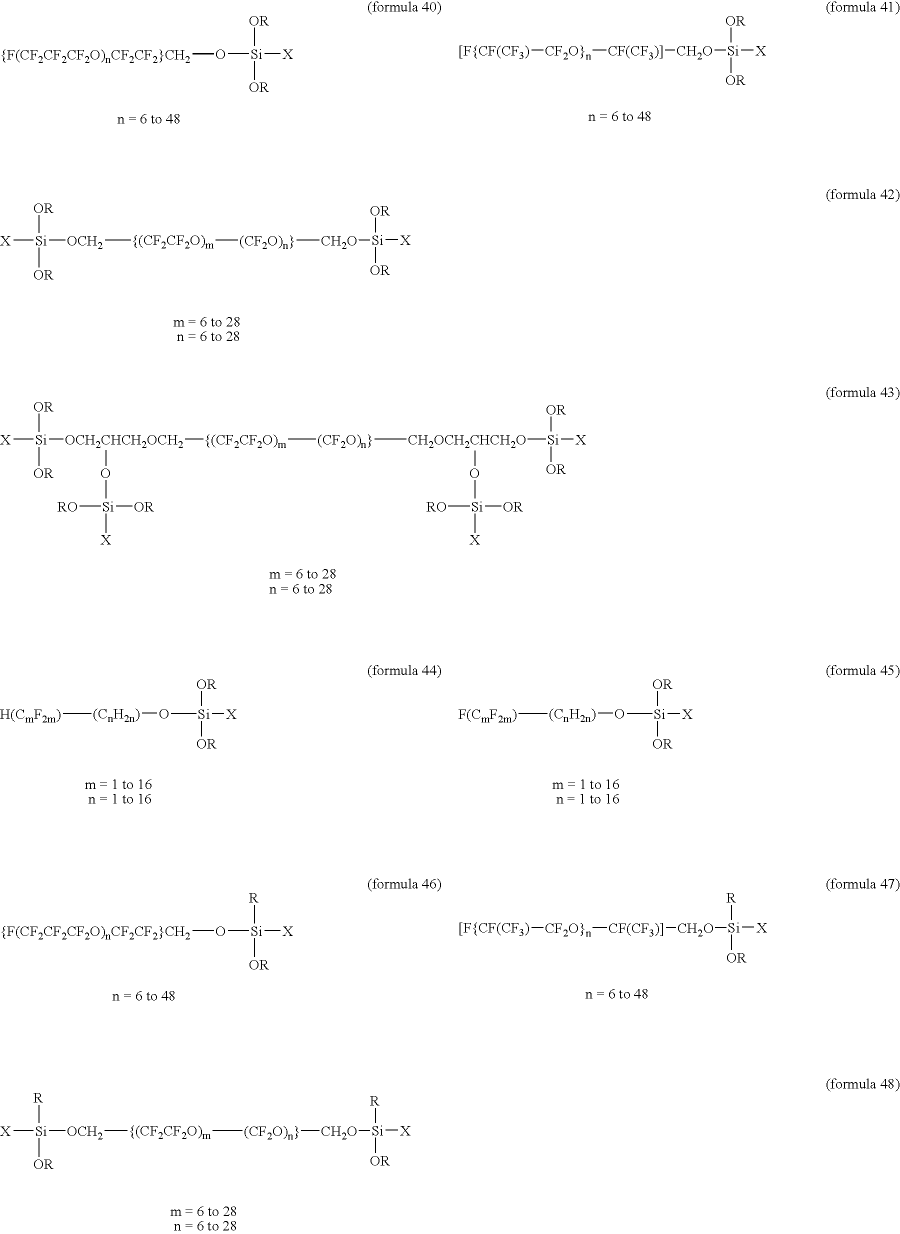 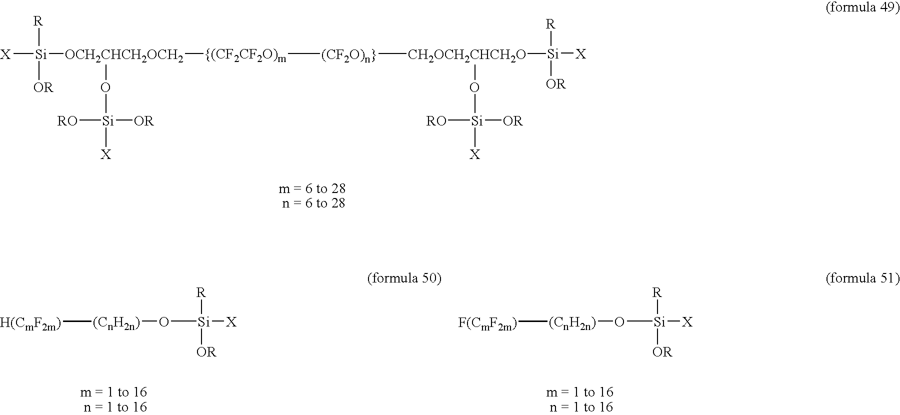
wherein, X is a structure represented by one of the following formulae, and R is an alkyl group of 1 to 4 carbon atoms:

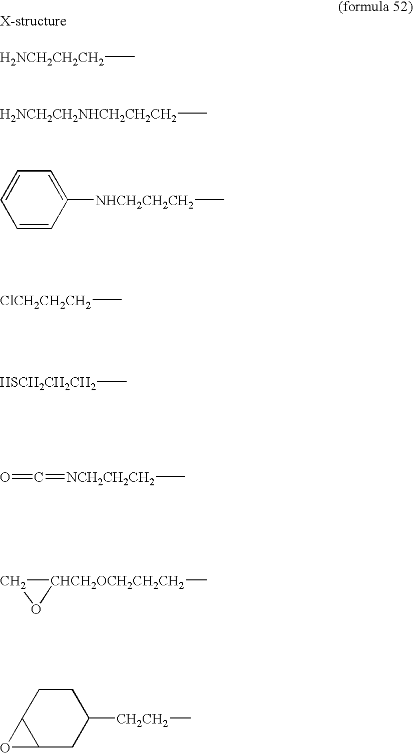

The 18^{th} aspect is a method for producing an organic electroluminescent device comprising steps for forming a transparent electrode, hole-injection layer, emission layer and metallic electrode, in this order on a transparent electrode, wherein a step for forming a liquid repellent membrane containing a fluorine compound represented by one of the following structures is carried out prior to at least one of the above steps: 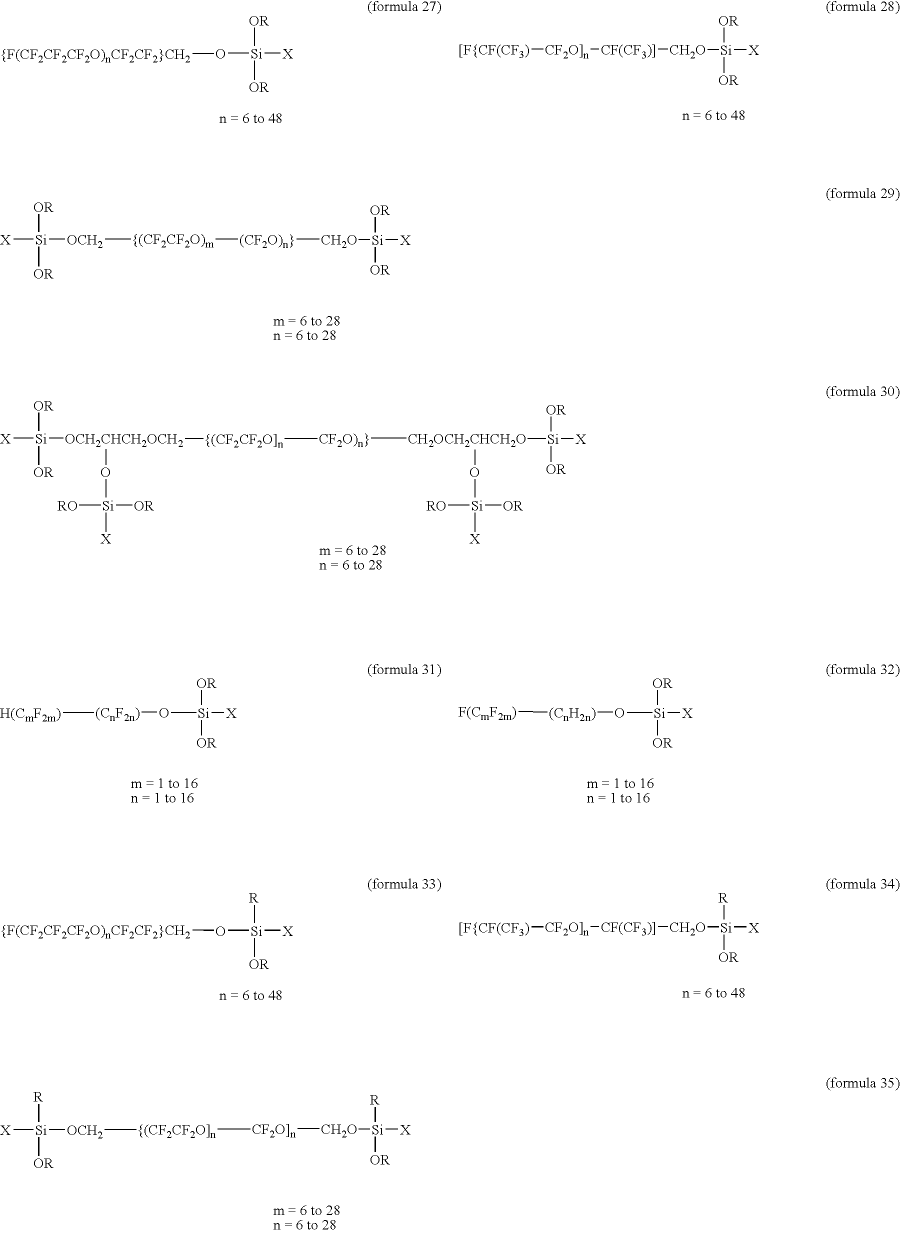 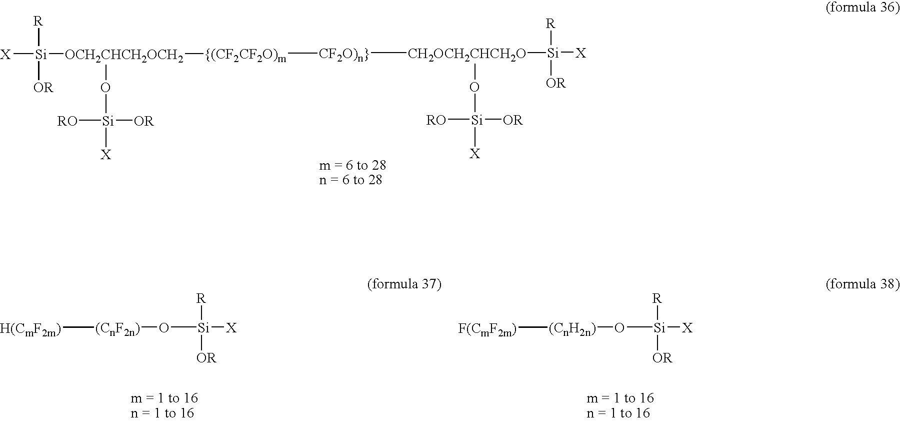
wherein, X is a structure represented by one of the following formulae, and R is an alkyl group of 1 to 4 carbon atoms:

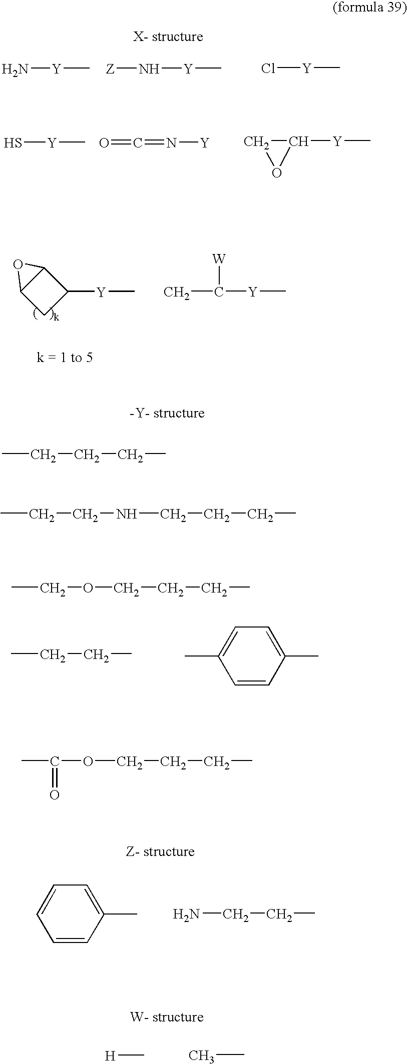

The 19^{th} aspect is a method for producing an organic electroluminescent device comprising steps for forming a transparent electrode, hole-injection layer, emission layer and metallic electrode, in this order on a transparent electrode, wherein a step for forming a liquid repellent membrane containing a fluorine compound represented by one of the following structures is carried out prior to at least one of the above steps: 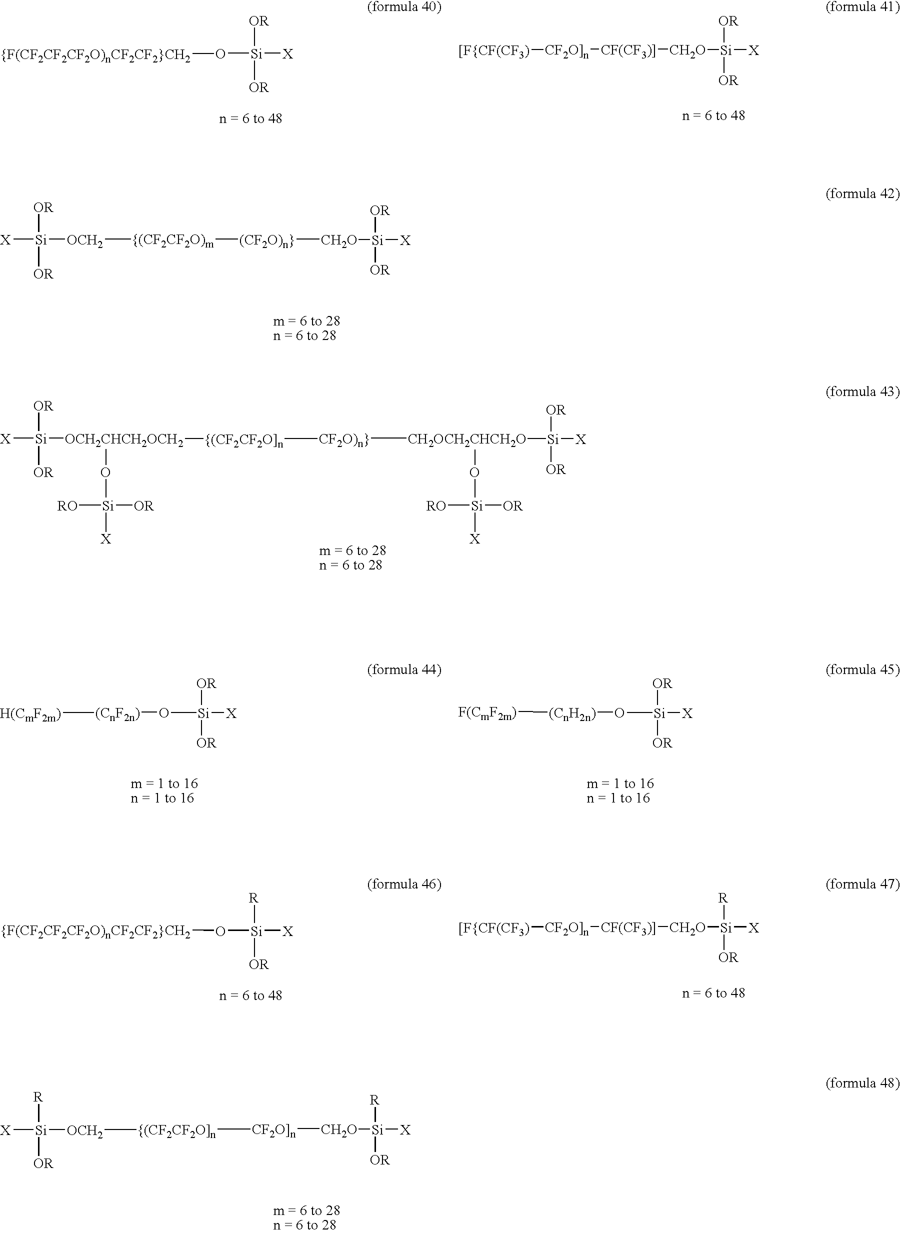 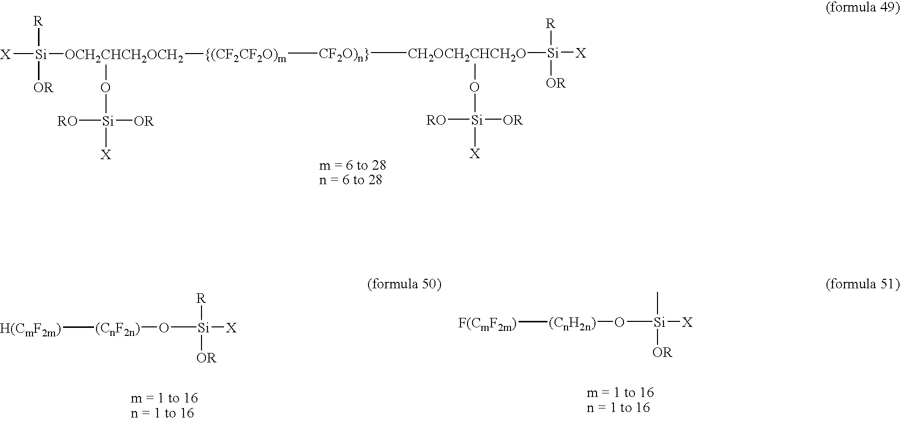
wherein, X is a structure represented by one of the following formulae, and R is an alkyl group of 1 to 4 carbon atoms:

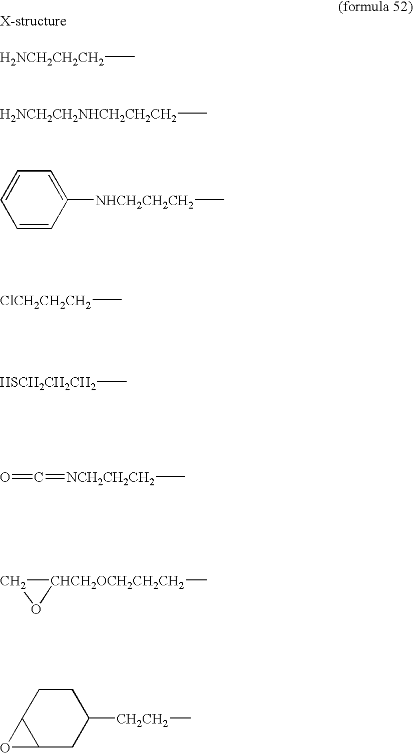

The 20^{th} aspect is a semiconductor device comprising a board which supports layers of a gate electrode, gate insulation layer, 2 or more source electrodes and drain electrode intersecting with these source electrodes, wherein a water repellent membrane is formed at least one of these layers.

Other objects, features and advantages of the invention will become apparent from the following description of the embodiments of the invention taken in conjunction with the accompanying drawings.

### BRIEF DESCRIPTION OF THE DRAWINGS

FIG. 1 schematically illustrates the fluorine compound of the present invention bound to a board.

FIG. 2 schematically illustrates a functional compound bound to the liquid repellent membrane of the present invention.

FIG. 3 presents an infrared (IR) spectral pattern of Compound 1.

FIG. 4 presents a proton nuclear magnetic resonance (¹H-NMR) pattern of Compound 1.

FIG. 5 illustrates a process scheme for producing a display TFT using the procedure for producing the liquid repellent membrane of the present invention.

FIG. 6 illustrates a process scheme for producing an organic EL board using the procedure for producing the liquid repellent membrane of the present invention.

FIG. 7 illustrates a process scheme for producing a display color filter using the procedure for producing the liquid repellent membrane of the present invention.

### DESCRIPTION OF REFERENCE NUMERALS

1 Fluorine compound
2 Liquid repellent site
3 Site at which the fluorine compound is bound to a functional compound
4 Site at which the fluorine compound is bound to a board (alkoxysilane structure)
5 Alkyl group
6, 8 Board
7 Functional compound
9 Liquid repellent membrane having light-absorbing sites.
10, 15, 18, 20, 25, 28, 31, 36, 39, 42, 45, 47 Light having a wavelength of 633 nm
11 Gate electrode
12 Irradiating light
13, 26 Insulation layer
14, 17, 24, 27, 35, 38, 41, 44 Liquid repellent membrane having light-absorbing sites
16 Source or drain electrode
19 Semiconductor device
21, 48 Protective layer
22 Transparent electrode of ITO
23, 34 Glass board
29 Hole-transport layer
30 Light emission layer
32 Metallic electrode
33 Sealing layer
37 Black matrix
40 Color filter R region
43 Color filter G region
46 Color filter B region

### DETAILED DESCRIPTION OF THE INVENTION

The best modes for carrying out the present invention are described for the fluorine compound, liquid repellent membrane using the fluorine compound, and board using the membrane, in this order.

It should be understood that the embodiments and EXAMPLES hereinafter described by no means limit the present invention, and various variations can be made within the technical concept of the present invention, needless to say.

[A] Fluorine Compound

(a) STRUCTURE OF THE FLUORINE COMPOUNDS

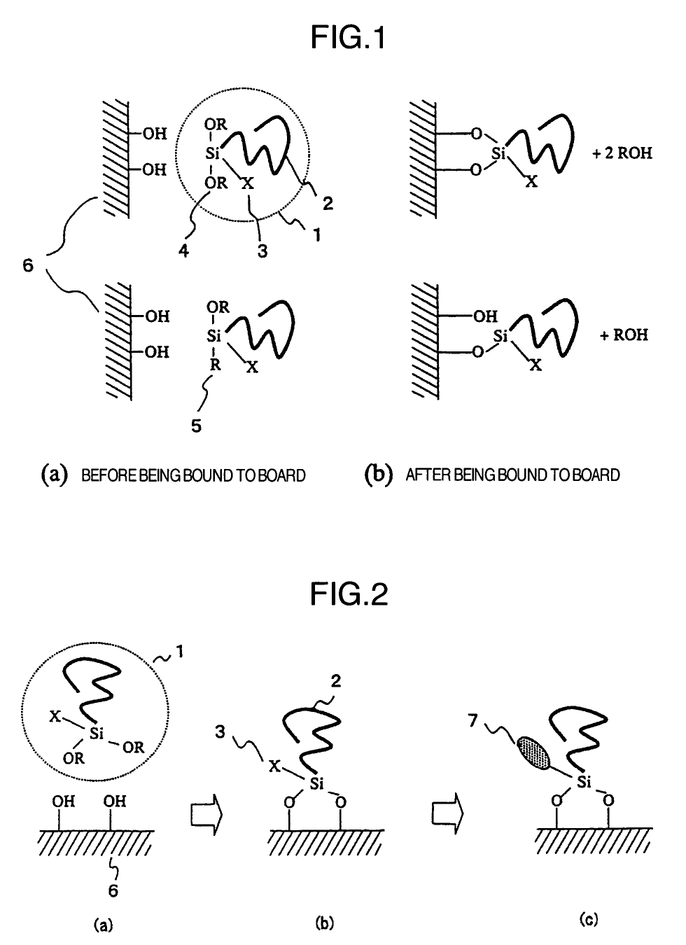

FIG. 1(a), (b) outlines the fluorine compounds described in the embodiments.

Referring to FIG. 1, each of the fluorine compounds 1 has 3 sites, the binding site 1 at which it is bound to a board, water repellent site 2, and binding site 3 at which it is bound to a functional compound. These sites are described below.

[i] Binding Site with a Board

An alkoxy silane structure is adopted for the binding site at which the fluorine compound is bound to a board. An alkoxy silane can be bound to the surface of a board of glass, metal or the like by reacting with hydroxyl group on the surface to form the oxygen-silicon bond. FIG. 1(a), (b) schematically illustrates the fluorine compound bound to a board.

[ii] Liquid Repellent Site

The liquid repellent site is the site at which liquid repellency is expressed.

Fluorine compounds frequently decrease liquid repellency of the liquid repellent membrane formed, when they contain a varying residue, e.g., pigment. Consequently, a perfluoroalkyl, fluoroalkyl or perfluoropolyether chain, which exhibits sufficiently high liquid repellency, is desirable for the oil repellent site. More specifically, examples of the desirable chains are described below: Examples of perfluoropolyether chain
F{CF(CF₃)—CF₂O)ₙ—
n=6 to 48
   F(CF₂CF₂CF₂O)ₙ—
   n=6 to 48
   -{(CF₂CF₂O)ₘ—(CF₂O)ₙ}-
   m=6 to 28
n=6 to 28

Example of fluoroalkyl chain
H(CₙF₂ₙ)—
n=1 to 16
   Example of perfluoroalkyl chain
   F(CₙF₂ₙ)—
n=1 to 16
   [iii] Binding Site with a Functional Compound

The —X site shown in FIG. 1 represents the site at which the fluorine compound is bound to a functional compound. Examples of the binding site include double bonds, e.g., those in amino, chloro, mercapto, isocyanate, epoxy and vinyl groups. The fluorine compound can be formed into a liquid repellent membrane which changes in liquid repellency in response to various physical stimulations, when bound at this site to a varying residue of a functional compound, e.g., pigment.

Specific examples of —X are described below:

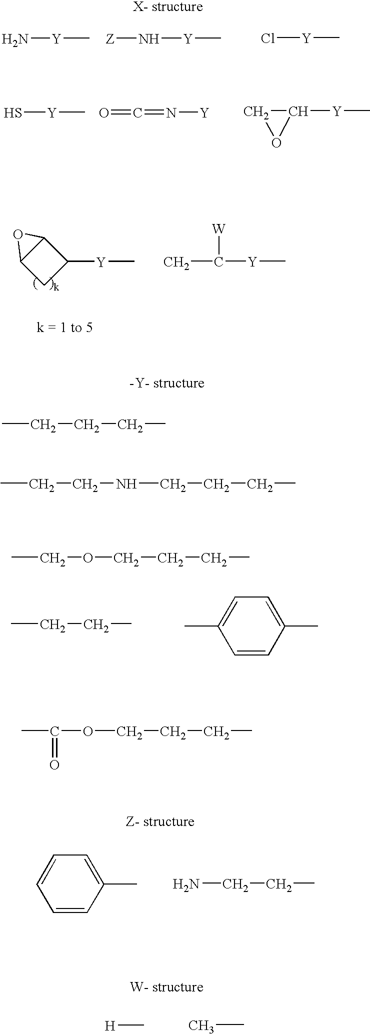

When primary amino group serves as —X, it reacts with a functional compound having chloro group, to bind the fluorine compound to the functional compound, while being transformed into secondary amino group. When secondary amino group serves as —X, it reacts with a functional compound having chloro group, to bind the fluorine compound to the functional compound, while being transformed into tertiary amino group. Moreover, each of these amino groups reacts with a functional compound having carboxyl group, to bind the fluorine compound to the functional compound, while being transformed into amide group. It also reacts with a functional compound having sulfonyl group, to bind the fluorine compound to the functional compound, while being transformed into amide group, as it reacts with a functional compound having carboxyl group.

When primary chloro group serves as —X, it reacts with primary or secondary amino group, to bind the fluorine compound to the functional group.

Similarly, the double bond in mercapto, isocyanate, epoxy or vinyl group reacts with a varying, corresponding residue, to bind the fluorine compound to the functional group.

FIG. 2(a) to (c) schematically illustrates the fluorine compound bound to a functional compound.

The preferable fluorine compounds for the embodiments of the present invention include: 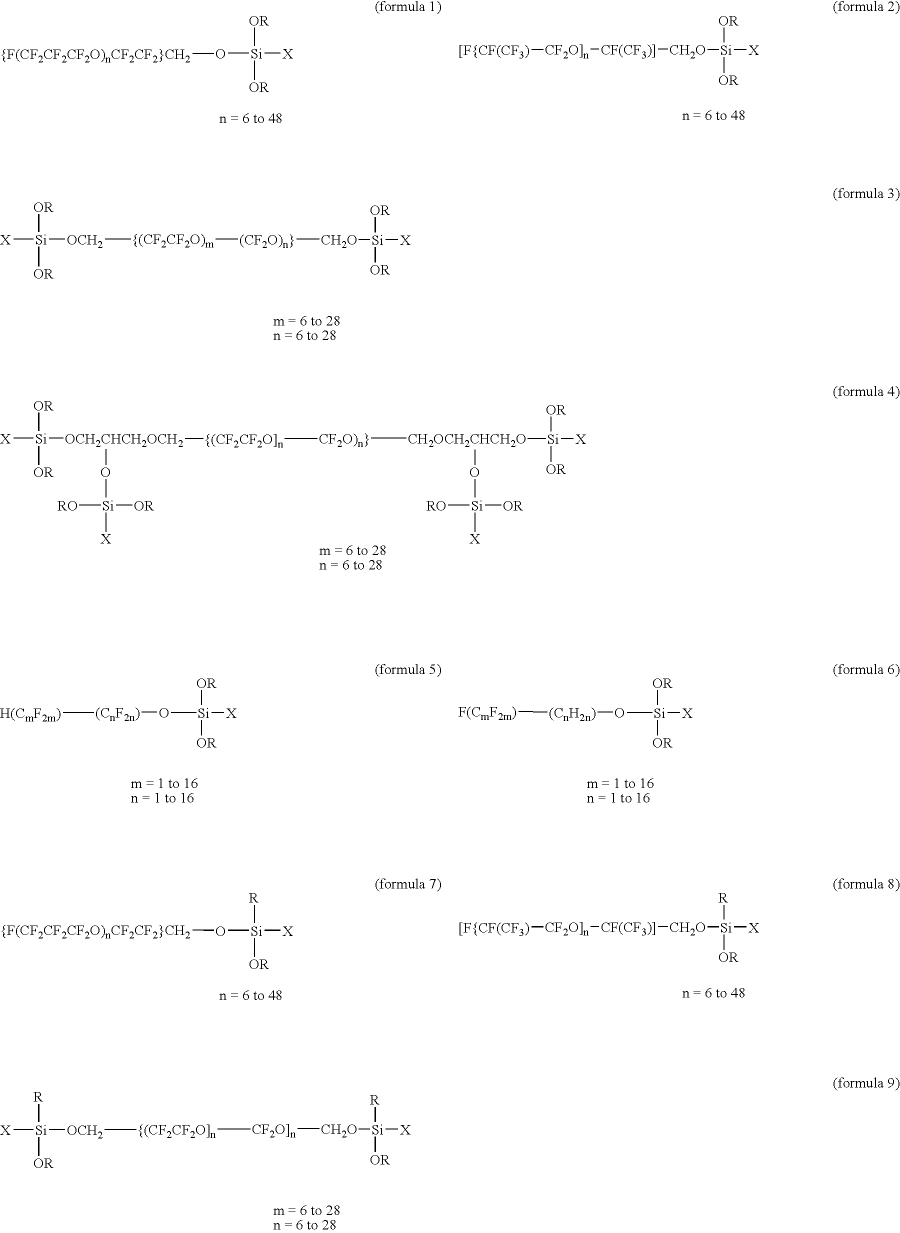 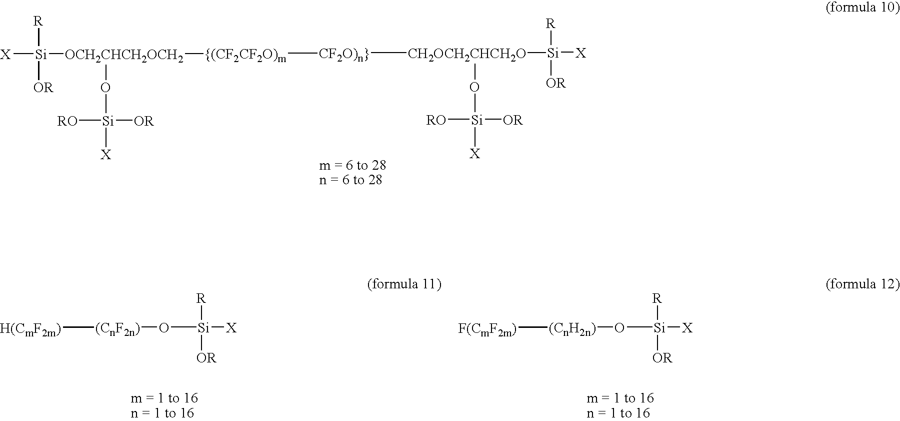
wherein, X is a structure represented by one of the following formulae, and R is an alkyl group of 1 to 4 carbon atoms: 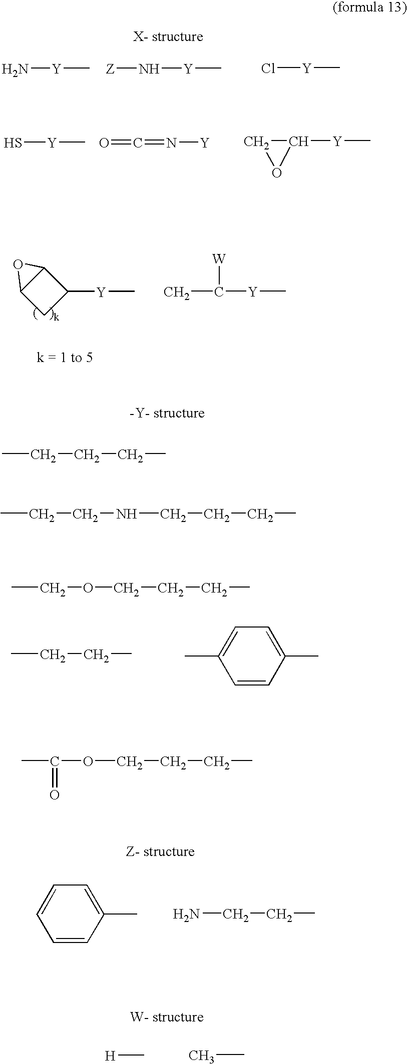
(b) METHOD FOR SYNTHESIZING THE FLUORINE COMPOUND

The fluorine compound for the embodiments of the present invention is synthesized by reacting a compound having a perfluoroalkyl, fluoroalkyl or perfluoropolyether chain, and hydroxyl group at the terminal (Compound α) and silane compound having epoxy, amino or chloro group or the like and 2 or more alkoxy groups (Compound β) to bind these compounds to each other. In other words, hydroxyl group in Compound α and one of alkoxy groups in Compound β to form the oxygen-silicon bond.

More specifically, Compound α and a trace quantity of a catalyst are dissolved in a fluorocarbon solvent, to which Compound β is added, and the mixture is heated with stirring to accelerate the reaction. On completion of the reaction, another fluorocarbon solvent and dichloromethane are added to the reaction solution, and the mixture is further stirred and the allowed to stand. It is separated into two layers. The layer in which the target product is dissolved is separated, and treated to remove the fluorine-based solvents by evaporation to produce the target product.

It is needless to say that the solvent, catalyst and the like are not limited, so long as they give the target product. Some of the solvents useful for the present invention include FLUORINERT (HFE-7100, HFE-7200, PF-5060 and PF-5052, supplied by 3M). The useful catalysts include compounds having a perfluoroalkyl, fluoroalkyl or perfluoropolyether chain, and hydroxyl group at the terminal, like Compound α.

Of the compounds falling into the category of Compound α, those having a perfluoroalkyl or fluoroalkyl chain include 1H, 1H-trifluoroethanol, 1H, 1H-pentafluoropropanol, 6-(pentafluoroethyl)hexanol, 1H, 1H-heptafluorobutanol, 2-(perfluorobutyl)ethanol, 3-(perfluorobutyl)propanol, 6-(perfluorobutyl)hexanol, 2-perfluoropropoxy-2,3,3,3-tetrafluoropropanol, 2-(perfluorohexyl)ethanol, 3-(perfluorohexyl)propanol, 6-(perfluorohexyl)hexanol, 2-(perfluorooctyl)ethanol, 3-(perfluorooctyl)ethanol, 6-(perfluorooctyl)hexanol, 1H, 1H-2,5-di(trifluoromethyl)-3,6-dioxaundecafluorononanol, 6-(perfluoro-1-methylethyl)hexanol, 2-(perfluoro-3-methylbutyl)ethanol, 2-(perfluoro-5-methylhexyl)ethanol, 2-(perfluoro-7-methyloctyl)ethanol, 1H, 1H, 3H-tetrafluoropropanol, 1H, 1H, 5H-octafluoropentanol, 1H, 1H, 7H-dodecafluoroheptanol, 1H, 1H, 9H-hexadecafluorononanol, 2H-hexafluoro-2-propanol, 1H, 1H, 3H-hexafluorobutanol, 2,2,3,3,4,4,5,5-octafluorohexane-1,6-diol, 2,2,3,3,4,4,5,5,6,6,7,7-dodecafluoro-1,8-octanediol and 2,2-bis(trifluoromethyl)propanol.

Of the compounds falling into the category of Compound α, those having a perfluoropolyether chain include DEMNUM SA (Daikin Kogyo), and FOMBRIN Z-DOL AND FOMBRIN Z-TETRAOL (Ausimont).

Of the compounds falling into the category of Compound β, those having amino group include 3-aminopropyltrimethoxysilane, 3-aminopropyltriethoxysilane, N-(2-aminoethyl)-3-aminopropyltrimethoxysilane, N-(2-aminoethyl)-3-aminopropyltriethoxysilane, N-(2-aminoethyl)-3-aminopropylmethyldimethoxysilane and N-phenyl-3-aminopropyltrimethoxysilane.

Of the compounds falling into the category of Compound β, those having chloro group include 3-chloropropyltrimethoxysilane, 3-chloropropyltriethoxysilane and 3-chloropropylmethyldimethoxysilane.

Of the compounds falling into the category of Compound β, those having mercapto group include 3-mercaptopropyltrimethoxysilane and 3-mercaptopropyltriethoxysilane.

Of the compounds falling into the category of Compound β, those having isocyanate group include 3-isocyanatepropyltriethoxysilane.

Of the compounds falling into the category of Compound β, those having an epoxy group include 3-glycidoxypropyltrimethoxysilane, 3-glycidoxypropyltriethoxysilane, 3-glycidoxypropylmethyldimethoxysilane, 2-(3,4-epoxycyclohexyl)ethyltrimethoxysilane and 2-(3,4-epoxycyclohexyl)ethyltriethoxysilane.

Of the compounds falling into the category of Compound β, those having an alkene unit, e.g., vinyl group, include vinyl trimethoxysilane, vinyl triethoxysilane, 3-methacryloxypropyltrimethoxysilane, vinyl triethoxysilane, 3-methacryloxypropyltriethoxysilane, N-(1,3-dimethylbutylidene)-3-(triethoxysilyl)-1-propaneamine and parastyryltrimethoxysilane.

### (c) SYNTHESIS EXAMPLES

SYNTHESIS EXAMPLES for producing the fluorine compounds for the embodiments of the present invention are described.

### Synthesis Example 1

SYNTHESIS EXAMPLE 1 produced a perfluoropolyether (Compound 1, represented by the following formula) with epoxy group as X.

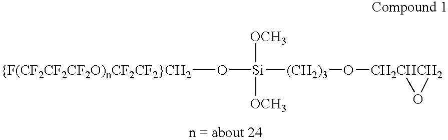

First, 10 parts by weight of DEMNUM SA (Daikin Kogyo, average molecular weight: 4000) and 0.1 parts by weight of DEMNUM SH (Daikin Kogyo, average molecular weight: 4000) were dissolved in 50 parts by weight of HFE-7200 (3M), to which 2 parts by weight of 3-glycidoxypropyltrimethoxysilane was added, and the mixture was stirred at 80° C. for 10 minutes. HFE-7200 was evaporated essentially totally during the stirring period. Next, the mixture was stirred at 100° C. for 4 hours, and cooled to normal temperature. The resulting residue was incorporated with 200 parts by weight of PF-5060 (3M) and 200 parts by weight of dichloromethane, and stirred. The mixture was separated into two phases in a couple of hours after it was allowed to stand. The lower phase was separated 24 hours after it was allowed to stand, and treated to remove PF-5060 as a solvent by evaporation. This produced 9 parts by weight of Compound 1.

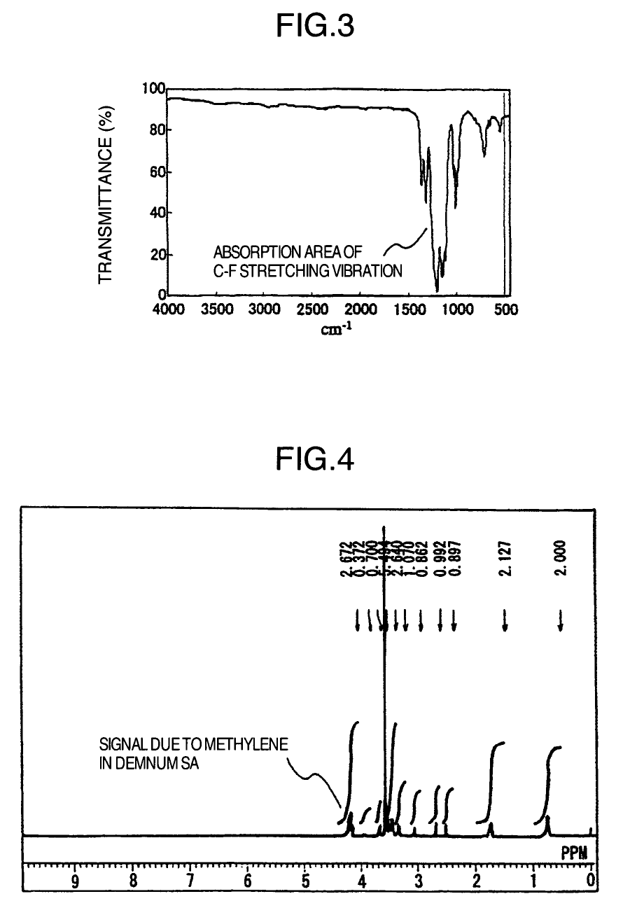

FIG. 3 presents an infrared (IR) spectral pattern of Compound 1, showing an absorption peak at around 1200 cm⁻¹, which is conceivably due to the C—F stretching vibration.

FIG. 4 presents a proton nuclear magnetic resonance (¹H-NMR) pattern of Compound 1, showing a signal at around 4.2 ppm, which is conceivably due to methylene in DEMNUM SA. The other signals are conceivably due to 3-glycidoxypropyltrimethoxysilane. It is bound to DEMNUM SA to lose one of its 3 methoxy groups, with the result that intensity due to methoxy group at around 3.6 ppm is decreased to about ⅔.

Thus, Compound 1 was synthesized.

### Synthesis Example 2

SYNTHESIS EXAMPLE 2 produced a perfluoropolyether (Compound 2, represented by the following formula) with epoxy group as X.

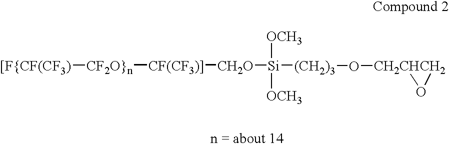

First, 50 parts by weight of KRYTOX 157FS-L (Du Pont, average molecular weight: 2500) was dissolved in 100 parts by weight of HFE-5080 (3M), to which 2 parts by weight of lithium aluminum hydride was added, and the mixture was stirred at 80° C. for 48 hours with stirring. Then, ice water was added to the reaction solution, to separate it into two phases. The lower phase was separated, washed with 1% hydrochloric acid, and washed with water until it became neutral. It was then passed through a filter paper to remove water, and treated to remove PF-5080 by an evaporator, to produce 45 parts by weight of Compound 2′, which was KRYTOX 157FS-L with its terminal converted into CH₂OH.

Then, 10 parts by weight of Compound 2′ was dissolved in 0.1 parts by weight of KRYTOX 157FS-L and 50 parts by weight of HFE-7200 (3M), to which 4 parts by weight of 3-glycidoxypropyltrimethoxysilane was added, and the mixture was stirred at 80° C. for 10 minutes. HFE-7200 was evaporated essentially totally during the stirring period. Next, the mixture was stirred at 100° C. for 4 hours, and cooled to normal temperature. The resulting residue was incorporated with 200 parts by weight of PF-5060 (3M) and 200 parts by weight of dichloromethane, and stirred. The mixture was separated into two phases in a couple of hours after it was allowed to stand. The lower phase was separated 24 hours after it was allowed to stand, and treated to remove PF-5060 as a solvent by evaporation. This produced 9 parts by weight of Compound 2.

Compound 2 was analyzed by infrared absorption spectrometry as in SYNTHESIS EXAMPLE 1. It had an absorption peak at around 1200 cm⁻¹, as was the case with Compound 1, which is conceivably due to the C-F stretching vibration.

It was also analyzed by proton nuclear magnetic resonance (¹H-NMR) spectrometry as in SYNTHESIS EXAMPLE 1. It had a spectral pattern similar to that of Compound 1, except that the signal due to methylene in Compound 2′ was observed at around 3.8 ppm.

Thus, compound 2 was synthesized.

### Synthesis Example 3

SYNTHESIS EXAMPLE 3 produced a perfluoropolyether (Compound 3, represented by the following formula) with epoxy group as X.

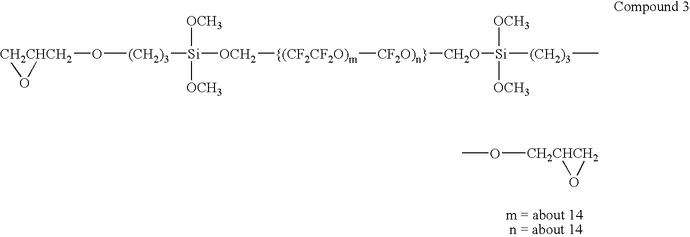

First, 10 parts by weight of FOMBRIN Z-DOL (Ausimont, average molecular weight: 4000) and 0.1 parts by weight of FOMBRIN Z-DIAC (Ausimont, average molecular weight: 4000) were dissolved in 50 parts by weight of HFE-7200 (3M), to which 4 parts by weight of 3-glycidoxypropyltrimethoxysilane was added, and the mixture was stirred at 80° C. for 10 minutes. HFE-7200 was evaporated essentially totally during the stirring period. Next, the mixture was stirred at 100° C. for 4 hours, and cooled to normal temperature. The resulting residue was incorporated with 1000 parts by weight of PF-5060 (3M) and 1000 parts by weight of dichloromethane, and stirred. The mixture was separated into two phases in a couple of hours after it was allowed to stand. The lower phase was separated 24 hours after it was allowed to stand, and treated to remove PF-5060 as a solvent by evaporation. This produced 9 parts by weight of Compound 3.

Compound 3 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a spectral pattern similar to that of Compound 1, except that the signal due to methylene in FOMBRIN Z-DOL was observed at around 3.8 ppm.

Thus, compound 3 was synthesized.

### Synthesis Example 4

SYNTHESIS EXAMPLE 4 produced a perfluoropolyether (Compound 4, represented by the following formula) with epoxy group as X.

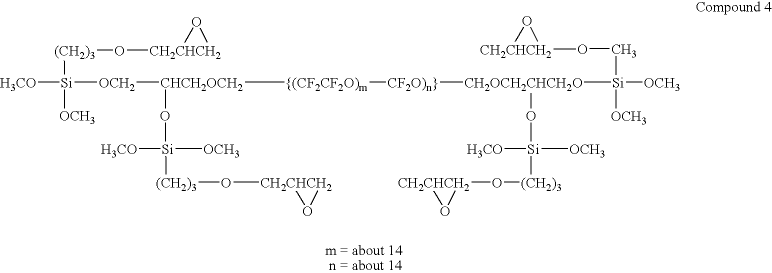

First, 10 parts by weight of FOMBRIN Z-TETRAOL (Ausimont, average molecular weight: 2000) and 0.1 parts by weight of FOMBRIN Z-DIAC (Ausimont, average molecular weight: 4000) were dissolved in 50 parts by weight of HFE-7200 (3M), to which 8 parts by weight of 3-glycidoxypropyltrimethoxysilane was added, and the mixture was stirred at 80° C. for 10 minutes. HFE-7200 was evaporated essentially totally during the stirring period. Next, the mixture was stirred at 100° C. for 4 hours, and cooled to normal temperature. The resulting residue was incorporated with 1000 parts by weight of PF-5060 (3M) and 1000 parts by weight of dichloromethane, and stirred. The mixture was separated into two phases in a couple of hours after it was allowed to stand. The lower phase was separated 72 hours after it was allowed to stand, and treated to remove PF-5060 as a solvent by evaporation. This produced 50 parts by weight of Compound 4.

Compound 4 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a spectral pattern similar to that of Compound 1, except that the signals due to methylene in 2-(perfluorodecyl)ethanol were observed at around 4 and 2 ppm.

Thus, compound 4 was synthesized.

### Synthesis Example 5

SYNTHESIS EXAMPLE 5 produced a fluoroalkyl compound (Compound 5, represented by the following formula) with epoxy group as X.

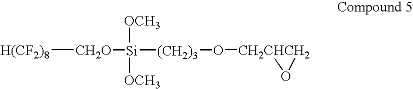

First, 43 parts by weight of 1H, 1H, 9H-hexadecafluorononal (Daikin Kogyo, molecular weight: 432.09) was dissolved in 100 parts by weight of HFE-7200 (3M), to which 40 parts by weight of 3-glycidoxypropyltrimethoxysilane was added, and the mixture was stirred at 80° C. for 10 minutes. HFE-7200 was evaporated essentially totally during the stirring period. Next, the mixture was heated at 100° C. for 4 hours, and cooled to normal temperature. The resulting residue was incorporated with 1000 parts by weight of PF-5060 (3M) and 1000 parts by weight of dichloromethane, and stirred. The mixture was separated into two phases in a couple of hours after it was allowed to stand. The lower phase was separated 72 hours after it was allowed to stand, and treated to remove PF-5060 as a solvent by evaporation. This produced 40 parts by weight of Compound 5.

Compound 5 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a spectral pattern similar to that of Compound 1, except that the signal due to methylene in 1H, 1H, 9H-hexadecafluorononal was observed at around 4 ppm.

Thus, compound 5 was synthesized.

### Synthesis Example 6

SYNTHESIS EXAMPLE 6 produced a perfluoroalkyl compound (Compound 6, represented by the following formula) with epoxy group as X.

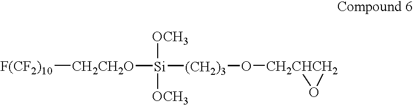

First, 56 parts by weight of 2-(perfluorodecyl)ethanol (Daikin Kogyo, molecular weight: 564.12) was dissolved in 100 parts by weight of HFE-7200 (3M), to which 40 parts by weight of 3-glycidoxypropyltrimethoxysilane was added, and the mixture was stirred at 80° C. for 10 minutes. HFE-7200 was evaporated essentially totally during the stirring period. Next, the mixture was heated at 100° C. for 4 hours, and cooled to normal temperature. The resulting residue was incorporated with 1000 parts by weight of PF-5060 (3M) and 1000 parts by weight of dichloromethane, and stirred. The mixture was separated into two phases in a couple of hours after it was allowed to stand. The lower phase was separated 72 hours after it was allowed to stand, and treated to remove PF-5060 as a solvent by evaporation. This produced 50 parts by weight of Compound 6.

Compound 6 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a spectral pattern similar to that of Compound 1, except that the signals due to methylene in 2-(perfluorodecyl)ethanol were observed at around 4 and 2 ppm.

Thus, compound 6 was synthesized.

### Synthesis Example 7

SYNTHESIS EXAMPLE 7 produced a perfluoropolyether compound (Compound 7, represented by the following formula) with epoxy group as X.

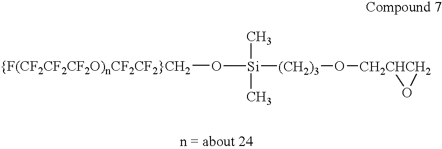

In SYNTHESIS EXAMPLE 7, 9 parts by weight of Compound 7 was synthesized in the same manner as in SYNTHESIS EXAMPLE 1, except that 2 parts by weight of 3-glycidoxypropyltrimethoxysilane was replaced by 2 parts by weight of 3-glycidoxypropylmethyldimethoxysilane.

Compound 7 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a spectral pattern similar to that of Compound 1, except that the signal due to methoxy group observed at around 3.6 ppm was halved (conceivably because one of two methoxy groups responsible for the signal disappeared) and that the signal due to methylene bound to Si was instead observed at around 2.5 ppm.

Thus, compound 7 was synthesized.

### Synthesis Example 8

SYNTHESIS EXAMPLE 8 produced a perfluoropolyether compound (Compound 8, represented by the following formula) with epoxy group as X.

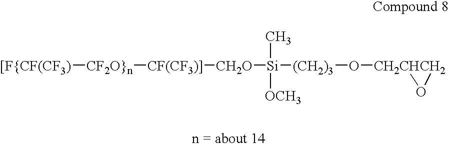

In SYNTHESIS EXAMPLE 8, 9 parts by weight of Compound 8 was synthesized in the same manner as in SYNTHESIS EXAMPLE 2, except that 4 parts by weight of 3-glycidoxypropyltrimethoxysilane was replaced by 4 parts by weight of 3-glycidoxypropylmethyldimethoxysilane.

Compound 8 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 2. It had a spectral pattern similar to that of Compound 2, except that the signal due to methoxy group observed at around 3.6 ppm was halved (conceivably because one of two methoxy groups responsible for the signal disappeared) and that the signal due to methylene bound to Si was instead observed at around 2.5 ppm.

Thus, compound 8 was synthesized.

### Synthesis Example 9

SYNTHESIS EXAMPLE 9 produced a perfluoropolyether compound (Compound 9, represented by the following formula) with epoxy group as X.

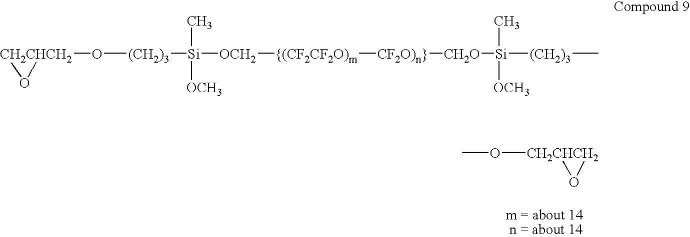

In SYNTHESIS EXAMPLE 9, 9 parts by weight of Compound 9 was synthesized in the same manner as in SYNTHESIS EXAMPLE 3, except that 4 parts by weight of 3-glycidoxypropyltrimethoxysilane was replaced by 4 parts by weight of 3-glycidoxypropylmethyldimethoxysilane.

Compound 9 was analyzed by infrared absorption spectrometry as in SYNTHESIS EXAMPLE 3. It had an absorption peak at around 1200 cm⁻¹, as was the case with Compound 3, which is conceivably due to the C—F stretching vibration.

It was also analyzed by proton nuclear magnetic resonance (¹H-NMR) spectrometry as in SYNTHESIS EXAMPLE 3. It had a spectral pattern similar to that of Compound 3, except that the signal due to methoxy group observed at around 3.6 ppm was halved (conceivably because one of two methoxy groups responsible for the signal disappeared) and that the signal due to methylene bound to Si was instead observed at around 2.5 ppm.

Thus, compound 9 was synthesized.

### Synthesis Example 10

SYNTHESIS EXAMPLE 10 produced a perfluoropolyether compound (Compound 10, represented by the following formula) with epoxy group as X.

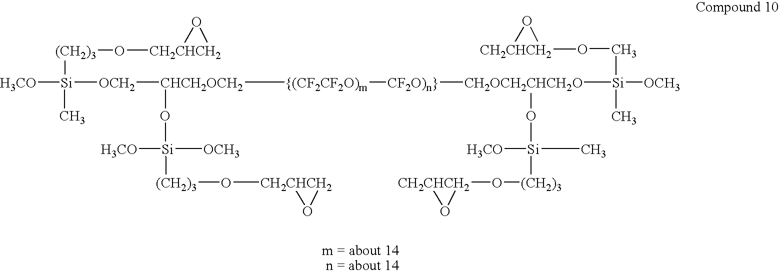

In SYNTHESIS EXAMPLE 10, 8 parts by weight of Compound 10 was synthesized in the same manner as in SYNTHESIS EXAMPLE 4, except that 8 parts by weight of 3-glycidoxypropyltrimethoxysilane was replaced by 8 parts by weight of 3-glycidoxypropylmethyldimethoxysilane.

Compound 10 was analyzed by infrared absorption spectrometry as in SYNTHESIS EXAMPLE 4. It had an absorption peak at around 1200 cm⁻¹, as was the case with Compound 4, which is conceivably due to the C—F stretching vibration.

It was also analyzed by proton nuclear magnetic resonance (¹H-NMR) spectrometry as in SYNTHESIS EXAMPLE 4. It had a spectral pattern similar to that of Compound 4, except that the signal due to methoxy group observed at around 3.6 ppm was halved (conceivably because one of two methoxy groups responsible for the signal disappeared) and that the signal due to methylene bound to Si was instead observed at around 2.5 ppm.

Thus, compound 10 was synthesized.

### Synthesis Example 11

SYNTHESIS EXAMPLE 11 produced a fluoroalkyl compound (Compound 11, represented by the following formula) with epoxy group as X.

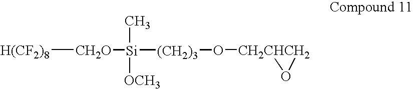

In SYNTHESIS EXAMPLE 11, 40 parts by weight of Compound 11 was synthesized in the same manner as in SYNTHESIS EXAMPLE 5, except that 40 parts by weight of 3-glycidoxypropyltrimethoxysilane was replaced by 40 parts by weight of 3-glycidoxypropylmethyldimethoxysilane.

Compound 11 was analyzed by infrared absorption spectrometry as in SYNTHESIS EXAMPLE 5. It had an absorption peak at around 1200 cm⁻¹, as was the case with Compound 5, which is conceivably due to the C—F stretching vibration.

It was also analyzed by proton nuclear magnetic resonance (¹H-NMR) spectrometry as in SYNTHESIS EXAMPLE 5. It had a spectral pattern similar to that of Compound 5, except that the signal due to methoxy group observed at around 3.6 ppm was halved (conceivably because one of two methoxy groups responsible for the signal disappeared) and that the signal due to methylene bound to Si was instead observed at around 2. 5 ppm.

Thus, compound 11 was synthesized.

### Synthesis Example 12

SYNTHESIS EXAMPLE 12 produced a fluoroalkyl compound (Compound 12, represented by the following formula) with epoxy group as X.

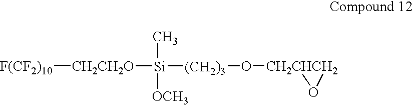

In SYNTHESIS EXAMPLE 12, 50 parts by weight of Compound 12 was synthesized in the same manner as in SYNTHESIS EXAMPLE 6, except that 40 parts by weight of 3-glycidoxypropyltrimethoxysilane was replaced by 40 parts by weight of 3-glycidoxypropylmethyldimethoxysilane.

Compound 12 was analyzed by infrared absorption spectrometry as in SYNTHESIS EXAMPLE 6. It had an absorption peak at around 1200 cm⁻¹, as was the case with Compound 6, which is conceivably due to the C—F stretching vibration.

It was also analyzed by proton nuclear magnetic resonance (¹H-NMR) spectrometry as in SYNTHESIS EXAMPLE 6. It had a spectral pattern similar to that of Compound 6, except that the signal due to methoxy group observed at around 3.6 ppm was halved (conceivably because one of two methoxy groups responsible for the signal disappeared) and that the signal due to methylene bound to Si was instead observed at around 2.5 ppm.

Thus, compound 12 was synthesized.

### Synthesis Example 13

SYNTHESIS EXAMPLE 13 produced a perfluoropolyether compound (Compound 13, represented by the following formula) with epoxy group as X.

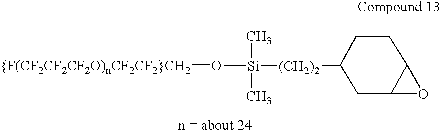

In SYNTHESIS EXAMPLE 13, 9 parts by weight of Compound 13 was synthesized in the same manner as in SYNTHESIS EXAMPLE 1, except that 2 parts by weight of 3-glycidoxypropyltrimethoxysilane was replaced by 2 parts by weight of 2-(3,4-epoxycyclohexyl)ethyltrimethoxysilane.

Compound 13 was analyzed by infrared absorption spectrometry as in SYNTHESIS EXAMPLE 1. It had an absorption peak at around 1200 cm⁻¹, as was the case with Compound 6, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to 2-(3,4-epoxycyclohexyl)ethyltrimethoxysilane. It is bound to DEMNUM SA to lose one of its 3 methoxy groups, with the result that intensity due to methoxy group at around 3.6 ppm is decreased to about ⅔.

Thus, compound 13 was synthesized.

### Synthesis Example 14)

SYNTHESIS EXAMPLE 14 produced a perfluoropolyether compound (Compound 14, represented by the following formula) with epoxy group as X.

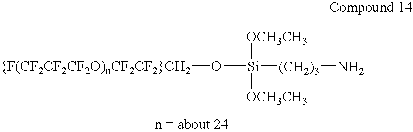

In SYNTHESIS EXAMPLE 14, 8 parts by weight of Compound 14 was synthesized in the same manner as in SYNTHESIS EXAMPLE 1, except that 2 parts by weight of 3-glycidoxypropyltrimethoxysilane was replaced by 2 parts by weight of 3-aminopropyltriethoxysilane.

Compound 14 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to 3-aminopropyltriethoxysilane. It is bound to DEMNUM SA to lose one of its 3 ethoxy groups, with the result that each intensity due to methoxy group at around 3.6 and 1 ppm is decreased to about ⅔.

Thus, compound 14 was synthesized.

### Synthesis Example 15

SYNTHESIS EXAMPLE 15 produced a perfluoropolyether compound (Compound 15, represented by the following formula) with epoxy group as X.

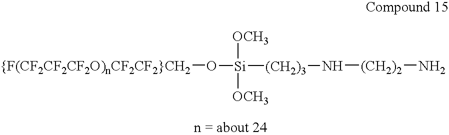

In SYNTHESIS EXAMPLE 15, 8 parts by weight of Compound 15 was synthesized in the same manner as in SYNTHESIS EXAMPLE 1, except that 2 parts by weight of 3-glycidoxypropyltrimethoxysilane was replaced by 2 parts by weight of N-(2-aminoethyl)-3-aminopropyltrimethoxysilane.

Compound 15 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to N-(2-aminoethyl)-3-aminopropyltrimethoxysilane. It is bound to DEMNUM SA to lose one of its 3 methoxy groups, with the result that intensity due to methoxy group at around 3.6 ppm is decreased to about ⅔.

Thus, compound 15 was synthesized.

### Synthesis Example 16

SYNTHESIS EXAMPLE 16 produced a perfluoropolyether compound (Compound 16, represented by the following formula) with epoxy group as X.

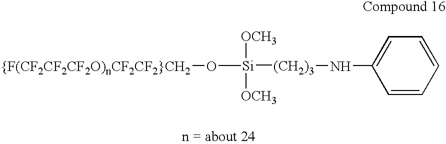

In SYNTHESIS EXAMPLE 16, 8 parts by weight of Compound 16 was synthesized in the same manner as in SYNTHESIS EXAMPLE 1, except that 2 parts by weight of 3-glycidoxypropyltrimethoxysilane was replaced by 2 parts by weight of N-phenyl-3-aminopropyltrimethoxysilane.

Compound 16 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to N-phenyl-3-aminopropyltrimethoxysilane. It is bound to DEMNUM SA to lose one of its 3 methoxy groups, with the result that intensity due to methoxy group at around 3.6 ppm is decreased to about ⅔.

Thus, compound 16 was synthesized.

### Synthesis Example 17

SYNTHESIS EXAMPLE 17 produced a perfluoropolyether compound (Compound 17, represented by the following formula) with chloro group as X.

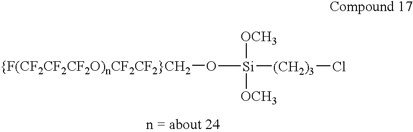

In SYNTHESIS EXAMPLE 17, 8 parts by weight of Compound 17 was synthesized in the same manner as in SYNTHESIS EXAMPLE 1, except that 2 parts by weight of 3-glycidoxypropyltrimethoxysilane was replaced by 2 parts by weight of 3-chloropropyltrimethoxysilane.

Compound 17 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to 3-chloropropyltrimethoxysilane. It is bound to DEMNUM SA to lose one of its 3 methoxy groups, with the result that intensity due to methoxy group at around 3.6 ppm is decreased to about ⅔.

Thus, compound 17 was synthesized.

### Synthesis Example 18

SYNTHESIS EXAMPLE 18 produced a perfluoropolyether compound (Compound 18, represented by the following formula) with mercapto group as X.

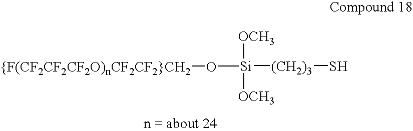

In SYNTHESIS EXAMPLE 18, 8 parts by weight of Compound 18 was synthesized in the same manner as in SYNTHESIS EXAMPLE 1, except that 2 parts by weight of 3-glycidoxypropyltrimethoxysilane was replaced by 2 parts by weight of 3-mercaptopropyltrimethoxysilane.

Compound 18 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to 3-mercaptopropyltrimethoxysilane. It is bound to DEMNUM SA to lose one of its 3 methoxy groups, with the result that intensity due to methoxy group at around 3.6 ppm is decreased to about ⅔.

Thus, compound 18 was synthesized.

### Synthesis Example 19

SYNTHESIS EXAMPLE 19 produced a perfluoropolyether compound (Compound 19, represented by the following formula) with isocyanate group as X.

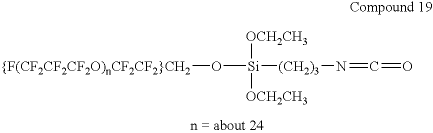

In SYNTHESIS EXAMPLE 19, 8 parts by weight of Compound 19 was synthesized in the same manner as in SYNTHESIS EXAMPLE 1, except that 2 parts by weight of 3-glycidoxypropyltrimethoxysilane was replaced by 2 parts by weight of 3-isocyanate(propyltrimethoxysilane).

Compound 19 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to3-isocyanate(propyltrimethoxysilane). It is bound to DEMNUM SA to lose one of its 3 methoxy groups, with the result that each intensity due to methoxy group at around 3.6 and 1 ppm is decreased to about ⅔.

Thus, compound 19 was synthesized.

### Synthesis Example 20

SYNTHESIS EXAMPLE 20 produced a perfluoropolyether compound (Compound 20, represented by the following formula) with an alkene unit as X.

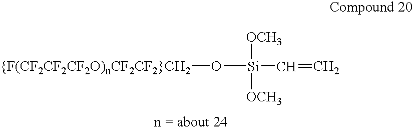

In SYNTHESIS EXAMPLE 20, 8 parts by weight of Compound 20 was synthesized in the same manner as in SYNTHESIS EXAMPLE 1, except that 2 parts by weight of 3-glycidoxypropyltrimethoxysilane was replaced by 2 parts by weight of vinyl trimethoxysilane.

Compound 20 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to vinyl trimethoxysilane. It is bound to DEMNUM SA to lose one of its 3 methoxy groups, with the result that intensity due to methoxy group at around 3.6 ppm is decreased to about ⅔.

Thus, compound 20 was synthesized.

### Synthesis Example 21

SYNTHESIS EXAMPLE 21 produced a perfluoropolyether compound (Compound 21, represented by the following formula) with an alkene unit as X.

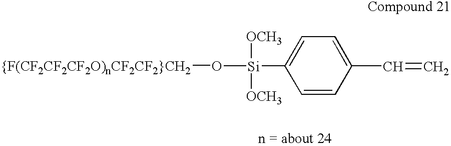

In SYNTHESIS EXAMPLE 21, 8 parts by weight of Compound 21 was synthesized in the same manner as in SYNTHESIS EXAMPLE 1, except that 2 parts by weight of 3-glycidoxypropyltrimethoxysilane was replaced by 2 parts by weight of p-styrylpropyltrimethoxysilane.

Compound 21 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to p-styrylpropyltrimethoxysilane. It is bound to DEMNUM SA to lose one of its 3 methoxy groups, with the result that each of intensities due to methoxy group at around 3.6 ppm are decreased to about ⅔.

Thus, compound 21 was synthesized.

### Synthesis Example 22

SYNTHESIS EXAMPLE 22 produced a perfluoropolyether compound (Compound 22, represented by the following formula) with an alkene unit as X.

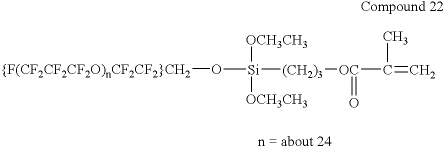

In SYNTHESIS EXAMPLE 22, 8 parts by weight of Compound 22 was synthesized in the same manner as in SYNTHESIS EXAMPLE 1, except that 2 parts by weight of 3-glycidoxypropyltrimethoxysilane was replaced by 2 parts by weight of 3-methacryloxypropyltrimethoxysilane.

Compound 22 was analyzed by infrared absorption spectrometry as in SYNTHESIS EXAMPLE 1. It had an absorption peak at around 1200 cm⁻¹, as was the case with Compound 1, which is conceivably due to the C—F stretching vibration.

It was also analyzed by proton nuclear magnetic resonance (¹H-NMR) spectrometry as in SYNTHESIS EXAMPLE 1. It had a signal at around 4 ppm, which is conceivably due to methylene in DEMNUM SA. The other signals are conceivably due to 3-methacryloxypropyltrimethoxysilane. It is bound to DEMNUM SA to lose one of its 3 methoxy groups, with the result that each of intensities due to methoxy group at around 3.6 ppm are decreased to about ⅔.

Thus, Compound 22 was synthesized.

[B] Liquid Repellent Membrane using the Fluorine Compound

Each of the fluorine compounds described above can be formed into a liquid repellent membrane, because of its liquid repellency. More specifically, it is spread on a board and heated, to be bound to the board. The method for forming the liquid repellent membrane is described.

(a) Selection of Board

The binding site at which the fluorine compound is bound to a board has an alkoxy silane structure. It is therefore necessary for the board to have a residue, e.g., hydroxyl or carboxyl group, which can react with an alkoxy silane structure to form the silicon-oxygen bond.

The boards having an alkoxy silane structure include those of glass or a metal, e.g., iron. Resin boards, e.g., those of a phenol resin, copolymer of a phenol resin with another resin, or polyvinyl alcohol, are useful. Boards of an oxidation-resistant metal (e.g., silver, gold or platinum) are also useful, when the metal is surface-oxidized to some extent with nitric acid, aqua regalis or the like, to improve its reactivity with an alkoxy silane structure.

On the other hand, a board free of a residue capable of forming the silicon-oxygen bond can have hydroxyl group on the surface, when coated with silica-sol or titania-sol and cured under heating to form the silicon oxide or titanium oxide layer thereon. There are other useful procedures to produce hydroxyl group on the board surface. For example, a board may be irradiated with an oxygen plasma, or exposed to an ozone atmosphere, and the resulting oxidized surface is reacted with moisture in air to produce hydroxyl group thereon. Moreover, it may be irradiated with ultraviolet ray to transform oxygen in air into ozone which acts on the board surface to produce hydroxyl group thereon. This is similar in principle to exposing the board to an ozone atmosphere.

The board is not limited in shape, so long as its function of binding a liquid repellent membrane thereto is concerned. It may be a plate in shape, or may have a curved surface or surface irregularities. A plate shape is more preferable in consideration of dispersibility of a solution to be spread thereon.

(b) Binding a Fluorine Compound to Board

First, a solution of one or more of the above-described fluorine compounds dissolved in a solvent is spread on a board, after being diluted. The solvent is preferably based on a fluorine compound. The fluorine-based solvents useful for the present invention include FC-72, PF-5060, PF-5080, HFE-7100 and HFE-7200 (3M), and Vertrel XF (du Pont). It may be spread by any procedure, e.g., dip coating, flow coating, spray coating or the like. It is preferably spread in a clean room, because uniformity of the resulting membrane may be damaged when it is contaminated with dust or the like.

A solution of fluorine compound may be directly spread in bulk. In this case, however, it is necessary to take into consideration possibly increased membrane thickness or decreased membrane physical strength. A fluorine compound is normally bound to a board in a monomolecular film. When a solution of fluorine compound is directly spread in bulk, the compound having no contribution to formation of the membrane bound to the board is massively present, which results in decreased film strength.

The board coated with a solution of fluorine compound is heated by constant-temperature bath, hot plate or the like to bind the compound to the board, preferably at a boiling point of the alcohol produced from the bound alkoxy silane structure or slightly higher (by around 20° C. higher at the highest) for 10 to 20 minutes. The reaction proceeds slowly even at normal temperature, and, when the board used has a low heat resistance temperature, it can be heated at below its heat resistance temperature.

(c) Binding of a Functional Compound

The above-described fluorine compound has a binding site represented by X—, at which it is bound to a functional compound. The liquid repellent membrane can have its liquid repellency easily changed by binding a functional compound, e.g., pigment, to the fluorine compound at the above site.

A functional compound may be bound to the fluorine compound before or after the fluorine compound is bound to a board. However, an alkoxy group is generally more reactive than epoxy, chloro or amino group, and may be degraded by hydrolysis or the like when a functional compound is bound to a board before the fluorine compound. Therefore, a functional group is preferably bound to a board after the fluorine compound. FIG. 2(a) to (c) schematically illustrates the binding process.

The binding structure (silicon-oxygen bond) by which the fluorine compound is bound to a board may be broken in the presence of a strong base. It is therefore recommended to avoid a reaction involving or producing a strong base for binding a functional group to the fluorine compound, or else it is necessary to take an adequate countermeasure, e.g., incorporation of a compound capable of trapping a strong base in the reaction system, or adoption of relatively low reaction temperature, when a strong base is used.

[C] Applicable Areas of the Liquid Repellent Membrane having the Fluorine Compound Bound to a Functional Compound

The liquid repellent membrane composed of the fluorine compound can allow various functional compounds to be bound thereto, and can be controlled for its liquid repellency depending of a function expressed by the bounded functional compound. For example, when the fluorine compound in a liquid repellent membrane has amino group, the amino group itself may be transformed into an ammonium salt structure depending on pH level of a liquid with which it comes into contact, to control liquid repellency of the membrane as well as a functional compound. Examples of controlling liquid repellency by pH level of a liquid with which the fluorine compound comes into contact and by light are described below. Liquid repellency can be controlled by other procedures. For example, binding a host compound, e.g., enzyme or cyclodextrin, can control liquid repellency varying depending on characteristics of the corresponding guest compound.

(a) Examples of Controlling Liquid Repellency by pH (Application to pH Sensors)

A liquid repellent membrane having amino group was prepared by acting the fluorine compound having amino group on a carbon electrode or the like. It was found, when the electrode was immersed in an aqueous solution of varying pH level and measured for its contact angle after it was washed with water, that its contact angle decreased as the pH level decreased. Especially, a lowering of the contact angle is remarkable in the case of immersing in an aqueous solution having a lower pH. This conceivably results from the amino group being transformed into an ammonium salt structure when immersed in a low pH aqueous solution, to have enhanced wettability and consequently to decrease liquid repellency of the membrane. The amino group is transformed into an ammonium salt structure at an accelerating rate as pH level of the aqueous solution decreases to decrease the contact angle more notably. This phenomenon can make the membrane applicable to a pH sensor.

(b) Examples of controlling liquid repellency by light (application to electrical board, semiconductor device, color filter or the like)

An electrical board can be prepared by coating a board with a liquid repellent membrane, irradiating the coated board with light to control (decrease) liquid repellency of part of the membrane, depositing a solution containing an electroconductive metal (e.g., suspension or plating solution containing an electroconductive metal) selectively on the portion of decreased liquid repellency, and heating the treated membrane to remove the medium of dispersion by evaporation and thereby to deposit the fine metal particles on the board. A display device can be prepared by using a “solution capable of forming an insulation, semiconducting or light emission layer, or the like” in place of the “solution containing an electroconductive metal.” Moreover, a color filter board can be prepared by using a “solution capable of forming a red, green or blue color,” e.g., a solution dissolving or dispersing a resin and pigment or colorant (resin may be omitted when a colorant is of a high-molecular-weight compound) in place of the “solution containing an electroconductive metal.”

The principle of and procedure for reducing liquid repellency by the aid of light are described below. It is decreased by the steps [i] to [iii], described below.

[i] A colorant which absorbs light is bound as a functional compound to a liquid repellent membrane.

[ii] When the liquid repellent membrane is irradiated with light, the colorant bound to the membrane absorbs light, and converts the light energy into heat energy. In other words, it absorbs light to generate heat.

[iii] The fluorine compound which constitutes the liquid repellent membrane is thermally decomposed by the heat generated. In other words, the liquid repellent membrane portion exhibiting liquid repellency is also decomposed, resulting in decreased liquid repellency.

When light for irradiating the liquid repellent membrane cannot have a sufficient intensity, it is an effective procedure to heat the membrane beforehand. When it is heated to close to its thermal decomposition temperature before being irradiated with light, the heat energy for its decomposition can be saved. As a result, light of low intensity can decompose the membrane and consequently decrease its liquid repellency.

(c) Methods for Producing Various Products

[i] Enhancing Board and its Surface Hydrophilicity

A light-irradiated liquid repellent membrane can have improved wettability (enhanced hydrophilicity) when a board is treated to be hydrophilic before it is coated with the membrane. It is preferable to adopt this treatment, because it promotes deposition of a suspension of fine, electroconductive metal particles and makes the resulting electrical lines more adhesive to the board.

Various materials are useful for the board which supports the membrane. These materials include glass, quartz, silicon, and resin which may contain glass particles.

A board of glass, quartz or silicon can have enhanced hydrophilicity, when treated with an oxygen plasma or immersed in a basic solution, among others. Treatment with an oxygen plasma can decrease contact angle of the board surface to 10° or less with water, when carried out under the conditions of oxygen partial pressure: 1 Torr, rf power source output: 300W and treatment time: 3 minutes. The board surface can also have enhanced hydrophilicity when treated with ozone. Irradiation of the surface with ultraviolet ray can transform oxygen in the vicinity of the surface into ozone, which can be used for the surface treatment. Exposing the surface to an ozone atmosphere generated by an ozone generator is also effective for enhancing surface hydrophilicity. Moreover, the board can have a contact angle decreased to 20° or less with water, when immersed in a 1% by weight aqueous solution of sodium hydroxide as a basic solution for 5 minutes.

A resin board can also have enhanced hydrophilicity, when treated with an oxygen plasma or immersed in a basic solution, among others. For the board of polystyrene, acrylic resin, styrene/acrylic resin, polyester resin, acetal resin, polycarbonate, polyether sulfone, polysulfone or the like, treatment with an oxygen plasma can decrease contact angle of the surface to 20° or less with water, when carried out under the conditions of oxygen partial pressure: 1 Torr, rf power source output: 100W and treatment time: 1 minute. The board surface can also have enhanced hydrophilicity when irradiated with ultraviolet ray to transform oxygen in the vicinity of the surface into ozone, as is the case with a board of glass, quartz or silicon. Exposing the surface to an ozone atmosphere generated by an ozone generator is also effective for enhancing surface hydrophilicity. Immersion in a basic solution is also useful for enhancing surface hydrophilicity, in particular for a board of resin having an ester bond in the molecular structure, e.g., acrylic resin, styrene/acrylic resin, polyester resin, acetal resin or polycarbonate. This is because a highly hydrophilic carboxylic acid residue and/or hydroxyl group is formed when the ester bond is broken on or in the vicinity of the surface, to enhance surface hydrophilicity. A board of resin produced by condensation of amino group in polyimide, polyamide or the like and carboxylic acid can have enhanced hydrophilicity, when immersed in an acidic solution, e.g., hydrochloric acid, to transform the unreacted amino group remaining in the resin into a highly hydrophilic ammonium salt structure, or when immersed in an aqueous solution of sodium hydroxide to transform the unreacted carboxylic group remaining in the resin into a highly hydrophilic carboxylate, to enhance surface hydrophilicity. Immersion in an acidic or basic solution tends to enhance surface hydrophilicity faster as solution temperature or concentration increases. However, care shall be taken when solution temperature or concentration is increased, because it may be accompanied by increased board damages.

The other useful procedures for enhancing surface hydrophilicity include covering a board with a coating solution which can exhibit hydrophilicity to form a hydrophilic membrane thereon. This procedure is applicable to a board whether it is of a metal, glass or resin. These solutions include, but not limited to, <α> to <ε>, described below. <α> Solution of a Water-Soluble High-Molecular-Weight Compound

The solutions falling into this category include those of a high-molecular-weight compound having a hydrophilic residue, e.g., hydroxyl, amino, carboxyl and a residue of salt structure, more specifically, polyethylene glycol, polyvinyl alcohol, polyacrylic acid and a salt thereof, polyallylamine and polyallyammonium chloride, and starch. Of these, polyethylene glycol in particular can decrease contact angle of a board. Moreover, it is also soluble in organic solvents, e.g., tetrahydrofuran, and can more decrease surface tension of the solution, when dissolved in an organic solvent than in water. Therefore, polyethylene glycol dissolved in an organic solvent is suitable for coating a liquid repellent surface, e.g., aluminum surface. The high-molecular-weight compound of higher molecular weight is more useful, because it can give a smoother hydrophilic membrane of lower light scattering.

The high-molecular-weight compound solution can give a hydrophilic coating membrane, when spread on a board and dried, whether it is dissolved in water or an organic solvent.

It may be difficult to form a smooth membrane on a highly liquid repellent surface, because the coating solution may be repelled by the surface, resulting from increased surface tension of the solution when water is used as the solvent. In such a case, treatment of the surface with an oxygen plasma beforehand facilitates formation of a smooth coating membrane thereon, and hence is an effective procedure for forming a hydrophilic membrane.

<β> Coating Solution Containing Hydrophilic Particles

The coating solutions falling into this category include mixtures of a dispersion solution containing hydrophilic alumina or silica particles and a solution containing an alkoxy silane, used as coating solutions. The coating solution can give a hydrophilic membrane, when spread on a board and then treated under heating. The hydrophilic alumina or silica particles in the solution are mainly responsible for the hydrophilicity, and the alkoxy silane mainly works to support these particles. Increasing content of these particles can increase membrane hydrophilicity, and increasing content of the alkoxy silane can increase physical properties of the membrane. The alkoxy silane is preferably crosslinked between the molecules to some extent, because of decreased loss by evaporation while the membrane is treated under heating. The alkoxy silane may be incorporated with hydrochloric acid or the like to accelerate inter-molecular polymerization, and the dispersion of hydrophilic silica particles may be kept basic to improve their dispersibility. It is therefore necessary to closely watch pH level of the solution and dispersed conditions of the hydrophilic silica particles, when they are mixed with each other, because the particles may agglomerate each other. The alumina particles cause less mixing-caused problems, because the dispersion is acidic in most cases, and are more useful in this sense. The alkoxy silanes useful for the present invention include methyltrimethoxy silane, ethyltrimethoxy silane, butyltrimethoxy silane, methyltriethoxy silane, ethyltriethoxy silane, butyltriethoxy silane, tetramethoxy silane and tetraethoxy silane. An alkoxy titanium compound may replace an alkoxy silane, if the pH and solvent conditions are met. These titanium compounds possibly used for the present invention include tetra-iso-propyl titanate, tetra-n-butyl titanate, tetrastearyl titanate, triethanolamine titanate, titanium acetylacetonate, titanium lactate and tetraoctyleneglycol titanate. Oligomers of these compounds (polymers of these several compounds) can be also used.

<γ> Coating Solution Containing a Water-Soluble High-Molecular-Weight Compound and Crosslinking Agent Therefor

A coating solution capable of forming a hydrophilic membrane can be produced by mixing the high-molecular-weight compound <α> and alkoxy silane or alkoxy titanium compound <β> as a crosslinking agent. Water may be used as a solvent for the solution, but the resulting coating solution may be repelled by a cell board surface when it is highly liquid repellent. Therefore, an alcohol-based solvent, e.g., methanol or ethanol, is more suitable.

<ε> Combination of an Alkoxy Silane and Alkaline Solutions

A coating membrane of silicon oxide can be formed, when the alkoxy silane solution <β> is spread on a board and heated at around 120 to 180° C. for a couple of minutes. It has a surface of enhanced hydrophilicity, when immersed in an alkaline solution and then washed with water. The alkaline solutions useful for the present invention include an aqueous solution of hydroxide, e.g., sodium or potassium hydroxide, alcohol solution, and alcohol-containing solution. The solution of higher concentration is more useful, viewed from shortened immersion time, which varies depending on hydroxide type. Suitable immersion time is 1 to 5 minutes with a 1% by weight sodium hydroxide solution, and 10 to 30 seconds with a 5% by weight solution. The solvents useful for dissolving an alkoxy silane are alcohol-, ester- and ether-based ones. A ketone-based solvent (acetone, methylethylketone or the like) tends to convert an alkoxy silane into silicon dioxide. An alcohol-based solvent is particularly suitable for a resin board, because it dissolves a resin only sparingly.

[ii] Light Source

Light with which part of the liquid repellent membrane is irradiated to decrease liquid repellency on that part should have a wavelength at which a colorant is bound to the membrane. The light source is not limited, and may be a lamp or laser. The light is preferably absorbed efficiently and converted into heat for heating the liquid repellent membrane.

When a colorant to be bound to the liquid repellent membrane has a broad absorption spectral pattern extending to the near-ultraviolet to near-infrared regions, the preferable choice is a xenon lamp or the like, which emits light of a broader wavelength range than a laser or mercury lamp emitting light of more specific wavelengths. So is vice versa, when it has a narrower absorption spectral pattern, a laser emitting light of its absorption wavelength is a preferable choice.

A mercury lamp is also effective for a colorant having an absorption spectral pattern in the near-ultraviolet region, because it emits light of specific wavelengths, like a laser. More specifically, a mercury lamp can emit light of 254 nm, 365 nm (I line) and 435 nm (G line) in the visible region. A low-voltage mercury lamp can also emit light of 185 nm. The light of these wavelengths is absorbed by oxygen to generate ozone, which may also decompose the liquid repellent sites in a liquid repellent membrane to damage its liquid repellency. Ozone, when generated, may make fine works (e.g., for producing electrical patterns of high precision) difficult, because it is gaseous and can diffuse to a board surface or in the vicinity thereof. In the fluorine compound of the present invention containing the above-described functional compound, on the other hand, a coloring material providing the light-absorbing sites, each of which has an absorption in the visible light region and can be visually recognized as a color, converts light energy into heat energy to thermally decompose part of the water-repellent sites, or decompose by selectively giving the heat to the molecules to be decomposed. As a result, it allows fine works, e.g., those for producing electrical patterns of high precision. Therefore, this effect is more notably demonstrated by using ultraviolet ray having a wavelength capable of generating ozone.

The wavelengths available by lasers are 415, 488 and 515 nm by an argon laser, 532, 355 and 266 nm as double, triple and quadruple waves by a YAG laser, 337 nm by a nitrogen laser, 633 nm by a helium/neon laser, 308 nm by an excimer laser (XeCl), 670, 780 and 830 nm by a semiconductor laser, and 1064 nm by a YAG laser. Use of a laser oscillation colorant allows light of wavelength in a wide range to be oscillated. This also expands a range from which a colorant is selected. For example, when 7-(ethylamino)-4,6-dimethyl-2H-1-benzopyran-2-one as a coumarin-based colorant is used for laser oscillation, light having a wavelength in a range from 430 to 490 nm can be oscillated. When a longer wavelength is desired, 2,3,6,7-tetrahydro-11-oxo-1H,5H,11H-[1]benzopyrano[6,7,8-ij]quinolizine-carboxylic acid ethyl also as a coumarin-based colorant can be used to have a wavelength in a range from 484 to 544 nm. When a still longer wavelength is desired, 9-[2-(ethoxycarbonyl)phenyl]-3,6-bis(ethylamino)-2,7-dimethylanthriumchloride as a rhodamine-based colorant can be used to have a wavelength in a range from 550 to 633 nm. When a still longer wavelength is desired, 2-[4-{4-dimethylamino}phenyl]-1,3-butadienyl]-1-ethylpyridiniumperchlorate, can be used to have a wavelength in a range from 645 to 808 nm. When a still wavelength is desired, 5-chloro-2-[2-[3-{2-(5-chloro-3-ethyl-2(3H)-benzothiazolidene)ethylidene}-2-diphenylamino-1-cyclopenten-1-yl]etenyul]-3-ethyl-benzothiazoliumperchlorate can be used to have a wavelength in a range from 805 to 1030 nm. When a still longer wavelength is desired, 3-ethyl-2-[[3-[3-[3-{3-ethylnaphtho[2,1-d]thiazol-2(3H)-idene}methyl}-5,5-dimethyl-2-cyclohexen-1-ylidene]-1-propenyl]-5,5-dimethyl-2-cyclohexen-1-ylidene]methyl]naphtha[2,1-d]thiazoliumperchlorate can be used to have a wavelength in a range from 1076 to 1200 nm.

[iii] Solution Containing an Electroconductive Metal

Solutions containing an electroconductive metal include a dispersion of fine electroconductive particles, and solution containing a metallic material.

The dispersions of fine electroconductive particles include those containing gold, silver or platinum. It is very effective to incorporate a dispersant or dispersion stabilizer in the dispersion, to prevent agglomeration of these particles into the larger particles. The primary particles preferably have a size of several to several tens nanometers. Copper tends to be corroded by oxygen in air, and the dispersion is preferably incorporated with an antioxidant or reductant.

The solutions containing a metallic material include a plating solution, e.g., Cu-containing solution for electroless copper plating. When an electroless copper plating solution is used, adhesion of the copper electrical lines to a board can be improved by depositing a solution containing palladium chloride on the board portions on which hydrophilic patterns are formed before depositing the copper-containing solution. Use of an Au-containing solution beforehand can further improve the adhesion.

[iv] Procedure for Application of the Liquid-Repellent Membrane to a Display Device or the Like

As discussed earlier, a display device can be prepared by using a “solution capable of forming an insulation, semiconducting or light emission layer, or the like”, or “solution capable of forming a red, green or blue color,” i.e., a solution dissolving or dispersing a resin and colorant” in place of the “solution containing an electroconductive metal,” for producing an electrical board. The procedures for producing a display device or the like are discussed in detail in EXAMPLES.

### EXAMPLES

The present invention is described in more detail by EXAMPLES, which by no means limit the present invention.

### Example 1

EXAMPLE 1 describes the procedures for producing the liquid repellent membrane.

First, 1 part by weight of Compound 1 was dissolved in 199 parts by weight of PF-5080 (3M), to prepare a 0.5% by weight solution of Compound 1.

A 1 mm thick glass board was immersed in the 0.5% by weight solution of Compound 1 dissolved in PF-5080, and heated at 120° C. for 10 minutes. Then, the coated board was washed with PF-5080 to remove Compound 1 not chemically bound to the board. This formed a liquid repellent membrane of Compound 1 on the board. The membrane had a contact angle of 112° with water, 91° with ethylene glycol, and 63° with cyclohexanone. The uncoated glass board had a contact angle of 30° with water, below 10° with ethylene glycol, and also below 10° with cyclohexanone. These results indicate that the membrane of Compound 1 works as a liquid repellent membrane. Surface tensions of water, ethylene glycol and cyclohexanone with the membrane were 72, 48 and 35 mN/m, respectively. The contact angle and surface tension were measured at 20 to 25° C. in EXAMPLES described in this specification

The liquid repellent membranes were prepared in the same manner as above, except that Compound 1 was replaced by Compounds 2 to 22. Their contact angles of these membranes with various liquids are given in Table 1.

TABLE 1
Contact angles of the membranes of the fluorine
compounds of the present invention with various liquids

| | Liquids used for measuring | | |
|---|---|---|---|
| | contact angle | | |
| | | Ethylene | |
| Compound used | Water | glycol | Cyclohexanone |
| Compound 1 | 112 | 91 | 63 |
| Compound 2 | 90 | 70 | 40 |
| Compound 3 | 108 | 88 | 60 |
| Compound 4 | 106 | 86 | 58 |
| Compound 5 | 107 | 85 | 56 |
| Compound 6 | 109 | 88 | 60 |
| Compound 7 | 112 | 91 | 63 |
| Compound 8 | 90 | 70 | 40 |
| Compound 9 | 108 | 88 | 60 |
| Compound 10 | 106 | 86 | 58 |
| Compound 11 | 107 | 85 | 56 |
| Compound 12 | 109 | 88 | 60 |
| Compound 13 | 112 | 91 | 63 |
| Compound 14 | 112 | 90 | 61 |
| Compound 15 | 111 | 88 | 61 |
| Compound 16 | 112 | 90 | 61 |
| Compound 17 | 112 | 91 | 62 |
| Compound 18 | 110 | 88 | 60 |
| Compound 19 | 112 | 89 | 61 |
| Compound 20 | 112 | 90 | 61 |
| Compound 21 | 112 | 90 | 61 |
| Compound 22 | 112 | 90 | 61 |
| Uncoated glass board | 30 | below 10 | below 10 |

Unit: °

The liquid repellent membrane of any of Compounds of the present invention has significantly larger contact angle with various liquids than the uncoated glass board. These results indicate that the membrane of each of Compounds 1 to 22 works as a liquid repellent membrane.

### Example 2

EXAMPLE 2 describes the procedures for producing the liquid repellent membrane of the fluorine compound to which a functional compound having a pigment unit working as the light-absorbing site is bound. These procedures comprise [A] preparation of a solution in which the following colorant working as the light-absorbing site is dissolved, [B] immersion of a board, on which the liquid repellent membrane is formed in the same manner as in EXAMPLE 1, in a colorant solution, which may involve heating in certain instances, to prepare several samples for each membrane, [C] measuring contact angle of the liquid repellent membrane with water, [D] irradiation of the liquid repellent membrane with light, and [E] measuring contact angle changed as a result of treatment with light.

[A] Preparation of Colorant Solution

(a) Colorant Solution α

Colorant Solution α was prepared by dissolving 10 parts by weight of copper phthalocyanine tetrasodium sulfonate in 990 parts by weight of water, to which 1 part by weight of tetramethyl ammonium bromide was added as a catalyst.

(b) Colorant Solution β

Colorant Solution β was prepared by dissolving 10 parts by weight of 1-methylaminoanthraquinone in 990 parts by weight of 1-methyl-2-pyrrolidone, to which 1 part by weight of tetramethyl ammonium bromide was added as a catalyst.

(c) Colorant Solution γ

Colorant Solution γ was prepared by dissolving 10 parts by weight of 2-aminoanthraquinone in 990 parts by weight of 1-methyl-2-pyrrolidone, to which 1 part by weight of tetramethyl ammonium bromide was added as a catalyst.

[B] Binding of the Light-Absorbing Site (Treatment with the Colorant Solution)

The light-absorbing site was introduced into the liquid repellent membrane using each of Colorant Solutions α, β and γ. A total of 52 types of the liquid repellent membranes were prepared by the following procedures, 16 types with Colorant Solution α, 18 types with Colorant Solution β and 18 types with Colorant Solution γ.

(a) In the Case with Colorant Solution α

Each of the boards coated with the liquid repellent membrane of one of Compounds 1 to 16 and 19 in EXAMPLE 1 was immersed in Colorant Solution α. Then, the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to fix copper phthalocyanine tetrasodium sulfonate on the liquid repellent membrane. The liquid repellent membrane had an absorption maximum at a wavelength of 686 nm in the visible region, as confirmed by the ultraviolet/visible absorption spectrometry.

The ion peaks 63 and 65 of the copper atoms present in copper phthalocyanine tetrasodium sulfonate were observed by TOF-SIMS to confirm whether the colorant was bound to the board.

(b) In the case with Colorant Solution β

Each of the boards coated with the liquid repellent membrane of one of Compounds 1 to 13, 17 and 18 in EXAMPLE 1 was immersed in Colorant Solution β. Then, the solution was heated to 100° C., at which it was held for 1 hour. Then, the board was taken out after it was cooled to normal temperature, and washed with 1-methyl-2-pyrrolidone 5 times in an ultrasonic washer, where used 1-methyl-2-pyrrolidone was replaced by the fresh one each time. It was then rinsed with 1-methyl-2-pyrrolidone and dried, to fix 1-methylaminoanthraquinone on the liquid repellent membrane. The liquid repellent membrane had an absorption maximum at a wavelength of 502 nm in the visible region, as confirmed by the ultraviolet/visible absorption spectrometry.

The ion peak 236 due to 1-methylaminoanthraquinone unit was observed by TOF-SIMS to confirm whether the colorant was bound to the board.

(c) In the case with Colorant Solution γ

Each of the boards coated with the liquid repellent membrane of one of Compounds 1 to 13, 17 and 18 in EXAMPLE 1 was immersed in Colorant Solution γ. Then, the solution was heated to 100° C., at which it was held for 1 hour. Then, the board was taken out after it was cooled to normal temperature, and washed with 1-methyl-2-pyrrolidone 5 times in an ultrasonic washer, where used 1-methyl-2-pyrrolidone was replaced by the fresh one each time. It was then rinsed with 1-methyl-2-pyrrolidone and dried, to fix 2-aminoanthraquinone on the liquid repellent membrane. The liquid repellent membrane had an absorption maximum at a wavelength of 434 nm in the visible region, as confirmed by the ultraviolet/visible absorption spectrometry.

The ion peak 222 due to 2-aminoanthraquinone unit was observed by TOF-SIMS to confirm whether the colorant was bound to the board.

It was confirmed that the liquid repellent membrane to which the light-absorbing sites having the pigment unit were bound was prepared.

[C] Contact Angle of the Liquid Repellent Membrane with Water

Table 2 gives contact angle of each board treated with a colorant solution.

TABLE 2
Contact angle of each liquid repellent membrane of the present invention
(treated with a colorant solution) before and after light irradiation

| | Board treated with Colorant | | Board treated with Colorant | | Board treated with Colorant | |
|---|---|---|---|---|---|---|
| | Solution α | | Solution β | | Solution γ | |
| Compound | Before light | After light | Before light | After light | Before light | After light |
| used | irradiation | irradiation | irradiation | irradiation | irradiation | irradiation |
| Compound 1 | 80 | 36 | 96 | 36 | 96 | 34 |
| Compound 2 | 66 | 34 | 80 | 34 | 80 | 33 |
| Compound 3 | 68 | 32 | 88 | 33 | 87 | 33 |
| Compound 4 | 60 | 34 | 80 | 35 | 78 | 34 |
| Compound 5 | 72 | 34 | 88 | 33 | 88 | 33 |
| Compound 6 | 77 | 33 | 90 | 33 | 90 | 33 |
| Compound 7 | 80 | 36 | 96 | 35 | 96 | 35 |
| Compound 8 | 65 | 30 | 78 | 30 | 80 | 32 |
| Compound 9 | 67 | 30 | 86 | 30 | 87 | 32 |
| Compound 10 | 59 | 30 | 80 | 30 | 76 | 32 |
| Compound 11 | 70 | 34 | 86 | 33 | 86 | 33 |
| Compound 12 | 75 | 33 | 88 | 33 | 90 | 33 |
| Compound 13 | 81 | 34 | 95 | 35 | 95 | 35 |
| Compound 14 | 80 | 34 | 96 | 34 | 95 | 34 |
| Compound 15 | 78 | 35 | 95 | 34 | 95 | 34 |
| Compound 16 | 80 | 34 | 96 | 35 | 95 | 35 |
| Compound 17 | | | 94 | 36 | 92 | 36 |
| Compound 18 | | | 94 | 36 | 92 | 36 |

Remarks: Water was used as a medium for the measurement.

Contact angle given in Table 2 is that given in Table 1 measured before the liquid repellent membrane was irradiated with light. Comparing with the contact angle of the membrane with water, given in Table 1, contact angle of the membrane irradiated with light decreased generally by around 20 to 30°. Introduction of the light-absorbing sites means that proportion of structural sites other than perfluoroalkyl, fluoroalkyl and perfluoropolyether chains decreases. In other words, proportion of the structural sites exhibiting liquid repellency decreases, with the result that liquid repellency the membrane decreases.

[D] Procedure for Irradiating the Liquid Repellent Membrane with Light

The liquid repellent membrane was irradiated with light by the laser described below on the square area, 5 by 5 mm, to facilitate measurement of contact angle.

(a) Membrane Treated with Colorant Solution α

The liquid repellent membrane treated with Colorant Solution α was irradiated with light emitted from a helium/neon laser under the conditions of output power: 3 mW, oscillation light wavelength: 633 nm, laser spot diameter: 2 μm, and scanning rate: 10 mm/second.

(b) Membrane treated with Colorant Solution β or γ

The liquid repellent membrane treated with Colorant Solution β or γ was irradiated with light emitted from an argon laser under the conditions of output power: 3 mW, oscillation light wavelength: 488 nm, laser spot diameter: 2 μm, and scanning rate: 10 mm/second.

[E] Changed Contact Angle of the Liquid Repellent Membrane Irradiated with Light

Contact angle of the liquid repellent membrane, irradiated with light under the conditions described above, with water was measured. The results are given in Table 2. As shown, each of the membranes had a contact angle decreased as a result of light irradiation.

Thus, the liquid repellent membrane to which the light-absorbing sites having a pigment unit are bound demonstrates decreased liquid repellency, when irradiated with light.

The decreased contact angle of the light-irradiated liquid repellent membrane conceivably results from degradation/decomposition of the light-irradiated membrane portion by the heat converted from the irradiating light absorbed by the light-absorbing sites in the membrane, because the degraded portion (i.e., light-irradiated portion) decreases in liquid repellency.

### Example 3

A total of 52 types of liquid repellent membranes were prepared in the same manner as in EXAMPLES 1 and 2 [A] to [C] to have the light-absorbing sites. Each was irradiated with light and provided with metallic electrical lines following the procedures [A] and [B], described below. [A] Procedure for irradiating the liquid repellent membrane with light

The liquid repellent membrane was irradiated with light by the following procedure on the areas, each 20 μm wide and 50 mm long.

(a) Membrane treated with Colorant Solution α

The liquid repellent membrane treated with Colorant Solution α was irradiated with light emitted from a helium/neon laser under the conditions of output power: 3 mW, oscillation light wavelength: 633 nm, laser spot diameter: 2 μm, and scanning rate: 10 mm/second.

(b) Membrane Treated with Colorant Solution β or γ

The liquid repellent membrane treated with Colorant Solution β or γ was irradiated with light emitted from an argon laser under the conditions of output power: 3 mW, oscillation light wavelength: 488 nm, laser spot diameter: 2 μm, and scanning rate: 10 mm/second.

[B] Discharging Dispersion of Fine Silver Particles (Forming Metallic Electrical Lines)

An ink jet cartridge (Morimura Chemicals, IJAG-4, refillable cartridge) filled with a dispersion of fine silver particles was set in an ink jet printer (Canon, PIXUS9501). Next, a dispersion of fine silver particles was dropped onto the liquid repellent membrane aiming at the light-irradiated portions and vicinities thereof. Then, the membrane was heated at 150° C. for 10 minutes and then at 300° C. for 60 minutes continuously. The 20 ηm wide, 10 mm long electrical lines of silver were formed in this way on the light-irradiated portions on all of the 52 types of the membranes.

Electrical continuity of each electrical line was confirmed by setting tester needles on the both ends. Insulation at a portion carrying no electrical line was also confirmed.

The membrane surface portions carrying no electrical line on each of the 52 types of the membranes showed the C—F stretching vibration (at near 1200 cm⁻¹) due to the fluorine compound for the membrane, as confirmed by infrared spectrometry. Moreover, the same ion peak (due to the light-absorbed site) as observed in EXAMPLE 2 [B] was also confirmed by TOF-SIMS. These results indicate that the liquid repellent membrane was formed on the board portion carrying no electrical line.

### Comparative Example 1

A glass substrate coated with no liquid repellent membrane was irradiated with light and a dispersion of fine silver particles was discharged onto the substrate in the same manner as in EXAMPLE 3. The electrical lines thus produced were broader to have a width of 50 to 200 μm, because the dispersion spread over the substrate surface.

A total of 52 types of the liquid repellent membranes having the light-absorbing sites were prepared in the same manner as in EXAMPLES 1 and 2 [A] to [C]. Electrical lines were formed on each of these membranes not irradiated with light in the same manner as in EXAMPLE 3 [B]. However, an electrical line could not be formed, because the dispersion of fine silver particles was repelled by the membrane to scatter over the surface in islands.

It is apparent, based on the EXAMPLE 3 and COMPARATIVE EXAMPLE 1 results, that the liquid repellent membrane of the present invention allows electrical lines of fine metallic particles to be formed on the portions irradiated with light to decrease their liquid repellency.

### Example 4

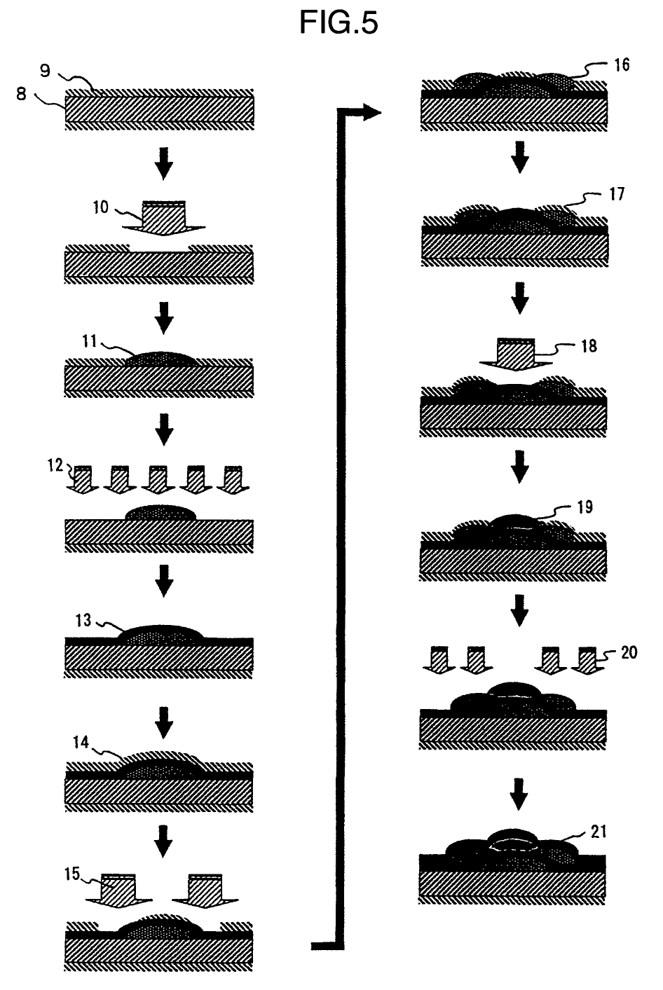

A TFT for display elements was prepared using the procedure for producing the liquid repellent membrane of the fluorine compound of the present invention. FIG. 5 illustrates the process scheme.

[A] Step for Forming the Liquid Repellent Membrane (Layer) having Light-Absorbing Sites

A solution was prepared by dissolving 1 part by weight of Compound 1 in 199 parts by weight of PF-5080 (3M), to prepare a 0.5% by weight solution of Compound 1. Next, Glass Board 8 (100 by 100mm in area, 1 mm in thickness) was immersed in the solution for 10 minutes, and heated at 120° C. for 10 minutes. Then, the coated board was rinsed with PF-5080 to form the liquid repellent membrane of Compound 1. Then, the coated board was immersed in Colorant Solution α, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 9 having the light-absorbing sites.

[B] Step for Light Irradiation

The coated board was irradiated with light of 633 nm emitted from a helium/neon laser under the conditions of output power: 3 mW, oscillation light wavelength: 633 nm, laser spot diameter: 2 μm, and scanning rate: 10 mm/second on the portion on which a gate electrode was to be formed.

FIG. 5 shows as if the liquid repellent membrane were lost when irradiated with light. In actuality, however, the degraded membrane (membrane of one type of fluorine compound) remained. The degraded membrane surface had a molecular ion peak due to fluorine, by which is meant that the membrane of the fluorine compound still remained after it was irradiated with light, although losing liquid repellency, as confirmed by TOF-SIMS analysis.

[C] Step for Forming a Gate Electrode

An ink jet cartridge (Morimura Chemicals, IJAG-4, refillable cartridge) filled with a dispersion of fine silver particles was set in an ink jet printer (Canon, PIXUS9501). Next, a dispersion of fine silver particles was dropped onto the liquid repellent membrane aiming at the light-irradiated portions and vicinities thereof. Then, the membrane was heated at 150° C. for 10 minutes and then at 300° C. for 60 minutes continuously. This formed Gate Electrode 11 of silver.

[D] Step for Light Irradiation

The coated board was irradiated with Light 12 emitted from a 2000W xenon lamp on the entire surface for 10 minutes. Light 12 was not passed through a filter. This step irradiated the entire membrane surface with light, covering the portion not irradiated in the step [B], to thermally degrade the membrane totally to remove liquid repellency from the surface.

FIG. 5 shows as if the liquid repellent membrane were lost when irradiated with light. In actuality, however, the degraded membrane (membrane of one type of fluorine compound) remained.

[E] Step for Forming an Insulation Layer

A 1% solution of poly(vinyl phenol) dissolved in methylethylketone was spread over the coated board carrying the electrical lines of silver by spin coating (rotation speed: 200 rpm, rotation time: 60 seconds), and dried at 100° C. for 10 minutes to remove methylethylketone by evaporation. Poly(vinyl phenol) has the following chemical structure. 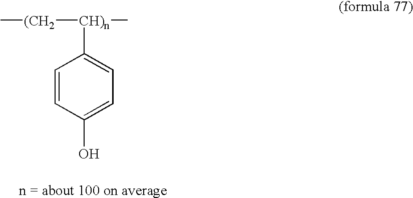
Poly(vinyl phenol)

Thus, the insulation layer 13 of poly(vinyl phenol) was formed.

[F] Step for Forming the Liquid Repellent Membrane having Light-Absorbing Sites

The board coated with the insulation layer was immersed in the 0.5% by weight solution of Compound 1 in PF-5080 for 10 minutes, and heated at 120° C. for 10 minutes. Then, the coated board was rinsed with PF-5080 to form the liquid repellent membrane of Compound 1 on the insulation layer. Then, the coated board was immersed in Colorant Solution a, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 14 having the light-absorbing sites.

[G] Step for Light Irradiation

The coated board was irradiated with Light 15 emitted from a helium/neon laser under the conditions of output power: 3 mW, oscillation light wavelength: 633 nm, laser spot diameter: 2 μm, and scanning rate: 10 mm/second on the portion on which a source and drain electrodes were to be formed.

FIG. 5 shows as if the liquid repellent membrane were lost when irradiated with light. In actuality, however, the degraded membrane (membrane of one type of fluorine compound) remained.

[H] Step for Forming Metallic Electrodes

A dispersion of fine silver particles was dropped onto the liquid repellent membrane aiming at the light-irradiated portions and vicinities thereof using the same members and devices as used in Step [C] for forming a gate electrode. Then, the coated board was heated at 150° C. for 10 minutes and then at 300° C. for 60 minutes continuously. This formed Source and Drain Electrodes 16 of silver.

[I] Step for Forming the Liquid Repellent Membrane having Light-Absorbing

The coated board provided with the source and drain electrodes was immersed in the 0.5% by weight solution of Compound 1 in PF-5080 for 10 minutes, and heated at 120° C. for 10 minutes. Then, the coated board was rinsed with PF-5080 to form the liquid repellent membrane of Compound 1 on the insulation layer. Then, the coated board was immersed in Colorant Solution α, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 17 having the light-absorbing sites.

[J] Step for Light Irradiation

The coated board was irradiated with Light 18 emitted from a helium/neon laser under the conditions of output power: 3 mW, oscillation light wavelength: 633 nm, laser spot diameter: 2 μm, and scanning rate: 10 mm/second on the portion on which a semiconductor device was to be formed.

FIG. 5 shows as if the liquid repellent membrane were lost when irradiated with light. In actuality, however, the degraded membrane (membrane of one type of fluorine compound) remained.

[K] Step for Forming a Semiconductor Device

First, a 1% solution of poly-(9,9-dioctylfluorene-bisthiophene) dissolved in xylene was prepared. Poly(9,9-dioctylfluorene-bisthiophene) has the following chemical structure. 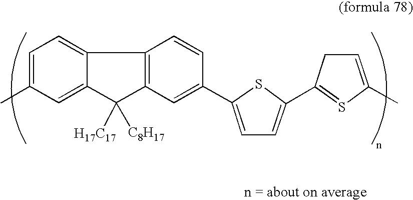
Poly(9,9-dioctylfluorene-bisthiophene)

An ink jet cartridge for an ink jet printer (Canon, PIXUS9501) was cut open at the upper side to remove the ink inside and, at the same time, wash out the ink deposited on the inner surfaces. Next, the cartridge was filled with the 1% poly-(9,9-dioctylfluorene-bisthiophene) solution, and set in the ink jet printer. Then, the solution was dropped onto the coated board aiming at the light-irradiated portions and vicinities thereof. The coated board was heated at 150° C. for 10 minutes. This formed Semiconductor Device 19 of poly-(9,9-dioctylfluorene-bisthiophene).

[L] Step for Light Irradiation

The coated board was irradiated with Light 20 emitted from a helium/neon laser under the conditions of output power: 3 mW, oscillation light wavelength: 633 nm, laser spot diameter: 2 μm, and scanning rate: 10 mm/second on the portion carrying no semiconductor device.

FIG. 5 shows as if the liquid repellent membrane were lost when irradiated with light. In actuality, however, the degraded membrane (membrane of one type of fluorine compound) remained.

[M] Step for Forming an Insulation Layer

A 1% solution of poly(vinyl phenol) in methylethylketone was spread over the coated board carrying the semiconductor device by spin coating (rotation speed: 200 rpm, rotation time: 60 seconds), and dried at 100° C. for 10 minutes to remove methylethylketone by evaporation. This formed Insulation Layer 21 of poly(vinyl phenol).

The TFT was produced by the above steps. It was provided with electrical lines to produce a display. It could output images, as demonstrated by the image output test. Thus, it is confirmed that a TFT can be produced without needing a vacuum process by providing electrodes, a semiconductor device and the like on the liquid repellent membrane of the present invention, after it is irradiated with light to decrease its liquid repellency.

### Example 5

A TFT was prepared in the same manner as in EXAMPLE 4, except that Compound 1 was replaced by Compound 13, Colorant Solution a by Colorant Solution β, both prepared in EXAMPLE 2, and a helium/neon laser by an argon laser. It was provided with electrical lines to produce a display. It could output images, as demonstrated by the image output test. Thus, it is confirmed again that a TFT can be produced without needing a vacuum process by providing electrodes, a semiconductor device and the like on the liquid repellent membrane of the present invention, after it is irradiated with light to decrease its liquid repellency.

### Example 6

A TFT was prepared in the same manner as in EXAMPLE 4, except that Compound 1 was replaced by Compound 17, Colorant Solution a by Colorant Solution χ, both prepared in EXAMPLE 2, and a helium/neon laser by an argon laser. It was provided with electrical lines to produce a display. It could output images, as demonstrated by the image output test. Thus, it is confirmed again that a TFT can be produced without needing a vacuum process by providing electrodes, a semiconductor device and the like on the liquid repellent membrane of the present invention, after it is irradiated with light to decrease its liquid repellency.

### Example 7

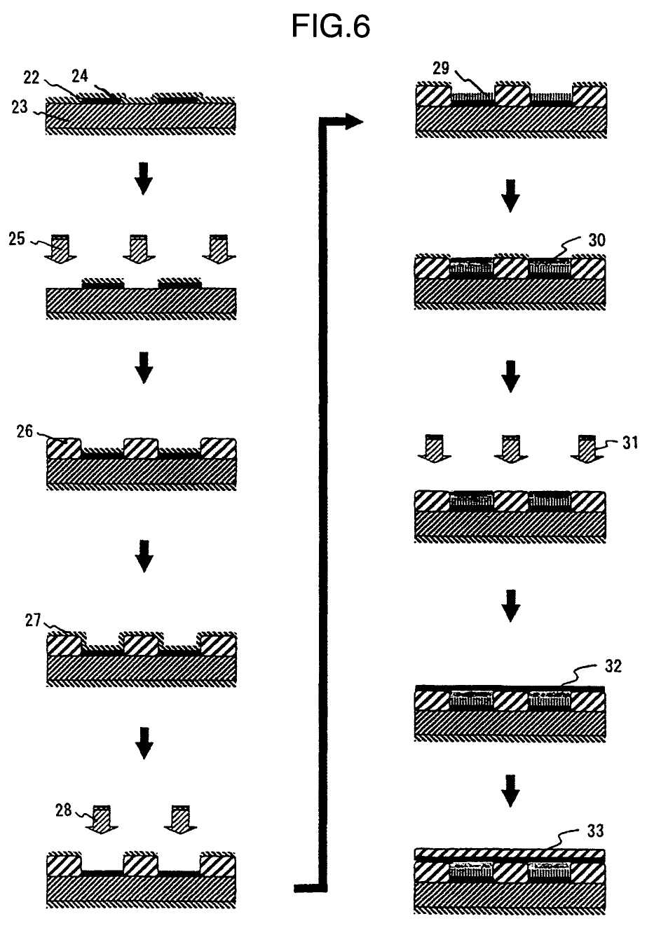

An organic EL board was prepared using the procedure for producing the liquid repellent membrane of the fluorine compound of the present invention. FIG. 6 illustrates the process scheme.

[A] Step for Forming the Liquid Repellent Membrane (Layer) having Light-Absorbing Sites

A solution was prepared by dissolving 1 part by weight of Compound 1 in 199 parts by weight of PF-5080 (3M), to prepare a 0.5% by weight solution of Compound 1. Next, Glass Board 23 (100 by 100 mm in area, 1 mm in thickness), coated with Transparent Electrode 22 of ITO, was immersed in the solution for 10 minutes, and heated at 120° C. for 10 minutes. Then, the coated board was rinsed with PF-5080 to form the liquid repellent membrane of Compound 1. Then, the coated board was immersed in Colorant Solution a, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 24 having the light-absorbing sites.

[B] Step for Light Irradiation

The coated board was irradiated with Light 25 emitted from a helium/neon laser under the conditions of output power: 3 mW, oscillation light wavelength: 633 nm, laser spot diameter: 2 μm, and scanning rate: 10 mm/second on the portion on which a gate electrode was to be formed.

FIG. 6 shows as if the liquid repellent membrane were lost when irradiated with light. In actuality, however, the degraded membrane (membrane of one type of fluorine compound) remained.

[C] Step for Forming an Insulation Layer

A 1% solution of poly(vinyl phenol) dissolved in methylethylketone was prepared. An ink jet cartridge for an ink jet printer (Canon, PIXUS9501) was cut open at the upper side to remove the ink inside and, at the same time, wash out the ink deposited on the inner surfaces. Next, the cartridge was filled with the 1% poly(vinyl phenol) solution, and set in the ink jet printer. Then, the solution was dropped onto the coated board aiming at the light-irradiated portions and vicinities thereof. The coated board was heated at 100° C. for 10 minutes. This formed Insulation Layer 26 of poly(vinyl phenol).

[D] Step for Forming the Liquid Repellent Membrane having Light-Absorbing Sites

The board coated with the insulation layer was immersed in the 0.5% by weight solution of Compound 1 in PF-5080 for 10 minutes, and heated at 120° C. for 10 minutes. Then, the coated board was rinsed with PF-5080 to form the liquid repellent membrane of Compound 1 on the insulation layer. Then, the coated board was immersed in Colorant Solution α, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 27 having the light-absorbing sites.

[E] Step for Light Irradiation

The coated board was irradiated with Light 28 emitted from a helium/neon laser under the conditions of output power: 3 mW, oscillation light wavelength: 633 nm, laser spot diameter: 2 μm, and scanning rate: 10 mm/second on the portion on which a transparent electrode was to be formed.

FIG. 6 shows as if the liquid repellent membrane were lost when irradiated with light. In actuality, however, the degraded membrane (membrane of one type of fluorine compound) remained.

[F] Step for Forming a Hole-Transport Layer

First, a 0.1% by weight dispersion of copper phthalocyanine in chloroform (average primary particle size of copper phthalocyanine: 50 nm) was prepared. An ink jet cartridge for an ink jet printer (Canon, PIXUS9501) was cut open at the upper side to remove the ink inside and, at the same time, wash out the ink deposited on the inner surfaces. Next, the cartridge was filled with the 0.1% by weight copper phthalocyanine dispersion, and set in the ink jet printer. Then, the dispersion was dropped onto the coated board aiming at the light-irradiated portions and vicinities thereof. The coated board was heated at 70° C. for 15 minutes, to remove chloroform as a dispersion medium by evaporation from the area on which the dispersion was deposited. This formed Hole-Transfer Layer 29.

[G] Step for Forming a Light Emission Layer

First, a 0.1% by weight solution of parafluorene dissolved in cyclohexanone was prepared. An ink jet cartridge for an ink jet printer (Canon, PIXUS9501) was cut open at the upper side to remove the ink inside and, at the same time, wash out the ink deposited on the inner surfaces. Next, the cartridge was filled with the 0.1% by weight parafluorene solution, and set in the ink jet printer. Then, the solution was dropped onto the coated board aiming at the hole-transport layer portions and vicinities thereof. The coated board was heated at 120° C. for 15 minutes, to remove cyclohexanone as a dispersion medium by evaporation from the area on which the solution was deposited. This formed Light Emission Layer 30.

[H] Step for Light Irradiation

The coated board was irradiated with Light 31 emitted from a helium/neon laser under the conditions of output power: 3 mW, oscillation light wavelength: 633 nm, laser spot diameter: 2 μm, and scanning rate: 10 mm/second on the portion on which the insulation layer was formed. This decreased liquid repellency of the insulation layer.

FIG. 6 shows as if the liquid repellent membrane were lost when irradiated with light. In actuality, however, the degraded membrane (membrane of one type of fluorine compound) remained.

[I] Step for Forming a Metallic Electrode

A silver ink for ink jetting (Morimura Chemicals) was spread over the coated board carrying the light-irradiated insulation layer by spin coating (rotation speed: 200rpm, rotation time: 60 seconds), and heated at 150° C. for 10 minutes and then at 300° C. for 60 minutes. This formed Metallic Electrode 32 of silver.

[J] Step for Forming a Sealing Layer

A 1% solution of poly(vinyl phenol) dissolved in methylethylketone was spread over the metallic electrode by spin coating (rotation speed: 200rpm, rotation time: 60 seconds), and dried at 100° C. for 10 minutes to remove methylethylketone by evaporation. This formed Sealing Layer 33.

The organic EL board was produced by the above steps. It was provided with electrical lines to produce a light emission device. It was tested whether it emitted light or not, and demonstrated to emit light. Thus, it is confirmed that an organic EL board can be produced without needing a vacuum process by providing an insulation, hole-transport and light emission layers on the liquid repellent membrane of the present invention, after it is irradiated with light to decrease its liquid repellency.

The step for forming a desired pattern by forming the liquid repellent membrane is applicable, as required, to each step for forming an organic light emission device member. Therefore, the present invention is not limited to the step order described in EXAMPLE 7. When it is applied to any step, the liquid repellent membrane will be formed on a layer between the substrate and sealing layer.

### Example 8

An organic EL board was prepared in the same manner as in EXAMPLE 7, except that Compound 1 was replaced by Compound 13, Colorant Solution a by Colorant Solution β, both prepared in EXAMPLE 2, and a helium/neon laser by an argon laser. It was provided with electrical lines to produce a light emission device. It was tested whether it emitted light or not, and demonstrated to emit light. Thus, it is confirmed again that an organic EL board can be produced.

### Example 9

An organic EL board was prepared in the same manner as in EXAMPLE 7, except that Compound 1 was replaced by Compound 17, Colorant Solution α by Colorant Solution γ, both prepared in EXAMPLE 2, and a helium/neon laser by an argon laser. It was provided with electrical lines to produce a light emission device. It was tested whether it emitted light or not, and demonstrated to emit light. Thus, it is confirmed again that an organic EL board can be produced.

### Example 10

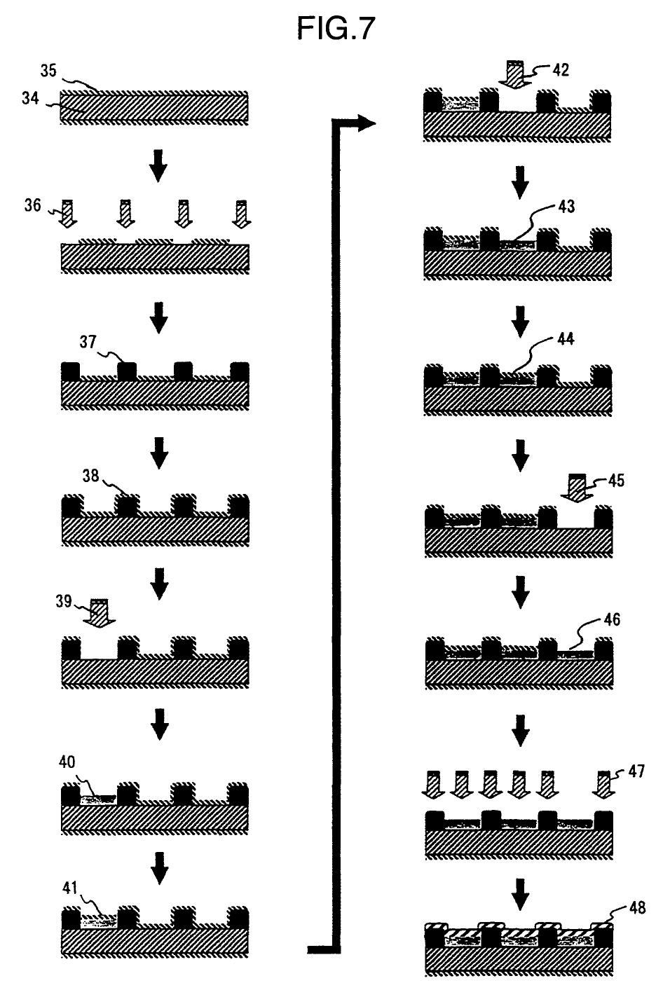

A color filter panel for displays was prepared using the procedure for producing the liquid repellent membrane of the fluorine compound of the present invention. FIG. 7 illustrates the process scheme.

[A] Step for Forming the Liquid Repellent Membrane having Light-Absorbing Sites

A solution was prepared by dissolving 1 part by weight of Compound 1 in 199 parts by weight of PF-5080 (3M), to prepare a 0.5% by weight solution of Compound 1. Next, Glass Board 34 (250 by 190 mm in area, 1 mm in thickness) was immersed in the solution for 10 minutes, and heated at 120° C. for 10 minutes. Then, the coated board was rinsed with PF-5080 to form the liquid repellent membrane of Compound 1. Then, the coated board was immersed in Colorant Solution a, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 35 having the light-absorbing sites.

[B] Step for Light Irradiation

The coated board was irradiated with Light 36 emitted from a helium/neon laser under the conditions of output power: 3 mW, oscillation light wavelength: 633 nm, laser spot diameter: 2 μm, and scanning rate: 10 mm/second on the portion on which a black matrix was to be formed.

FIG. 7 shows as if the liquid repellent membrane were lost when irradiated with light. In actuality, however, the degraded membrane (membrane of one type of fluorine compound) remained.

[C] Step for Forming Black Matrices

First, 10 parts by weight of carbon black (average primary particle size: 50 nm) and 1 part by weight of a particle dispersant (Kao Corp., Geraniol L-95) were added to 1000 parts by weight of cyclohexanone, and the mixture was stirred in a planetary mill to disperse the carbon black, to which 50 parts by weight of poly(vinyl phenol), 50 parts by weight of an epoxy resin (EP1001) and 1 part by weight of benzoimidazole were added. The resulting mixture was stirred to prepare the solution dissolving or dispersing the black matrix forming material (this solution is hereinafter referred to as Black Matrix Forming Solution). An ink jet cartridge for an ink jet printer (Canon, PIXUS9501) was cut open at the upper side to remove the ink inside and, at the same time, wash out the ink deposited on the inner surfaces. Next, the cartridge was filled with Black Matrix Forming Solution, and set in the ink jet printer. Then, Black Matrix Forming Solution was dropped onto the coated board aiming at the light-irradiated portions and vicinities thereof. The coated board was heated at 120° C. for 10 minutes. This formed Black Matrices 37.

[D] Step for Forming the Liquid Repellent Membrane having Light-Absorbing Sites

The board coated with the black matrices was immersed in the 0.5% by weight solution of Compound 1 in PF-5080 for 10 minutes, and heated at 120° C. for 10 minutes. Then, the coated board was rinsed with PF-5080 to form the liquid repellent membrane of Compound 1 on the black matrices. Then, the coated board was immersed in Colorant Solution α, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 38 having the light-absorbing site on the black matrix.

[E] Step for Light Irradiation

The coated board was irradiated with Light 39 emitted from a helium/neon laser under the conditions of output power: 3 mW, oscillation light wavelength: 633 nm, laser spot diameter: 2 μm, and scanning rate: 10 mm/second on the portion on which a color filter R region was to be formed.

FIG. 7 shows as if the liquid repellent membrane were lost when irradiated with light. In actuality, however, the degraded membrane (membrane of one type of fluorine compound) remained.

[F] Step for Forming a Color Filter R Region

First, 10 parts by weight of a red colorant (C.I. pigment red 177) for the R region and 1 part by weight of a particle dispersant (Kao Corp., Geraniol L-95) were added to 100 parts by weight of ethanol, and the mixture was stirred in a planetary mill to disperse the C.I. pigment red 177, to which 20 parts by weight of a 6% by weight silica-sol solution (average molecular weight: 2000 to 4000, solvent composed of ethanol (70%) and water accounting for most of the balance, pH: controlled at around 3 with phosphoric acid) was added. This solution is hereinafter referred to as Color Filter R Region Forming Solution. An ink jet cartridge for an ink jet printer (Canon, PIXUS9501) was cut open at the upper side to remove the ink inside and, at the same time, wash out the ink deposited on the inner surfaces. Next, the cartridge was filled with Color Filter R Region Forming Solution, and set in the ink jet printer. Then, Color Filter R Region Forming Solution was dropped onto the coated board aiming at the light-irradiated portions and vicinities thereof. The coated board was heated at 120° C. for 10 minutes. This formed Color Filter R Region 40.

[G] Step for Forming the Liquid Repellent Membrane having Light-Absorbing Sites

The board coated with the color filter R region was immersed in the 0.5% by weight solution of Compound 1 in PF-5080 for 10 minutes, and heated at 120° C. for 10 minutes. Then, the coated board was rinsed with PF-5080 to form the liquid repellent membrane of Compound 1 on the color filter R region. Then, the coated board was immersed in Colorant Solution α, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 41 having the light-absorbing sites on the color filter R region.

[H] Step for Light Irradiation

The coated board was irradiated with Light 42 emitted from a helium/neon laser under the conditions of output power: 3 mW, oscillation light wavelength: 633 nm, laser spot diameter: 2 μm, and scanning rate: 10 mm/second on the portion on which a color filter G region was to be formed.

FIG. 7 shows as if the liquid repellent membrane were lost when irradiated with light. In actuality, however, the degraded membrane (membrane of one type of fluorine compound) remained.

[I] Step for Forming a Color Filter G Region

First, 10 parts by weight of a green colorant (C.I. pigment green 7) for the G region and 1 part by weight of a particle dispersant (Kao Corp., Geraniol L-95) were added to 100 parts by weight of ethanol, and the mixture was stirred in a planetary mill to disperse the C.I. pigment green 7, to which 20 parts by weight of a 6% by weight silica-sol solution (average molecular weight: 2000 to 4000, solvent composed of ethanol (70%) and water accounting for most of the balance, pH: controlled at around 3 with phosphoric acid) was added. This solution is hereinafter referred to as Color Filter G Region Forming Solution. An ink jet cartridge for an ink jet printer (Canon, PIXUS9501) was cut open at the upper side to remove the ink inside and, at the same time, wash out the ink deposited on the inner surfaces. Next, the cartridge was filled with Color Filter G Region Forming Solution, and set in the ink jet printer. Then, Color Filter G Region Forming Solution was dropped onto the coated board aiming at the light-irradiated portions and vicinities thereof. The coated board was heated at 120° C. for 10 minutes. This formed Color Filter G Region 43.

[J] Step for Forming the Liquid Repellent Membrane having Light-Absorbing Sites

The board coated with the color filter G region was immersed in the 0.5% by weight solution of Compound 1 in PF-5080 for 10 minutes, and heated at 120° C. for 10 minutes. Then, the coated board was rinsed with PF-5080 to form the liquid repellent membrane of Compound 1 on the color filter G region. Then, the coated board was immersed in Colorant Solution α, prepared in EXAMPLE 2, and the solution was heated to 100° C., at which it was held for 1 hour. Then, the board was taken out after it was cooled to normal temperature, and washed with water 5 times in an ultrasonic washer, where used water was replaced by the fresh one each time. It was then rinsed with water and dried, to prepare Liquid Repellent Membrane 44 having the light-absorbing sites on the color filter G region.

[K] Step for Light Irradiation

The coated board was irradiated with Light 45 emitted from a helium/neon laser under the conditions of output power: 3 mW, oscillation light wavelength: 633 nm, laser spot diameter: 2 μm, and scanning rate: 10 mm/second on the portion on which a color filter B region was to be formed.

FIG. 7 shows as if the liquid repellent membrane were lost when irradiated with light. In actuality, however, the degraded membrane (membrane of one type of fluorine compound) remained.

[L] Step for Forming a Color Filter B Region

First, 10 parts by weight of a blue colorant (C.I. pigment blue 15) for the B region and 1 part by weight of a particle dispersant (Kao Corp., Geraniol L-95) were added to 100 parts by weight of ethanol, and the mixture was stirred in a planetary mill to disperse the C.I. pigment blue 15, to which 20 parts by weight of a 6% by weight silica-sol solution (average molecular weight: 2000 to 4000, solvent composed of ethanol (70%) and water accounting for most of the balance, pH: controlled at around 3 with phosphoric acid) was added. This solution is hereinafter referred to as Color Filter B Region Forming Solution. An ink jet cartridge for an ink jet printer (Canon, PIXUS9501) was cut open at the upper side to remove the ink inside and, at the same time, wash out the ink deposited on the inner surfaces. Next, the cartridge was filled with Color Filter B Region Forming Solution, and set in the ink jet printer. Then, Color Filter B Region Forming Solution was dropped onto the coated board aiming at the light-irradiated portions and vicinities thereof. The coated board was heated at 120° C. for 10 minutes. This formed Color Filter B Region 46.

[M] Step for Light Irradiation

The coated board was irradiated with Light 47 emitted from a helium/neon laser under the conditions of output power: 3 mW, oscillation light wavelength: 633 nm, laser spot diameter: 2 μm, and scanning rate: 10 mm/second on a board portion carrying no color filter B region.

FIG. 7 shows as if the liquid repellent membrane were lost when irradiated with light. In actuality, however, the degraded membrane (membrane of one type of fluorine compound) remained.

[N] Step for Forming a Protective Layer

A 6% by weight silica-sol solution (average molecular weight: 2000 to 4000, solvent composed of ethanol (70%) and water accounting for most of the balance, pH: controlled at around 3 with phosphoric acid) was spread over the coated board by spin coating (rotation speed: 200 rpm, rotation time: 60 seconds), and heated at 120° C. for 10 minutes. This formed Protective Layer 48 of SiO₂ on the black matrix, and color filter R, G and B regions.

The color filter panel was produced by the above steps. It was set in a display to be tested. It could output clear images, as demonstrated by the image output test.

Thus, it is confirmed that a color filter panel can be produced without needing a vacuum process by providing a black matrix portion, and color filter R, G and B regions on the liquid repellent membrane of the present invention, after it is irradiated with light to decrease its liquid repellency.

### Example 11

A color filter panel was prepared in the same manner as in EXAMPLE 10, except that Compound 1 was replaced by Compound 13, Colorant Solution α by Colorant Solution α, both prepared in EXAMPLE 2, and a helium/neon laser by an argon laser. It was set in a display to be tested. It could output clear images, as demonstrated by the image output test. Thus, it is confirmed again that a color filter panel can be produced by the method of the present invention.

### Example 12

A color filter panel was prepared in the same manner as in EXAMPLE 10, except that Compound 1 was replaced by Compound 17, Colorant Solution a by Colorant Solution γ, both prepared in EXAMPLE 2, and a helium/neon laser by an argon laser. It was set in a display to be tested. It could output clear images, as demonstrated by the image output test. Thus, it is confirmed again that a color filter panel can be produced by the method of the present invention.

### Example 13

First, 1 part by weight of Compound 14 was dissolved in 199 parts by weight of PF-5080 (3M), to prepare a 0.5% by weight solution of Compound 14.

A 1 mm thick glass board was immersed in the 0.5% by weight solution of Compound 14 dissolved in PF-5080, and heated at 120° C. for 10 minutes. Then, the coated board was washed with PF-5080 to remove Compound 14 not chemically bound to the board. This formed a liquid repellent membrane of Compound 14 on the board. The membrane had a contact angle of 112° with water, 90° with ethylene glycol, and 61° with cyclohexanone.

Next, the coated board was immersed in hydrochloric acid (pH: 3) for 1 minute, washed with water and dried. It had a contact angle of 90° with water, 69° with ethylene glycol and 31° with cyclohexanone.

Next, the coated board was immersed in hydrochloric acid (pH: 2) for 1 minute, washed with water and dried. It had a contact angle of 81° with water, 59° with ethylene glycol and 20° with cyclohexanone.

Furthermore, the coated board was immersed in hydrochloric acid (pH: 1) for 1 minute, washed with water and dried. It had a contact angle of 70° with water, 51° with ethylene glycol and 120 with cyclohexanone.

Thus, the liquid repellent membrane exhibits a contact angle varying in accordance with pH level of the liquid with which it comes into contact. This means that the membrane of Compound 14 can be used as a pH sensor's responsive unit which determines pH level of a liquid with which it comes into contact by measuring its contact angle.

It is therefore confirmed that the liquid repellent membrane of Compound 14 can constitute a pH sensor, when it is used as the responsive unit and a contact angle meter as the sensing unit.

Contact angle of the membrane varies in accordance with pH level of the liquid with which it comes into contact conceivably results from the following phenomenon. Compound 14 has amino group which is transformed into an ammonium salt structure, when comes into contact with an acidic solution. The ammonium salt structure is more hydrophilic than amino group and increases hydrophilicity of the membrane to which it is bound. This decreases liquid repellency of the membrane to decrease its contact angle with a liquid.

The membrane was tested in the same manner as the above, except that solutions of pH 1, 2 or 3 of nitric acid in place of hydrochloric acid were used. Its contact angle varies in accordance with pH level of the liquid with which the membrane comes into contact. It is therefore apparent that magnitude of changed contact angle is not peculiar to hydrochloric acid itself but depends on pH level of the liquid.

### Example 14

The test was carried out in the same manner as in EXAMPLE 13, except that Compound 14 was replaced by Compound 15 for the membrane. Like Compound 14, Compound 15 has amino group.

According to the test results, the uncoated board had a contact angle of 111° with water, 88° with ethylene glycol, and 61° with cyclohexanone. The board treated with hydrochloric acid had a contact angle of 83° with water, 62° with ethylene glycol, and 25° with cyclohexanone, when immersed in hydrochloric acid of pH3; 70° with water, 50° with ethylene glycol, and 12° with cyclohexanone, when immersed in hydrochloric acid of pH2; and 65° with water, 45° with ethylene glycol, and below 10° with cyclohexanone, when immersed in hydrochloric acid of pH1.

Thus, the liquid repellent membrane of Compound 15 also exhibits a contact angle varying in accordance with pH level of the liquid with which it comes into contact. This means that the membrane of the compound of the present invention can be used as a pH sensor's responsive unit.

### Comparative Example 2

A total of the 52 coated boards prepared in EXAMPLE 2 were irradiated with light in the same manner as in EXAMPLE 2, except that light output power was changed from 3 mW to 0.5 mW in the procedure [D], (a) and (b). No liquid repellent membrane on the board showed decreased contact angle, conceivably because of insufficient light energy to degrade/decompose the membrane.

### Example 15

Each of the coated boards was irradiated with light in the same manner as in COMPARATIVE EXAMPLE 2, except that it was placed on a hot plate heated to 200° C. The results are given in Table 3.

TABLE 3
Contact angle of each liquid repellent membrane of the present invention
(treated with a colorant solution) before and after light irradiation

| | Board treated with Colorant | | Board treated with Colorant | | Board treated with Colorant | |
|---|---|---|---|---|---|---|
| | Solution α | | Solution β | | Solution γ | |
| Compound | Before light | After light | Before light | After light | Before light | After light |
| used | irradiation | irradiation | irradiation | irradiation | irradiation | irradiation |
| Compound 1 | 80 | 35 | 96 | 35 | 96 | 34 |
| Compound 2 | 66 | 33 | 80 | 32 | 80 | 32 |
| Compound 3 | 68 | 30 | 88 | 31 | 87 | 32 |
| Compound 4 | 60 | 32 | 80 | 33 | 78 | 32 |
| Compound 5 | 72 | 33 | 88 | 32 | 88 | 32 |
| Compound 6 | 77 | 31 | 90 | 32 | 90 | 31 |
| Compound 7 | 80 | 34 | 96 | 35 | 96 | 34 |
| Compound 8 | 65 | 28 | 78 | 29 | 80 | 31 |
| Compound 9 | 67 | 28 | 86 | 28 | 87 | 30 |
| Compound 10 | 59 | 29 | 80 | 29 | 76 | 30 |
| Compound 11 | 70 | 33 | 86 | 32 | 86 | 31 |
| Compound 12 | 75 | 32 | 88 | 31 | 90 | 31 |
| Compound 13 | 81 | 34 | 95 | 34 | 95 | 34 |
| Compound 14 | 80 | 34 | 96 | 34 | 95 | 34 |
| Compound 15 | 78 | 35 | 95 | 34 | 95 | 34 |
| Compound 16 | 80 | 34 | 96 | 34 | 95 | 34 |
| Compound 17 | | | 94 | 35 | 92 | 35 |
| Compound 18 | | | 94 | 35 | 92 | 35 |

Remarks: Water was used as a medium for the measurement. The board on which the liquid repellent membrane was formed was kept at 200° C. during the light irradiation step.

As shown, each sample showed a contact angle decrease in EXAMPLE 15, magnitude of which was similar to that observed in EXAMPLE 2. It is confirmed in EXAMPLE 15 and COMPARATIVE EXAMPLE 2 that energy of light with which the liquid repellent membrane could be decreased, when the membrane was heated to decrease its liquid repellency.

### Example 16

A total of the 52 coated boards prepared in EXAMPLE 2 were irradiated with light in the same manner as in EXAMPLE 2, except that each sample was irradiated with light having an output power of 0.5 mW while it was placed on a hot plate heated to 200° C. It was found that the 20 μm wide, 50 mm long electrical lines of silver were formed on each of the coated boards.

Electrical continuity of each electrical line was confirmed by setting tester needles on the both ends. Insulation at a portion carrying no electrical line was also confirmed.

It was also found that an electrical line could not be formed on the coated board not heated by a hot plate, because the dispersion of fine silver particles was repelled to scatter over the surface in islands.

### Example 17

A TFT was prepared in the same manner as in EXAMPLE 4, except that the light irradiation step [B] was carried out with light of output power changed to 0.5 mW while the coated board was placed on a hot plate heated to 2000C. This step was followed by the gate electrode forming step [C]. It was found that the gate electrode was formed, as in EXAMPLE 4. It was also found that an electrode could not be formed on the coated board not heated by a hot plate, because the dispersion of fine silver particles was repelled to scatter over the surface in islands.

### Example 18

A TFT was prepared in the same manner as in EXAMPLE 7, except that the light irradiation step [B] was carried out with light of output power changed to 0.5 mW while the coated board was placed on a hot plate heated to 200° C. This step was followed by the insulation layer forming step [C]. It was found that the insulation layer was formed, as in EXAMPLE 7.

It was also found that an insulation layer could not be formed on the coated board not heated by a hot plate, because the 1% solution of poly(vinyl phenol) dissolved in methylethylketone was repelled to scatter over the surface in islands.

### Example 19

A color filter panel for displays was prepared in the same manner as in EXAMPLE 10, except that the light irradiation step [B] was carried out with light of output power changed to 0.5 mW while the coated board was placed on a hot plate heated to 200° C. This step was followed by the black matrix forming step [C]. It was found that the black matrix was formed, as in EXAMPLE 10.

It was also found that an insulation layer could not be formed on the coated board not heated by a hot plate, because the black matrix forming solution was repelled to scatter over the surface in islands.

Thus, it is found, based on the results of EXAMPLES 15 to 19 and COMPARATIVE EXAMPLE 2, that output power of light with which the coated board is irradiated can be decreased when the board is heated during the light irradiation step for production of the electrical board, TFT element, organic EL element and color filter panel which incorporate the fluorine compound of the present invention and liquid repellent membrane thereof.

It is more preferable to directly heat the coated board during the light irradiation step that to heat the board by heat converted from light energy, because of decreased energy consumption.

### Example 20

First, 1 part by weight of Compound 14 was dissolved in 199 parts by weight of PF-5080 (3M), to prepare a 0.5% by weight solution of Compound 14.

A 1 mm thick glass board was immersed in the 0.5% by weight solution of Compound 14 dissolved in PF-5080, and heated at 120° C. for 10 minutes. Then, the coated board was washed with PF-5080 to remove Compound 14 not chemically bound to the board. This formed a liquid repellent membrane of Compound 14 on the board.

Next, 3 parts by weight of 4-carboxy-benzo-15-crown-5-ether and 3 parts by weight of N,N-dicyclohexylcarbodiimide were dissolved in 100 parts by weight of ethyl acetate. The resulting solution is hereinafter referred to as Crown Ether Solution. The glass board coated with the liquid repellent membrane by the above procedure was immersed in Crown Ether Solution for 1 hour. Then, it was taken out and washed with ethyl acetate. This bound the 15-crown-5-ether to the liquid repellent membrane.

In EXAMPLE 20, 4-carboxy-benzo-15-crown-5-ether was synthesized by the procedure proposed by R. Ungaro, B. El Haj and J. Smith, Journal of American Chemical Society, vol. 98, pp.5198, 1976.

The membrane to which the 15-crown-5-ether was bound had a contact angle of 108° with water, 85° with ethylene glycol, and 56° with cyclohexanone.

Next, the coated board was immersed in hydrochloric acid (pH: 3) for 1 minute, washed with water and dried. It had a contact angle of 90° with water, 69° with ethylene glycol and 31° with cyclohexanone.

Next, the coated board was immersed in hydrochloric acid (pH: 2) for 1 minute, washed with water and dried. It had a contact angle of 81° with water, 59° with ethylene glycol and 200 with cyclohexanone.

Furthermore, the coated board was immersed in hydrochloric acid (pH: 1) for 1 minute, washed with water and dried. It had a contact angle of 70° with water, 51° with ethylene glycol and 12° with cyclohexanone.

The membrane was tested in the same manner as the above, except that sodium chloride was replaced by lithium chloride of varying concentration. No change in contact angle with ion concentration was observed. This means that the liquid repellent membrane prepared EXAMPLE 20 is selectively responsive to the sodium ion.

Thus, the liquid repellent membrane exhibits a contact angle varying in accordance with sodium ion concentration of the liquid with which it comes into contact. This means that the membrane of the present invention can be used as an ion sensor's responsive unit.

It is therefore confirmed that the liquid repellent membrane can constitute an ion sensor, when it is used as the responsive unit and a contact angle meter as the sensing unit.

Contact angle of the membrane varies in accordance with sodium ion concentration of the liquid with which it comes into contact conceivably results from the following phenomenon. The 15-crown-5 ether bound to the liquid repellent membrane includes the sodium ion. The chloride ion as the counter ion is present near the sodium ion to neutralize its charges. In other words, presence of the hydrophilic material near the liquid repellent membrane increases hydrophilicity of the membrane. This decreases liquid repellency of the membrane to decrease its contact angle with a liquid.

It should be further understood by those skilled in the art that although the foregoing description has been made on embodiments of the invention, the invention is not limited thereto and various changes and modifications may be made without departing from the spirit of the invention and the scope of the appended claims.

### ADVANTAGE OF THE INVENTION

The present invention provides a fluorine compound to which a varying functional compound can be bound,, liquid repellent membrane using the same compound, and various products (e.g., electrical board, display device, color filter for display devices, pH sensor and ion sensor) using the same membrane.

1. A fluorine compound represented by one of the following structures: 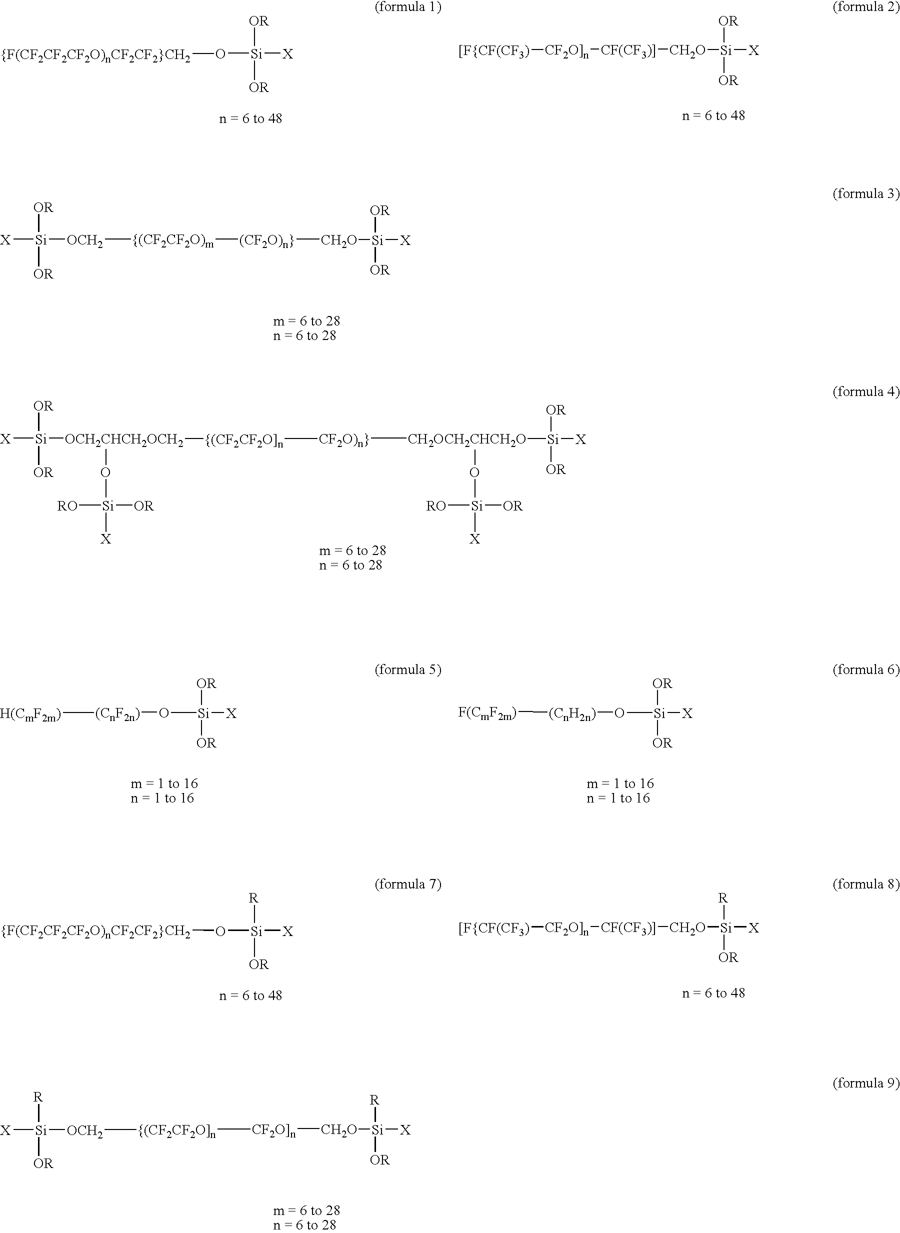 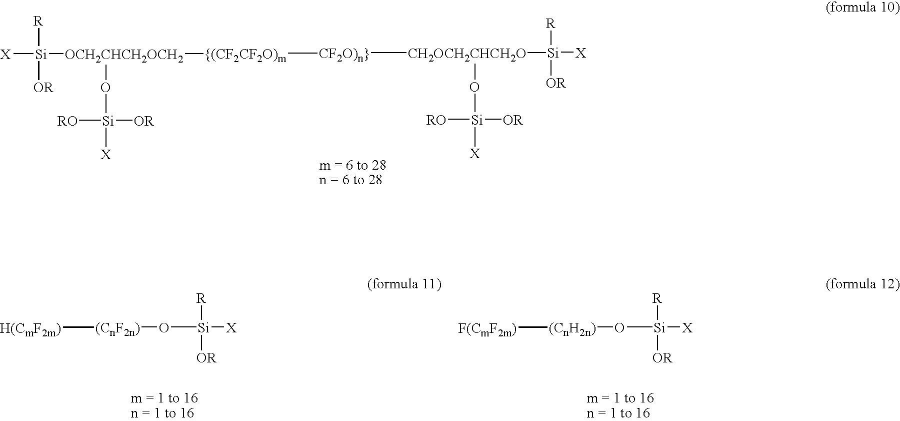
wherein, X is a structure represented by one of the following formulae, and R is an alkyl group of 1 to 4 carbon atoms:

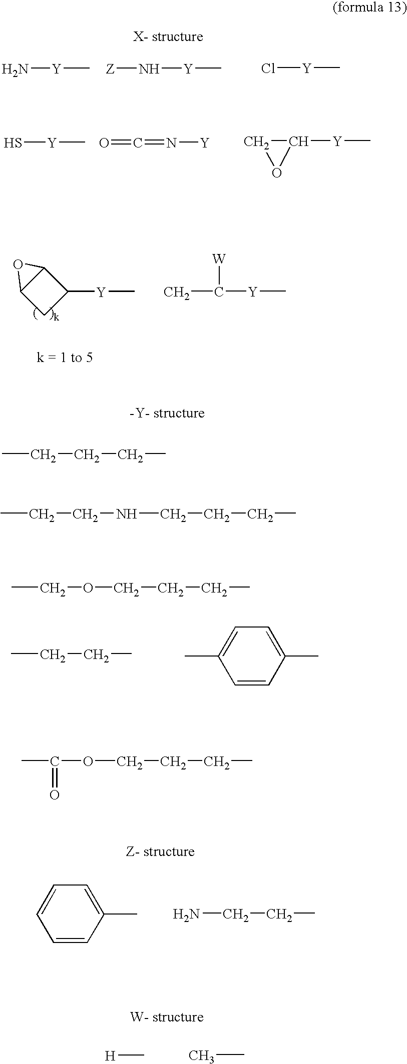

2. A fluorine compound represented by one of the following structures: 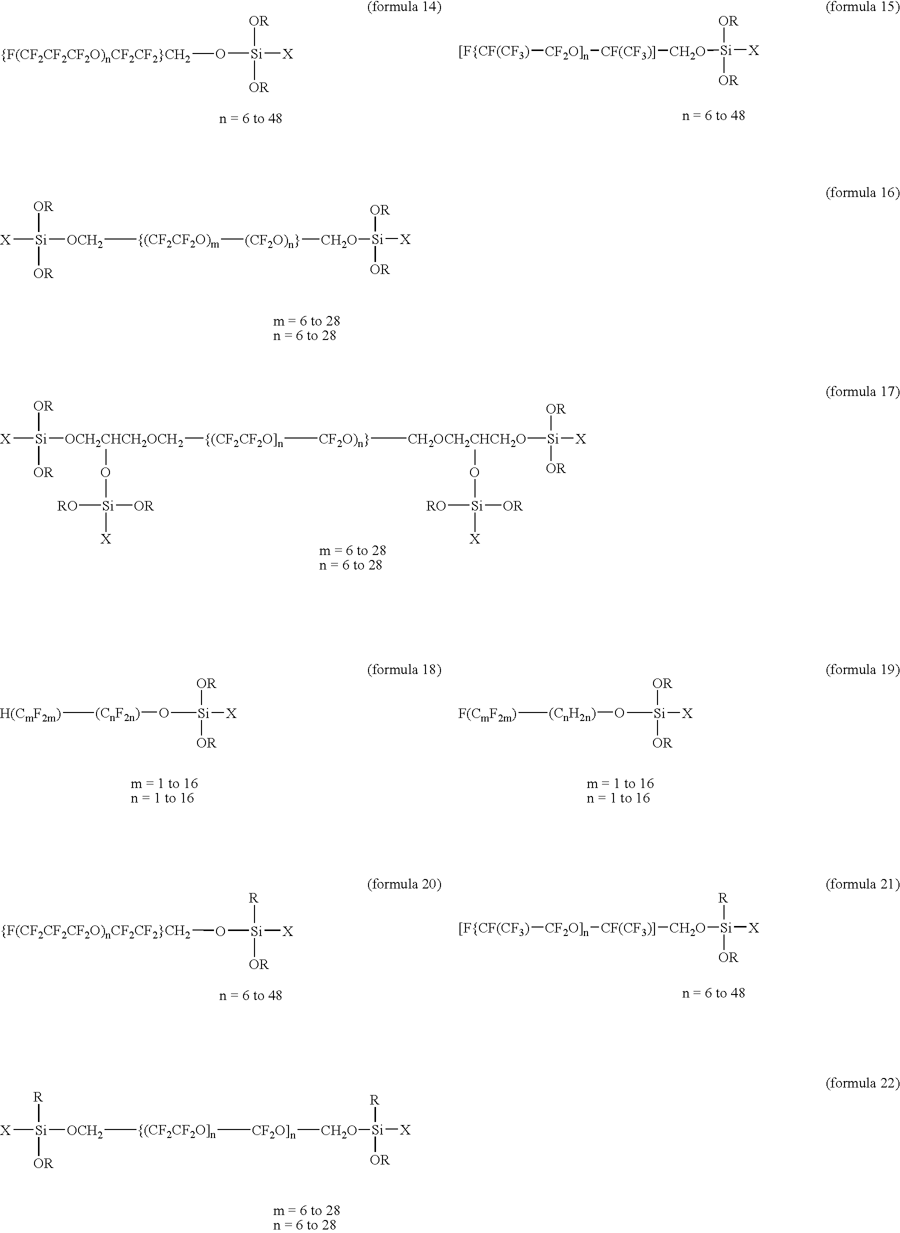 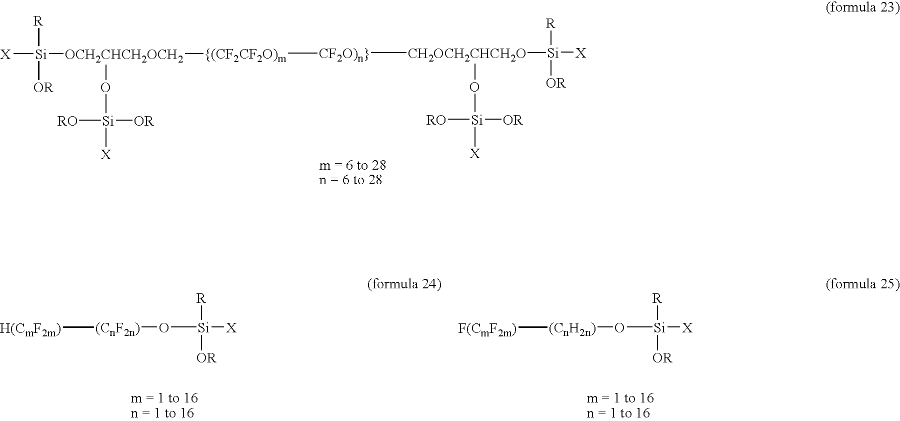
wherein, X is a structure represented by one of the following formulae, and R is an alkyl group of 1 to 4 carbon atoms:

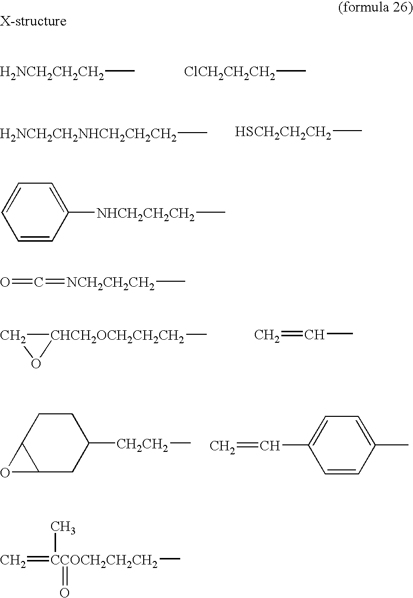

3. A liquid repellent membrane containing a fluorine compound represented by one of the following structures: 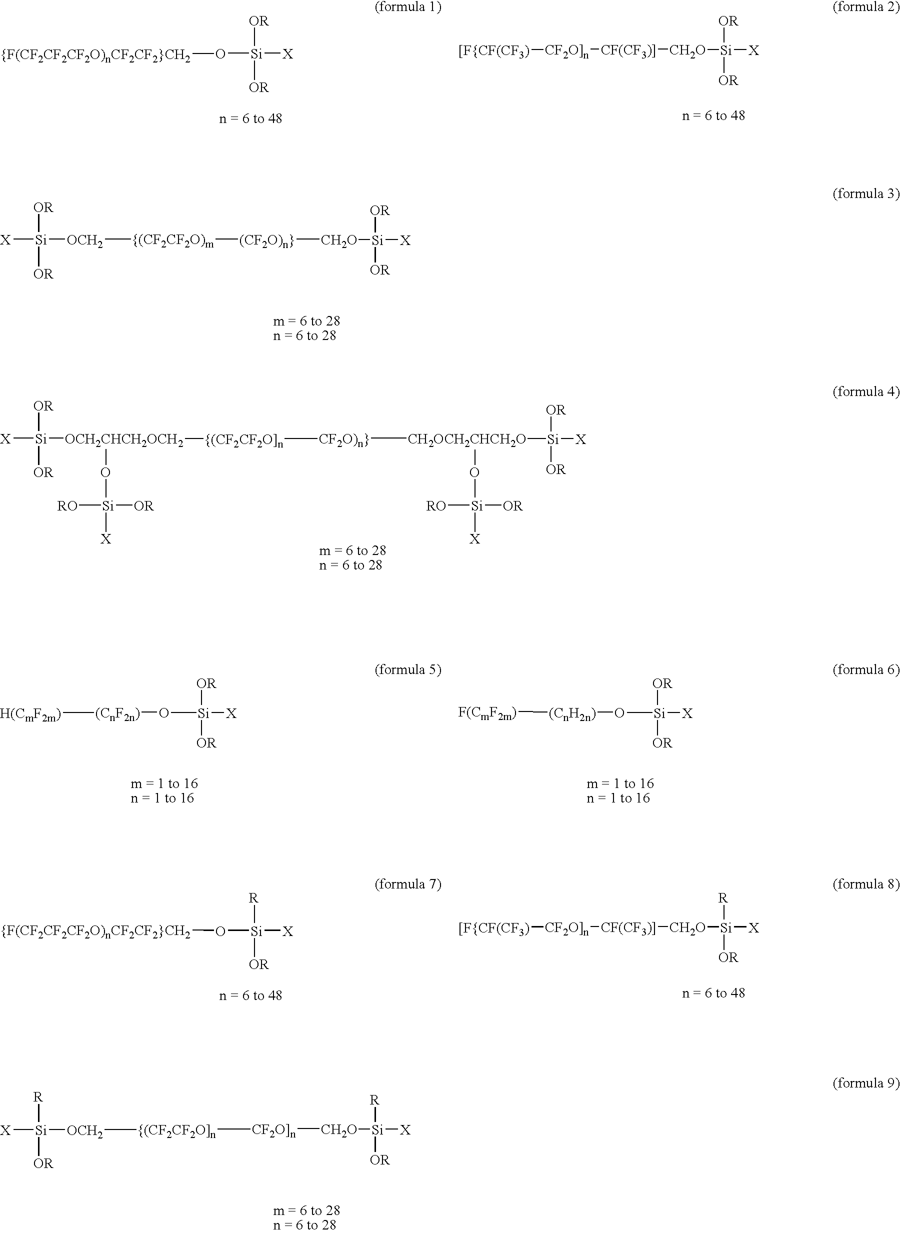 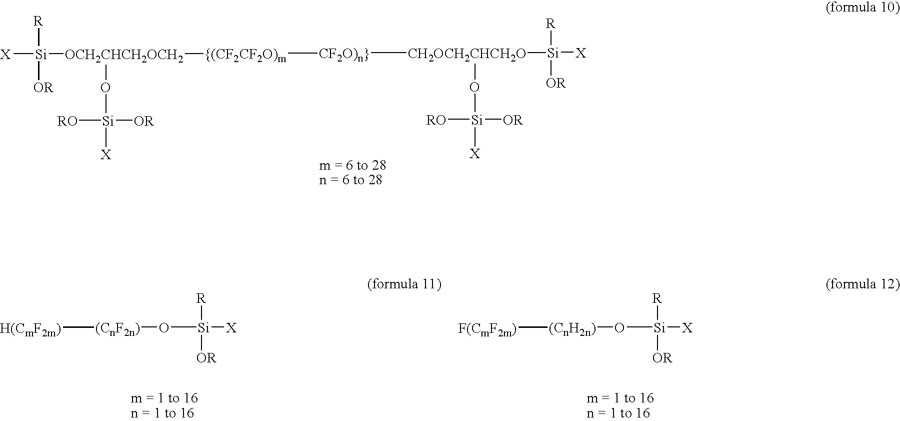
wherein, X is a structure represented by one of the following formulae, and R is an alkyl group of 1 to 4 carbon atoms:

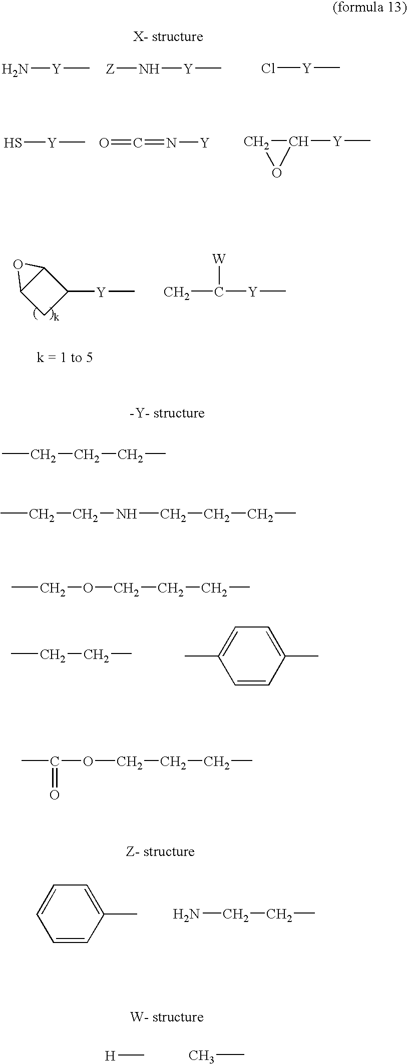

4. A liquid repellent membrane containing a fluorine compound represented by one of the following structures: 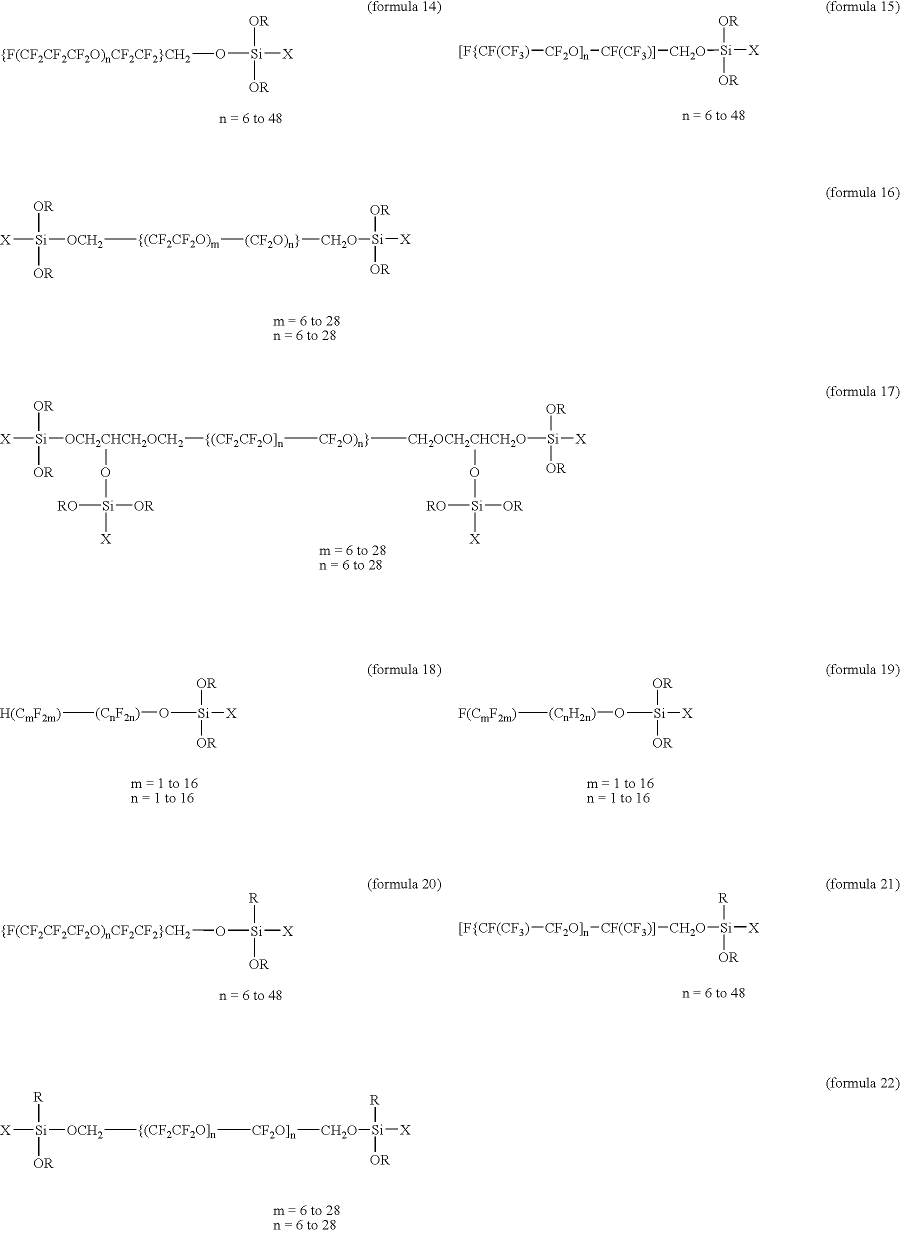 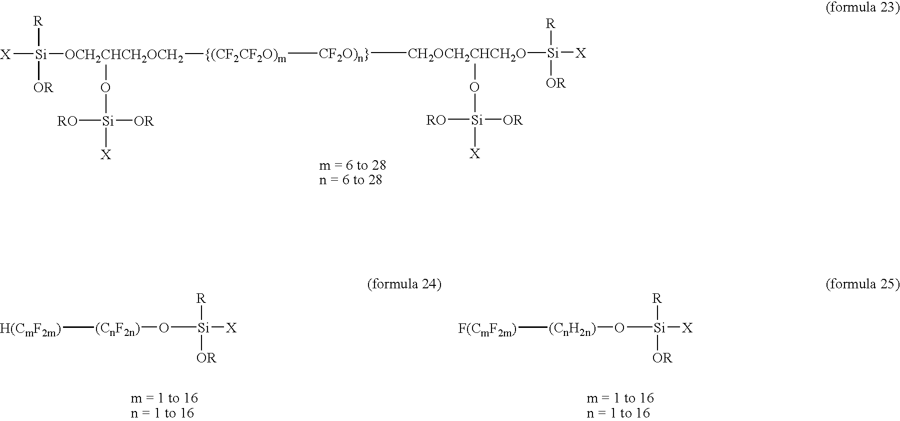
wherein, X is a structure represented by one of the following formulae, and R is an alkyl group of 1 to 4 carbon atoms:

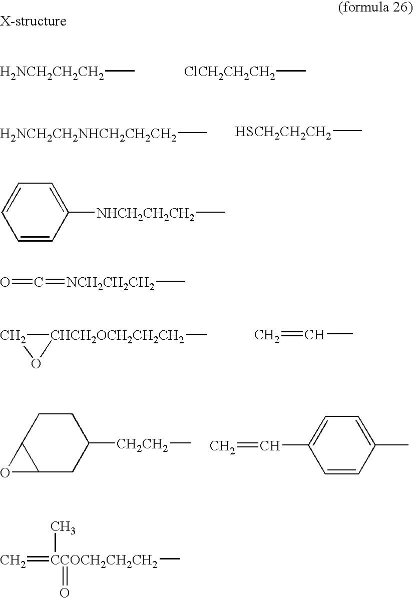

5. A liquid repellent membrane in which a fluorine compound represented by one of the following structures is bound to a functional compound having a pigment unit: 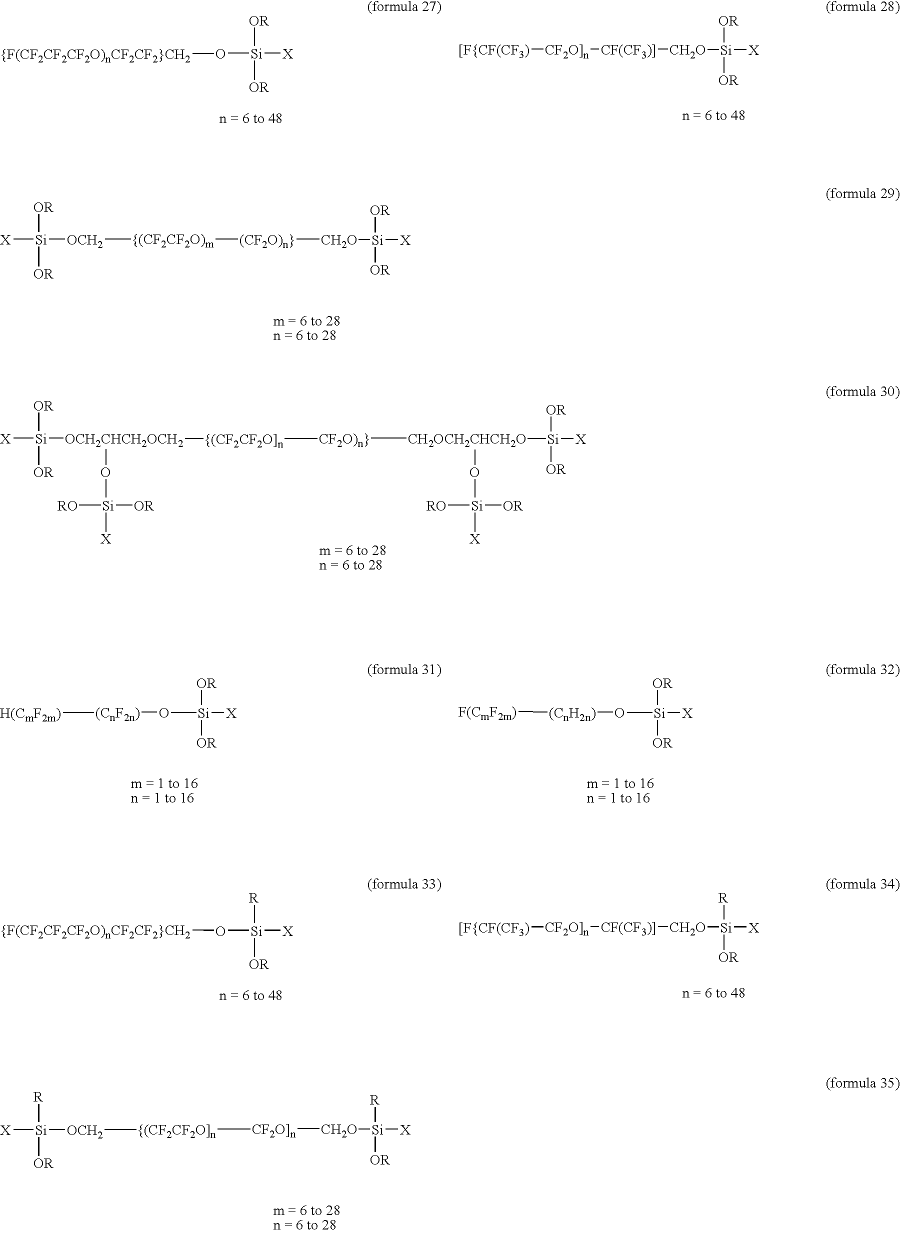 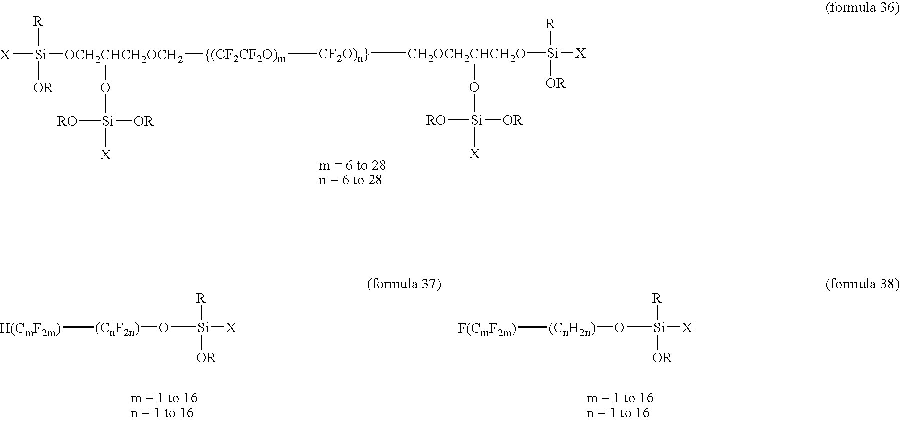
wherein, X is a structure represented by one of the following formulae, and R is an alkyl group of 1 to 4 carbon atoms:

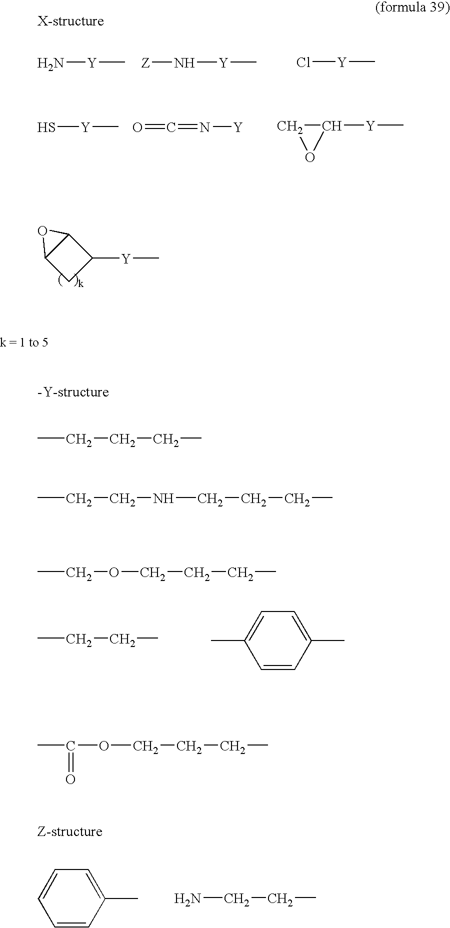

6. A liquid repellent membrane in which a fluorine compound represented by one of the following structures is bound to a functional compound having a pigment unit: 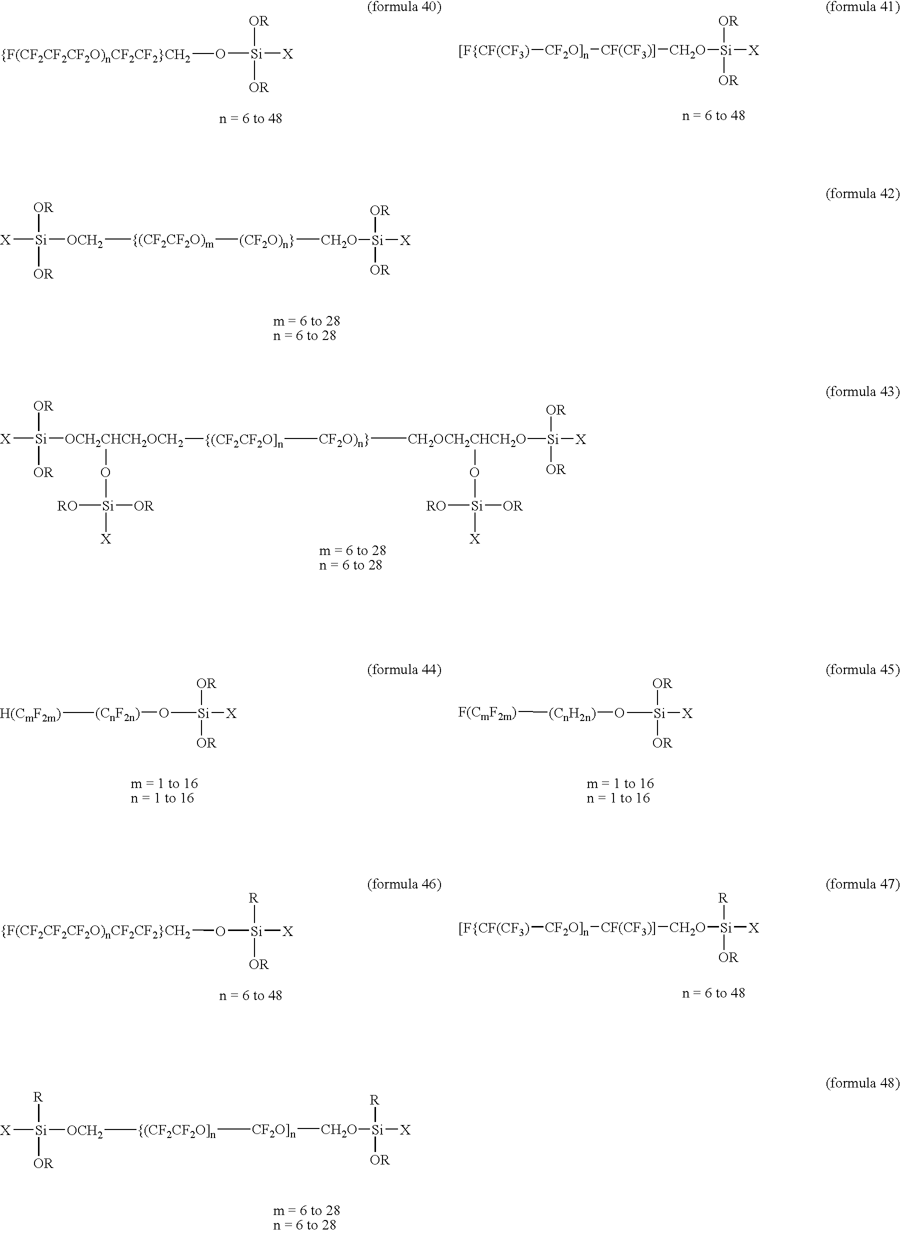 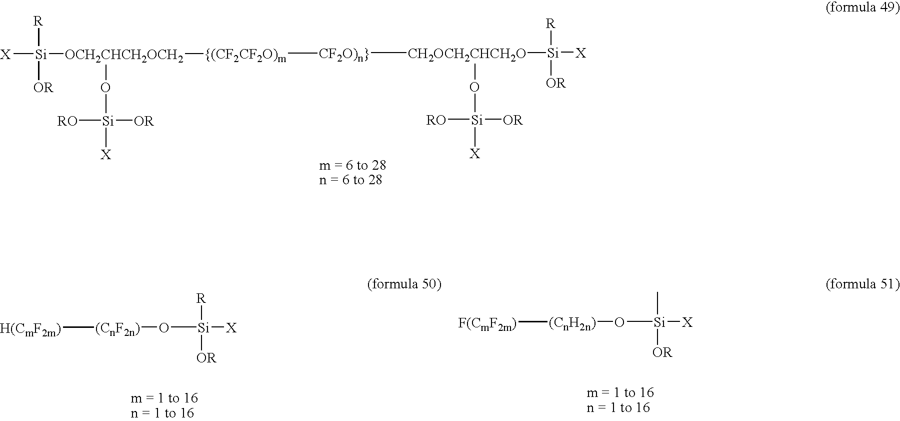
wherein, X is a structure represented by one of the following formulae, and R is an alkyl group of 1 to 4 carbon atoms:

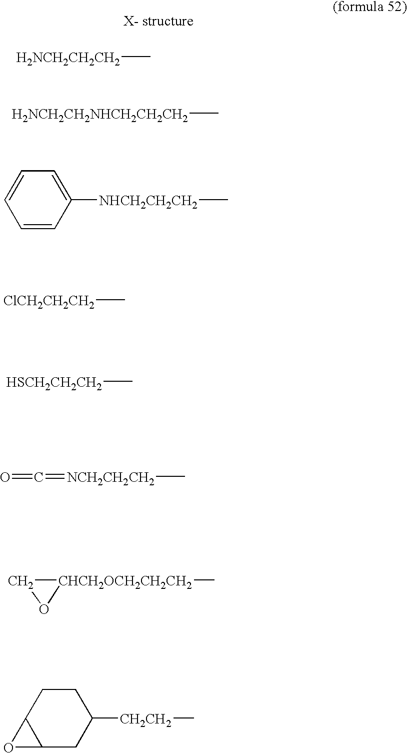

7. An electrical board comprising a board which supports a water repellent membrane and electrical lines in this order, wherein the water repellent membrane is the liquid repellent membrane according to claim 5 or 6.

8. The electrical board according to claim 7, wherein the water repellent membrane is formed on a board portion carrying no electrical line.

9. A semiconductor device comprising a board which supports layers of a gate electrode, gate insulation layer, source electrode, drain electrode, organic semiconductor layer and protective layer, wherein the liquid repellent membrane according to claim 5 or 6 is placed between any two of the adjacent layers on the board.

10. The semiconductor device according to claim 9, wherein at least one of the source and drain electrodes is transparent.

11. An organic electroluminescent device comprising a board which supports layers of a transparent electrode, hole-transport layer, light-emitting layer and metallic electrode in this order, wherein the liquid repellent membrane according to claim 5 or 6 is placed between any two of the adjacent layers on the board.

12. A color filter board comprising a board which supports a color filter layer and protective layer for protecting the color filter layer, wherein the liquid repellent membrane according to claim 5 or 6 is placed between the protective layer and board.

13. A pH sensor comprising a board which supports a responsive unit, wherein the responsive unit has the liquid repellent membrane according to claim 5 or 6.

14. A pH sensor comprising a board which supports a responsive unit, wherein the responsive unit determines pH level of a sample brought into contact with the responsive unit by measuring a contact angle at the contact point.

15. An ion sensor comprising a board which supports a responsive unit, wherein the responsive unit determines pH level of a sample brought into contact with the responsive unit by measuring a contact angle at the contact point.

16. A method for producing an electrical board, comprising the steps of:
forming a liquid repellent membrane on a board;
irradiating part of the liquid repellent membrane with light to decrease liquid repellency of that part, and
spreading a solution in which an electrical line material is dissolved or dispersed on the part of decreased repellency and drying the solution,
wherein a fluorine compound represented by one of the following structures is used for the liquid repellent membrane: 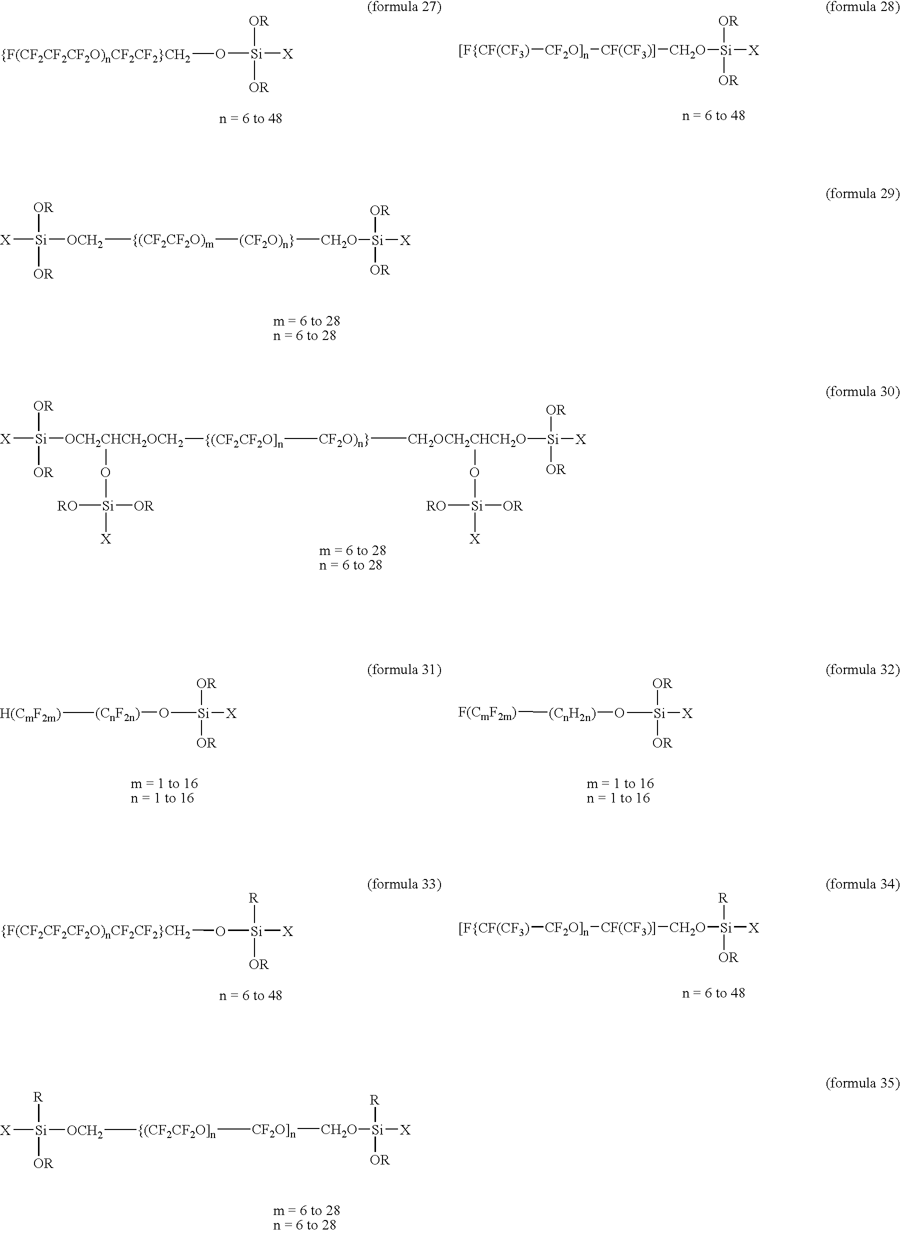 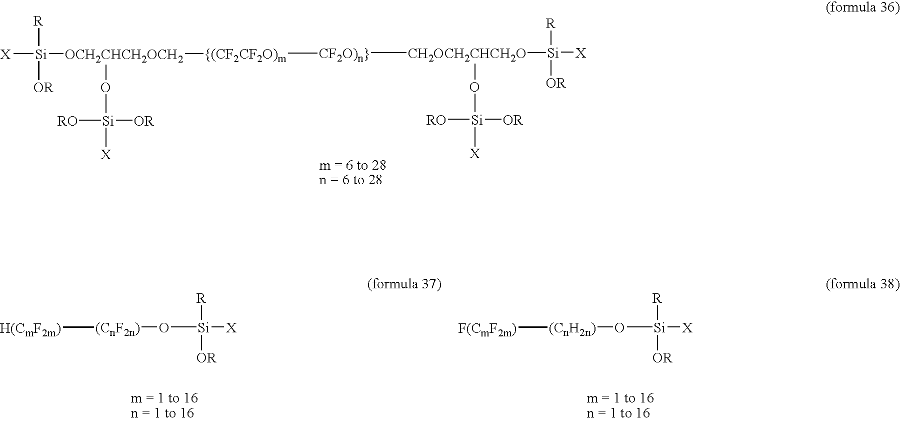
wherein, X is a structure represented by one of the following formulae, and R is an alkyl group of 1 to 4 carbon atoms:

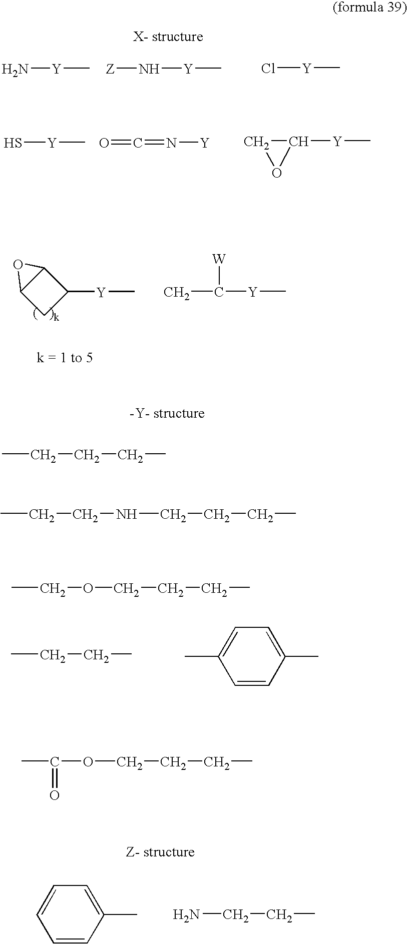

17. A method for producing an electrical board, comprising the steps of:
forming a liquid repellent membrane on a board;
irradiating part of the liquid repellent membrane with light to decrease liquid repellency of that part; and
spreading a solution in which an electrical line material is dissolved or dispersed on the part of decreased repellency and drying the solution,
wherein a fluorine compound represented by one of the following structures is used for the liquid repellent membrane: 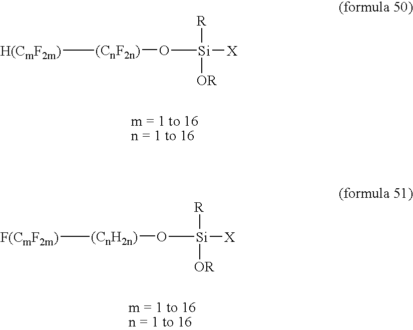
wherein, X is a structure represented by one of the following formulae, and R is an alkyl group of 1 to 4 carbon atoms:

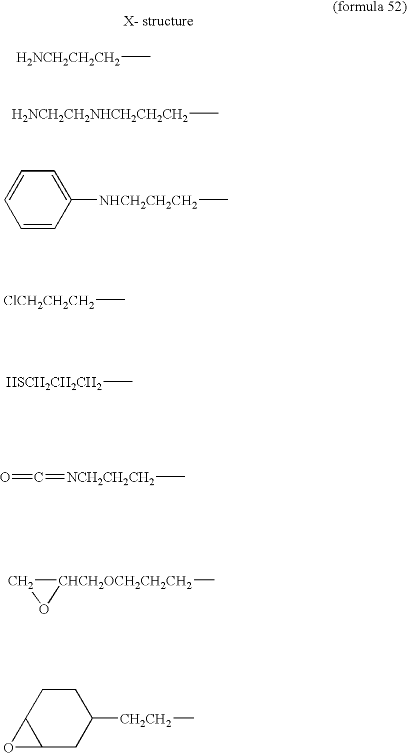

18. A method for producing an organic electroluminescent device comprising the steps of:
forming a transparent electrode on a board;
forming a hole-injection layer on the transparent electrode;
forming an emission layer on the hole-injection layer; and
forming a metallic electrode on the emission layer,
wherein the step for forming a liquid repellent membrane containing a fluorine compound represented by one of the following structures is carried out prior to at least one of the above steps: 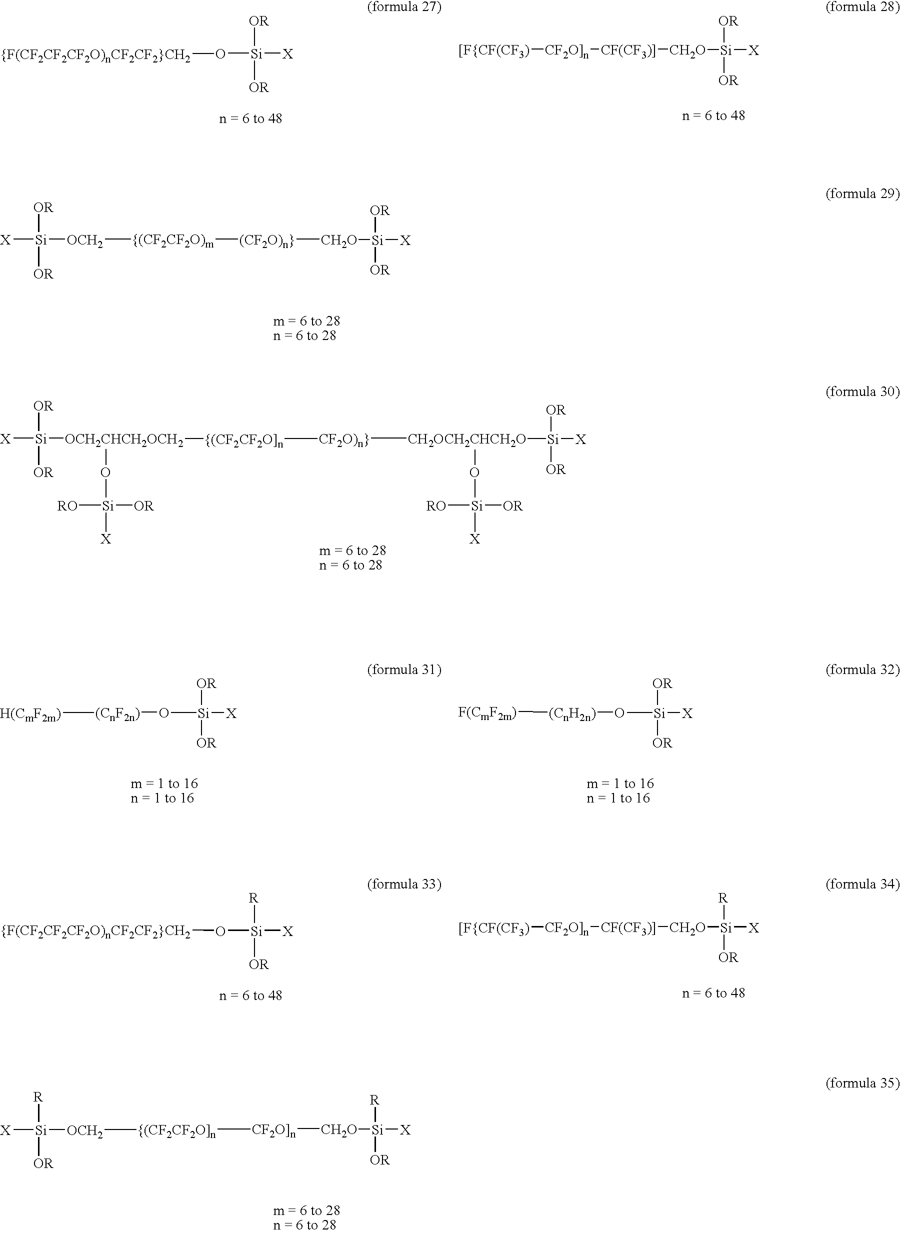 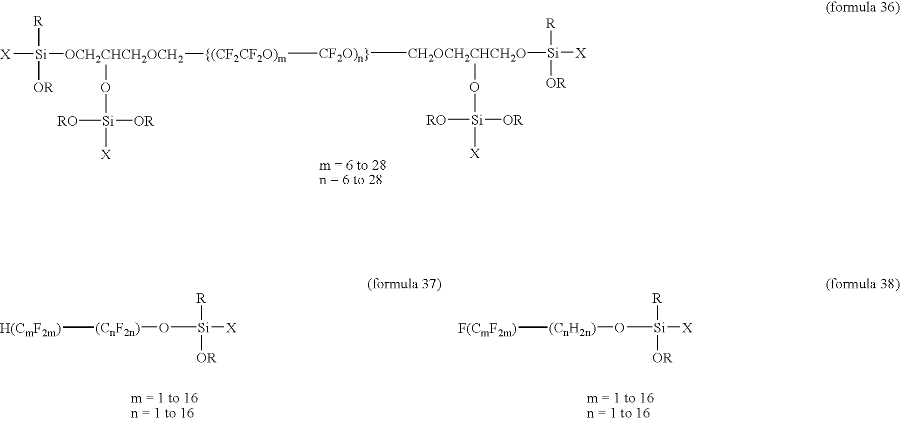
wherein, X is a structure represented by one of the following formulae, and R is an alkyl group of 1 to 4 carbon atoms:

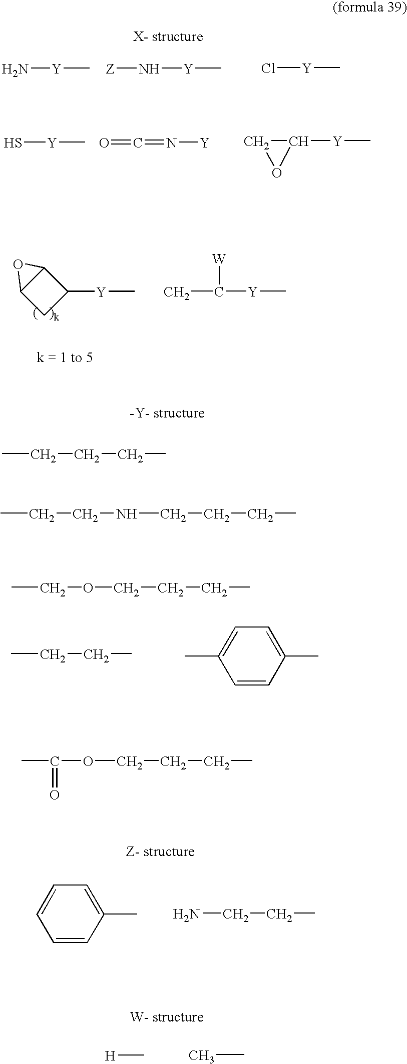

19. A method for producing an organic electroluminescent device comprising the steps of:
forming a transparent electrode on a board;
forming a hole-injection layer on the transparent electrode;
forming an emission layer on the hole-injection layer; and
forming a metallic electrode on the emission layer,
wherein the step for forming a liquid repellent membrane containing a fluorine compound represented by one of the following structures is carried out prior to at least one of the above steps: 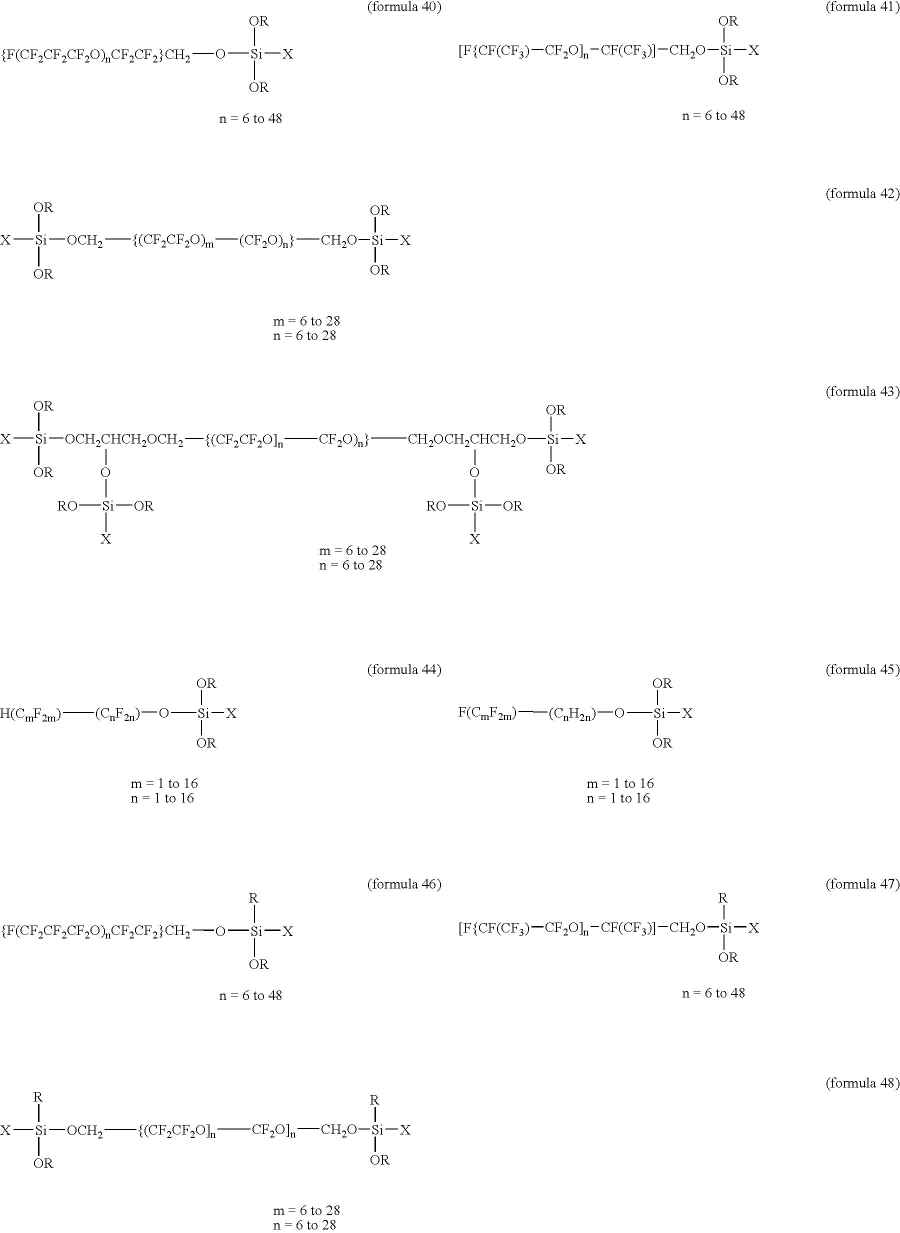 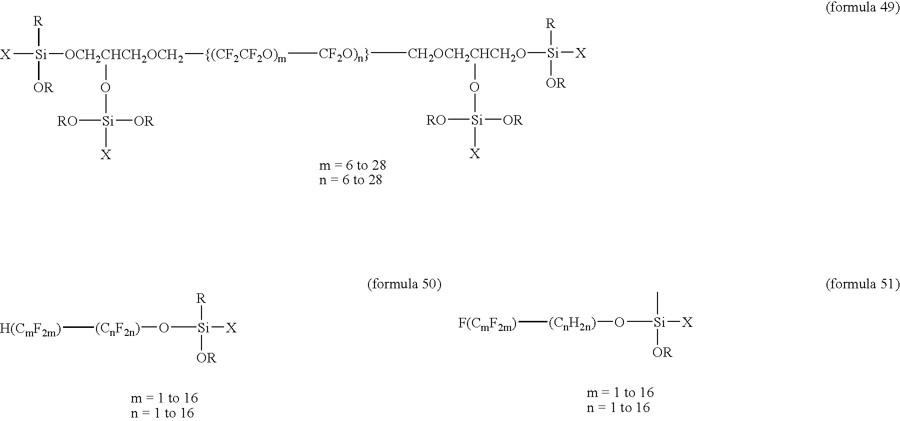
wherein, X is a structure represented by one of the following formulae, and R is an alkyl group of 1 to 4 carbon atoms:

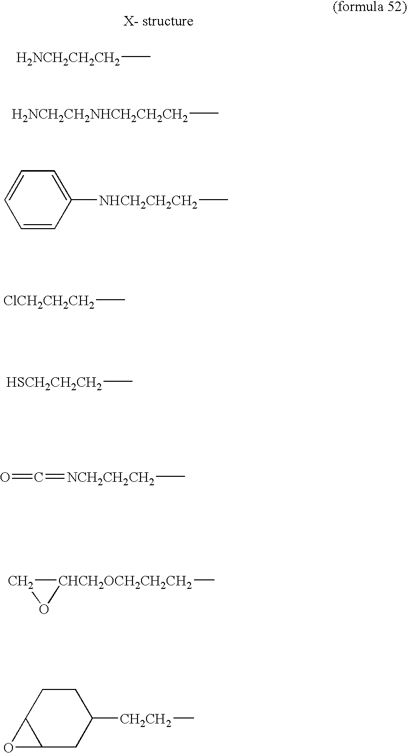

20. A semiconductor device comprising a board which supports layers of a gate electrode, gate insulation layer, two or more source electrodes and drain electrode intersecting with these source electrodes, wherein the liquid repellent membrane according to claim 5 or 6 is formed on at least one of these layers.
